(19) United States
(12) Patent Application Publication
(10) Pub. No.: US 2024/0341173 A1
(43) Pub. Date: Oct. 10, 2024

(54) ORGANIC LIGHT-EMITTING DEVICE

(71) Applicant: CANON KABUSHIKI KAISHA, Tokyo (JP)

(72) Inventors: YOSUKE NISHIDE, Kanagawa (JP); HIROKAZU MIYASHITA, Miyagi (JP); NAOKI YAMADA, Tokyo (JP); HIRONOBU IWAWAKI, Kanagawa (JP); JUN KAMATANI, Tokyo (JP); ITARU TAKAYA, Kanagawa (JP); HIROKI OHRUI, Tokyo (JP)

(21) Appl. No.: 18/747,910

(22) Filed: Jun. 19, 2024

Related U.S. Application Data
(63) Continuation of application No. PCT/JP2022/045338, filed on Dec. 8, 2022.

(30) Foreign Application Priority Data
Dec. 20, 2021 (JP) 2021-206091
Mar. 4, 2022 (JP) 2022-033476

(51) Int. Cl. H10K 85/60; C09K 11/06; G03G 15/04; G03G 15/043; H10K 50/12; H10K 101/40

(52) U.S. Cl. CPC H10K 85/626; C09K 11/06; G03G 15/04036; G03G 15/043; H10K 85/622; H10K 85/623; C09K 2211/1011; H10K 50/12; H10K 2101/40

(57) ABSTRACT

An organic light-emitting device including, in sequence, an anode, a light-emitting layer, a first organic compound layer in contact with the light-emitting layer, and a cathode, in which the light-emitting layer contains a host material and a guest material, the host material is a hydrocarbon compound whose carbon atoms are SP² carbon atoms only, the hydrocarbon compound is represented by any of the following formulae [1-1] to [1-6]:

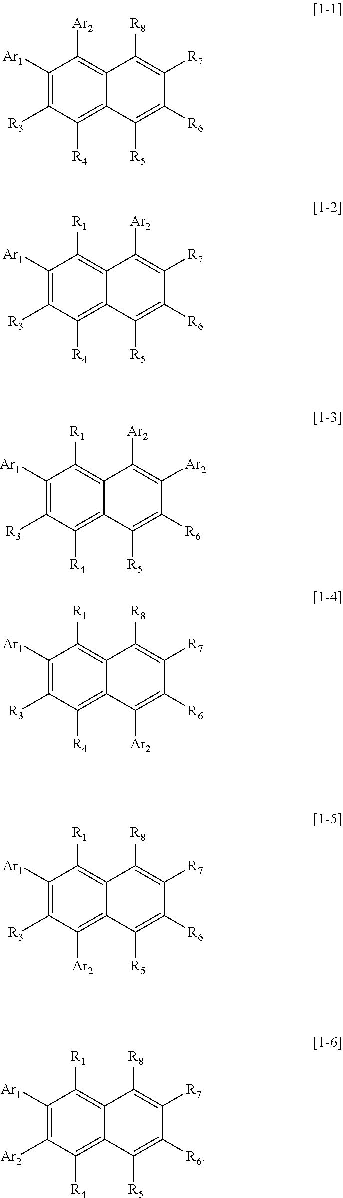

Ar₁ and Ar₂ are each independently selected from aryl groups, each of Ar₁ and Ar₂ may further contain substituents, R₁ to R₈ are each independently selected from a hydrogen atom and aryl groups. The guest material is a light-emitting material containing a fluoranthene skeleton, and the first organic compound layer contains a compound containing fused polycyclic hydrocarbon skeleton having three or more rings and five or less rings.

### CROSS-REFERENCE TO RELATED APPLICATIONS

This application is a Continuation of International Patent Application No. PCT/JP2022/045338, filed Dec. 8, 2022, which claims the benefit of Japanese Patent Application No. 2021-206091, filed Dec. 20, 2021, and No. 2022-033476, filed Mar. 4, 2022, all of which are hereby incorporated by reference herein in their entirety.

### TECHNICAL FIELD

The present disclosure relates to an organic light-emitting device.

### BACKGROUND ART

In recent years, the research and development of full-color displays including an organic electroluminescent (EL) device that emits light by energizing an organic EL layer including a light-emitting layer interposed between a pair of electrodes has been vigorously pursued. Full-color displays are produced by the following two methods. In one method, different light-emitting layers are allocated to different pixels (elements). In the other method, a white organic EL device including a white-light-emitting layer and different color filters allocated to different pixels is used. For such a white organic EL device, two or more light-emitting materials are often used.

Patent Literature 1 discloses a blue organic light-emitting device containing the following organic compound 1-a as a host for a light-emitting layer.

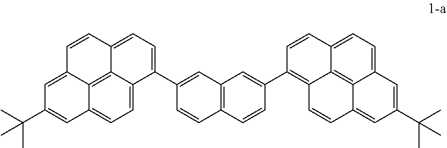 [SMILES: CC(C)(C)c1cc2ccc3ccc(-c4ccc5ccc(-c6ccc7ccc8cc(C(C)(C)C)cc9ccc6c7c89)cc5c4)c4ccc(c1)c2c34]

### CITATION LIST

### Patent Literature

PTL 1 Japanese Patent Laid-Open No. 2008-255099

However, the organic EL device disclosed in Patent Literature 1 has room for further improvement in durability.

### SUMMARY OF INVENTION

The present disclosure has been made in light of the foregoing problems and provides an organic light-emitting device having improved durability characteristics.

An organic light-emitting device of the present disclosure includes, in sequence, an anode, a light-emitting layer, a first organic compound layer in contact with the light-emitting layer, and a cathode,
in which the light-emitting layer contains a host material and a guest material,
the host material is a hydrocarbon compound whose carbon atoms are SP² carbon atoms only, the hydrocarbon compound is represented by any of the following general formulae [1-1] to [1-6]:

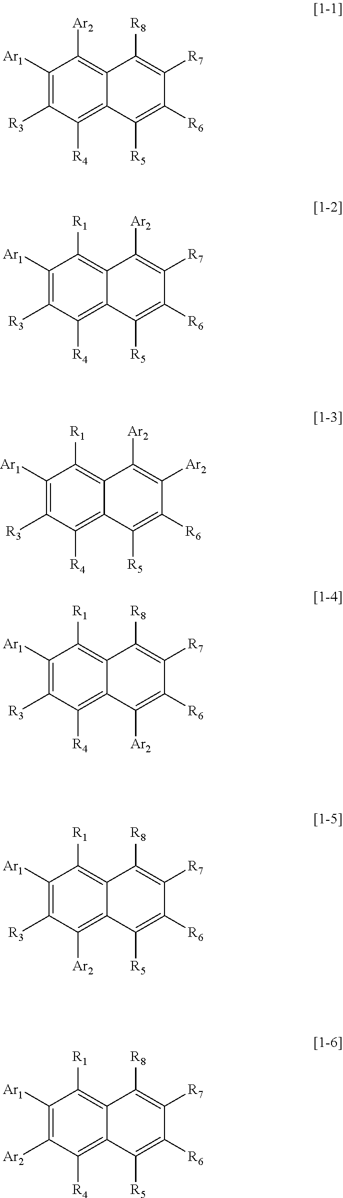

(where in general formulae [1-1] to [1-6], Ar₁ and Ar₂ are each independently selected from an anthracene residue, a phenanthrene residue, a pyrene residue, a fluoranthene residue, a chrysene residue, a triphenylene residue, a benzanthracene residue, a benzophenanthrene residue, a benzpyrene residue, a benzofluoranthene residue, a benzochrysene residue, and a picene residue, each of Ar₁ and Ar₂ may further contain a phenyl group, a biphenyl group, a terphenyl group, or a naphthyl group,

R₁ to R₈ are each independently selected from a hydrogen atom and a substituted or unsubstituted aryl group),
the guest material is a light-emitting material containing a fluoranthene skeleton, and
the first organic compound layer contains a compound containing at least one fused polycyclic hydrocarbon skeleton having three or more rings and five or less rings.

Further features of the present disclosure will become apparent from the following description of exemplary embodiments with reference to the attached drawings.

### BRIEF DESCRIPTION OF DRAWINGS

FIG. 1A is a schematic cross-sectional view of an example of a pixel of a display apparatus according to an embodiment of the present disclosure,

FIG. 1B is a schematic cross-sectional view of an example of a display apparatus including organic light-emitting devices according to an embodiment of the present disclosure.

FIG. 2 is a schematic view of an example of a display apparatus according to an embodiment of the present disclosure.

FIG. 3A is a schematic view of an example of an image pickup apparatus according to an embodiment of the present disclosure.

FIG. 3B is a schematic view of an example of an electronic apparatus according to an embodiment of the present disclosure.

FIG. 4A is a schematic view of an example of a display apparatus according to an embodiment of the present disclosure.

FIG. 4B is a schematic view of an example of a foldable display apparatus.

FIG. 5A is a schematic view of an example of a lighting apparatus according to an embodiment of the present disclosure.

FIG. 5B is a schematic view of an example of a moving object including an automotive lighting unit according to an embodiment of the present disclosure.

FIG. 6A is a schematic view of an example of a wearable device according to an embodiment of the present disclosure.

FIG. 6B is a schematic view of another example of a wearable device according to an embodiment of the present disclosure.

FIG. 7A is a schematic view of an example of an image-forming apparatus according to an embodiment of the present disclosure.

FIG. 7B is a schematic view of an example of an exposure light source of an image-forming apparatus according to an embodiment of the present disclosure.

FIG. 7C is a schematic view of an example of an exposure light source of an image-forming apparatus according to an embodiment of the present disclosure.

### DESCRIPTION OF EMBODIMENTS

The present disclosure will be described in detail below.

### <1> Organic Light-Emitting Device

An organic light-emitting device of the present embodiment includes, in sequence, an anode, a light-emitting layer, a first organic compound layer in contact with the light-emitting layer, and a cathode. The light-emitting layer contains a host material and a guest material.

The host material is a hydrocarbon compound whose carbon atoms are SP² carbon atoms only, and the hydrocarbon compound is represented by any of the following general formulae [1-1] to [1-6]:

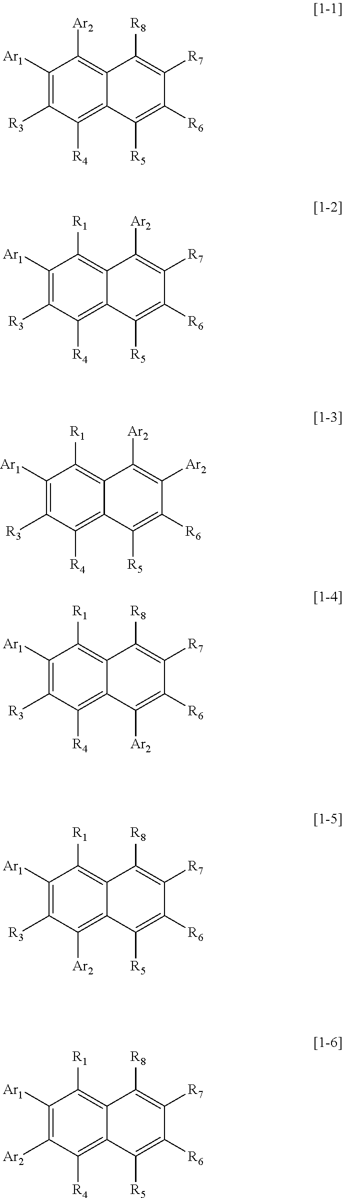

(where in general formulae [1-1] to [1-6], Ar₁ and Ar₂ are each independently selected from an anthracene residue, a phenanthrene residue, a pyrene residue, a fluoranthene residue, a chrysene residue, a triphenylene residue, a benzanthracene residue, a benzophenanthrene residue, a benzpyrene residue, a benzofluoranthene residue, a benzochrysene residue, and a picene residue, each of Ar₁ and Ar₂ may further contain a phenyl group, a biphenyl group, a terphenyl group, or a naphthyl group, and

R₁ to R₈ are each independently selected from a hydrogen atom and a substituted or unsubstituted aryl group).

The guest material is a light-emitting material containing a fluoranthene skeleton.

The first organic compound layer contains a compound containing at least one fused polycyclic hydrocarbon skeleton having three or more rings and five or less rings.

The organic light-emitting device of the present embodiment includes, in sequence, the anode, the light-emitting layer, the first organic compound layer in contact with the light-emitting layer, and the cathode. The specific configuration of the device includes multilayer device configurations described in (1) to (6) below, in which electrode layers and organic compound layers are sequentially stacked over a substrate. In any device configuration, the organic compound layer always includes a light-emitting layer containing a light-emitting material.

(1) Anode/light-emitting layer/electron transport layer/cathode

(2) Anode/hole transport layer/light-emitting layer/electron transport layer/cathode

(3) Anode/hole transport layer/light-emitting layer/electron transport layer/electron injection layer/cathode

(4) Anode/hole injection layer/hole transport layer/light-emitting layer/electron transport layer/cathode

(5) Anode/hole injection layer/hole transport layer/light-emitting layer/electron transport layer/electron injection layer/cathode

(6) Anode/hole transport layer/electron-blocking layer/light-emitting layer/hole-blocking layer/electron transport layer/cathode

However, these examples of the device configurations are only very basic device configurations, and the device configuration of the organic light-emitting device of the present disclosure is not limited thereto. Various layer configurations can be used, and examples thereof include an insulating layer, an adhesive layer, or an interference layer provided at the interface between an electrode and an organic compound layer; an electron transport layer or a hole transport layer formed of two layers having different ionization potentials; and a light-emitting layer formed of two layers having different light-emitting materials.

A mode of extracting light output from a light-emitting layer (device configuration) may be what is called a bottom emission mode in which light is extracted from an electrode on the substrate side, or what is called a top emission mode in which light is extracted from the side opposite to the substrate. In addition, a double-sided extraction mode in which light is extracted from the substrate side and the side opposite to the substrate can also be used.

This light-emitting layer may be formed of a single layer or multiple layers. It is also possible to mix colors by making the emission color of the light-emitting layer of the present embodiment blue and containing a light-emitting material having another emission color. The term “multiple layers” refers to a state in which a light-emitting layer and another light-emitting layer are stacked. In this case, the emission color of the organic light-emitting device is not limited to blue. More specifically, the emission color may be white or intermediate color. In the case of white, the other light-emitting layer emits light of a color other than blue, that is, green or red. Regarding a film-forming method, a film is formed by vapor deposition or a coating method. The details thereof will be described in Examples below.

Preferably, the other light-emitting layer contains a host material and a guest material and is disposed between the light-emitting layer and the anode. The host material contained in the other light-emitting layer preferably has no SP³ carbon. The host material contained in the light-emitting layer is preferably identical to the host material contained in the other light-emitting layer.

Preferably, in the organic light-emitting device of the present embodiment, the light-emitting layer contains a naphthalene compound represented by any of general formulae [1-1] to [1-6], and the first organic compound layer adjacent to the light-emitting layer on the cathode side contains a compound containing a fused polycyclic hydrocarbon skeleton having three or more rings and five or less rings.

In this case, the light-emitting layer contains a light-emitting material containing a fluoranthene skeleton. The light-emitting material containing a fluoranthene skeleton is characterized by having low highest occupied molecular orbital (HOMO) and lowest unoccupied molecular orbital (LUMO) energies (far from the vacuum level) due to containing an electron-deficient five-membered ring. This provides two effects.

The first is that the light-emitting material itself is stable against oxidation and reaction. In an organic light-emitting device, a light-emitting material contained in a light-emitting layer repeatedly undergoes excitation and light emission during driving. Accordingly, when the stability of the light-emitting material is high, the continuous driving durability characteristics are also improved.

The second is that the difference in LUMO energy with the host material is large, and the electron-trapping properties can be improved. Furthermore, the electron-trapping properties can be enhanced by containing two or more fluoranthene skeletons. This can result in a reduction in the number of electrons reaching a layer, such as an EBL, in contact with the light-emitting layer on the anode side to provide an organic EL device having excellent durability characteristics.

Compounds contained in the light-emitting layer are used for different applications depending on their concentrations in the light-emitting layer. Specifically, the compounds are divided into a main component and an auxiliary component according to their concentrations contained in the light-emitting layer.

A compound serving as a main component is a compound having the highest proportion (concentration) by mass in a group of compounds contained in the light-emitting layer, and is also referred to as a host. The host is a compound that is present as a matrix around the light-emitting material in the light-emitting layer and that is mainly responsible for transporting carriers to the light-emitting material and providing excitation energy to the light-emitting material. The concentration of the host is preferably 50% or more by mass and 99.99% or less by mass, more preferably 80% or more by mass and 99.9% or less by mass, based on the total amount of constituent materials of the light-emitting layer.

A compound serving as an auxiliary component is a compound other than the main component and can be referred to as a guest (dopant), a light-emission assist material, or a charge injection material in accordance with the function of the compound. The guest, which is a type of auxiliary component, is a compound (light-emitting material) responsible for main light emission in the light-emitting layer. The light-emission assist material, which is a type of auxiliary component, is a compound that assists light emission of the guest and that has a lower proportion (concentration) by mass than the host in the light-emitting layer. The light-emission assist material is also referred to as a second host because of its function.

The concentration of the guest is preferably 0.01% or more by mass and 50% or less by mass, more preferably 0.1% or more by mass and 20% or less by mass, based on the total amount of constituent materials of the light-emitting layer. From the viewpoint of preventing concentration quenching, the concentration of the guest is particularly preferably 10% or less by mass.

The guest may be uniformly contained in the entire layer in which the host serves as a matrix, or may be contained with a concentration gradient. The guest may be partially contained in a specific region in the layer, in other words, the light-emitting layer may have a region containing only the host without containing the guest.

In the present disclosure, an aspect is preferable in which an organic compound, serving as a host material, containing a naphthalene skeleton represented by any of general formulae [1-1] to [1-6] and a light-emitting material, serving as a guest material, containing a fluoranthene skeleton are both contained in a light-emitting layer. For the purpose of assisting the transport of excitons and carriers, the light-emitting layer may further contain another light-emitting material in addition to the foregoing light-emitting material. For the purpose of assisting the transport of excitons and carriers, the light-emitting layer may further contain, as a second host, a compound other than the compound represented by any of general formulae [1-1] to [1-6].

### <2> Combination Effect of Light-Emitting Layer and Adjacent First Organic Compound Layer

When an organic light-emitting device contains, as a guest, a light-emitting material containing a fluoranthene skeleton, the difference in LUMO energy between the light-emitting material and the host material is large, thus enhancing the electron-trapping properties. That is, in the light-emitting layer, the electron mobility is lower than the hole mobility. In other words, with regard to the charge mobility in the light-emitting layer, the hole mobility is higher than the electron mobility. Thus, it has been found that electric charges accumulate easily at the interface between the light-emitting layer and the adjacent organic compound layer on the cathode side. This causes the quenching and reaction of excitons and electric charges, thereby deteriorating the durability characteristics.

In the organic light-emitting device of the present embodiment, we have focused on the compatibility between the organic compound, represented by any of general formulae [1-1] to [1-6], contained in the light-emitting layer and the organic compound contained in the first organic compound layer adjacent to the light-emitting layer on the cathode side. That is, we have found that by increasing the compatibility between the light-emitting layer and the adjacent organic compound layer to allow charge transfer to proceed smoothly, charge accumulation is improved to improve the durability characteristics.

To increase the compatibility, a design has been made to maximize the interaction between molecules while maintaining good film properties. In general, π-π interactions between aromatic rings are known. Among them, it has been found that a closer number of fused rings results in greater intermolecular interactions in the thin-film state, leading to greater compatibility.

Table 1 presents examples of a fused polycyclic hydrocarbon skeleton having three or more rings and five or less rings.

TABLE 1

| | Basic skeleton |
|---|---|
| Fused-ring skeleton with three rings | 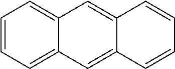 [SMILES: c1ccc2cc3ccccc3cc2c1] |
| | 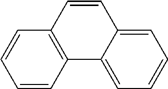 [SMILES: c1ccc2c(c1)ccc1ccccc12] |
| Fused-ring skeleton with four rings | 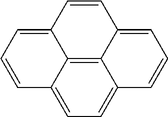 [SMILES: c1cc2ccc3cccc4ccc(c1)c2c34] |
| | 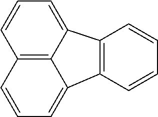 [SMILES: c1ccc2c(c1)-c1cccc3cccc-2c13] |
| | 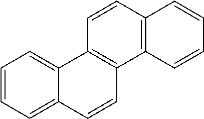 [SMILES: c1ccc2c(c1)ccc1c3ccccc3ccc21] |
| | 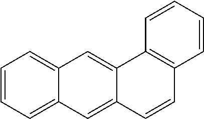 [SMILES: c1ccc2cc3c(ccc4ccccc43)cc2c1] |
| | 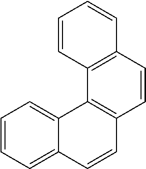 [SMILES: c1ccc2c(c1)ccc1ccc3ccccc3c12] |
| | 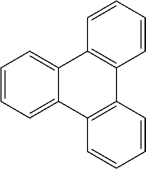 [SMILES: c1ccc2c(c1)c1ccccc1c1ccccc21] |
| Fused-ring skeleton with five rings | 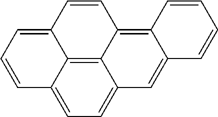 [SMILES: c1ccc2c(c1)cc1ccc3cccc4ccc2c1c34] |
| | 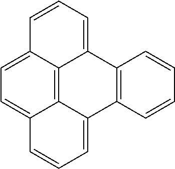 [SMILES: c1ccc2c(c1)c1cccc3ccc4cccc2c4c31] |
| | 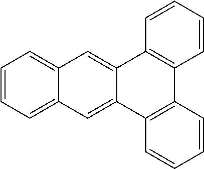 [SMILES: c1ccc2cc3c4ccccc4c4ccccc4c3cc2c1] |
| | 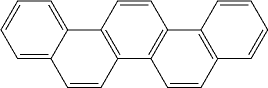 [SMILES: c1ccc2c(c1)ccc1c2ccc2c3ccccc3ccc21] |
| | 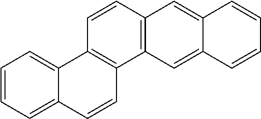 [SMILES: c1ccc2cc3c(ccc4c5ccccc5ccc34)cc2c1] |
| | 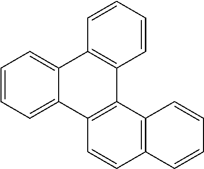 [SMILES: c1ccc2c(c1)ccc1c3ccccc3c3ccccc3c21] |
| | 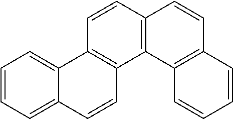 [SMILES: c1ccc2c(c1)ccc1c2ccc2ccc3ccccc3c21] |
| | 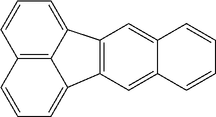 [SMILES: c1ccc2cc3c(cc2c1)-c1cccc2cccc-3c12] |
| | 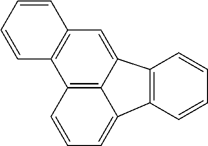 [SMILES: c1ccc2c(c1)-c1cccc3c1c-2cc1ccccc13] |

Table 2 represents the relationship between the number of fused rings in Ar₁ and Ar₂ of the host material contained in the light-emitting layer and the number of fused rings in the organic compound contained in the first organic compound layer adjacent to the light-emitting layer on the cathode side, and the effect of improving the durability of the device. Table 3 presents the effect of improving the durability of the device in the combination of specific compounds. The effect of improving the durability of the devices in Tables 2 and 3 was obtained by determining the percentage ratios of luminance degradation in the organic light-emitting devices at the time of continuous driving in the same manner as in Examples and evaluating the results according to the following criteria.

A· · · A percentage ratio of luminance degradation of 2.5 or more

B· · · A percentage ratio of luminance degradation of 2.0 or more and less than 2.5

C· · · A percentage ratio of luminance degradation of 1.5 or more and less than 2.0

D· · · A percentage ratio of luminance degradation of 1.0 or less

TABLE 2

| Number of fused | Number of fused rings in | |
|---|---|---|
| rings in | compound contained in first | Effect of improving |
| Ar₁ and Ar₂ | organic compound layer | durability of device |
| 3 | 3 | B |
| | 4 | C |
| | 5 | C |
| 4 | 3 | B |
| | 4 | A |
| | 5 | B |
| 5 | 3 | C |
| | 4 | B |
| | 5 | B |

TABLE 3

| | | | Effect of |
|---|---|---|---|
| | | | improving |
| | | Compound contained in first | durability of |
| | Host compound | organic compound layer | device |
| Present disclosure | 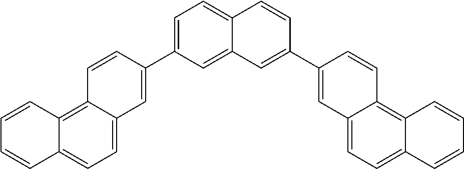 [SMILES: c1ccc2c(c1)ccc1cc(-c3ccc4ccc(-c5ccc6c(ccc7ccccc76)c5)cc4c3)ccc12] Three rings A30 | 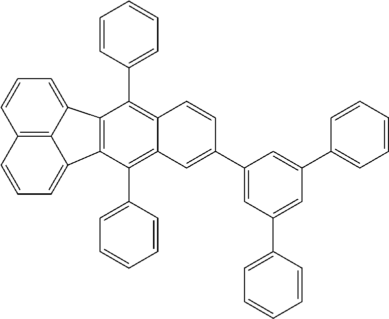 [SMILES: c1ccc(-c2cc(-c3ccccc3)cc(-c3ccc4c(-c5ccccc5)c5c(c(-c6ccccc6)c4c3)-c3cccc4cccc-5c34)c2)cc1] Five rings HB18 | C |
| | 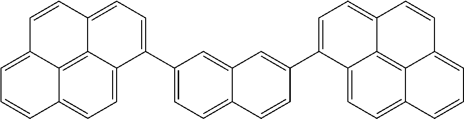 [SMILES: c1cc2ccc3ccc(-c4ccc5ccc(-c6ccc7ccc8cccc9ccc6c7c89)cc5c4)c4ccc(c1)c2c34] Four rings A2 | 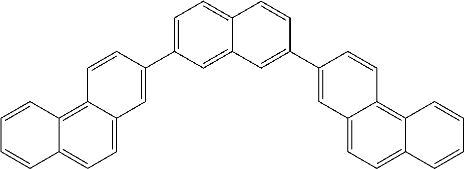 [SMILES: c1ccc2c(c1)ccc1cc(-c3ccc4ccc(-c5ccc6c(ccc7ccccc76)c5)cc4c3)ccc12] Three rings A30 | B |
| | 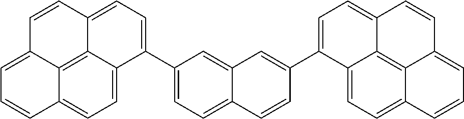 [SMILES: c1cc2ccc3ccc(-c4ccc5ccc(-c6ccc7ccc8cccc9ccc6c7c89)cc5c4)c4ccc(c1)c2c34] Four rings A2 | 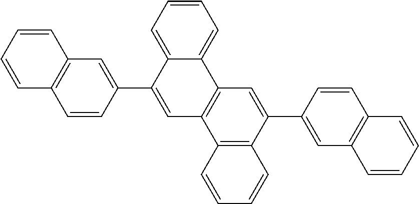 [SMILES: c1ccc2cc(-c3cc4c5ccccc5c(-c5ccc6ccccc6c5)cc4c4ccccc34)ccc2c1] Four rings HB7 | A |
| | 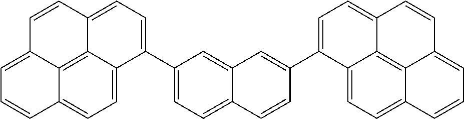 [SMILES: c1cc2ccc3ccc(-c4ccc5ccc(-c6ccc7ccc8cccc9ccc6c7c89)cc5c4)c4ccc(c1)c2c34] Four rings A2 | 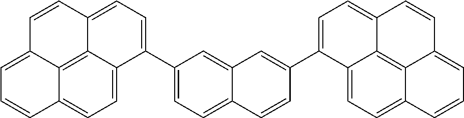 [SMILES: c1cc2ccc3ccc(-c4ccc5ccc(-c6ccc7ccc8cccc9ccc6c7c89)cc5c4)c4ccc(c1)c2c34] Four rings A2 | A |
| | 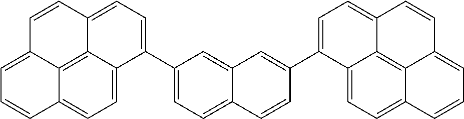 [SMILES: c1cc2ccc3ccc(-c4ccc5ccc(-c6ccc7ccc8cccc9ccc6c7c89)cc5c4)c4ccc(c1)c2c34] Four rings A2 | 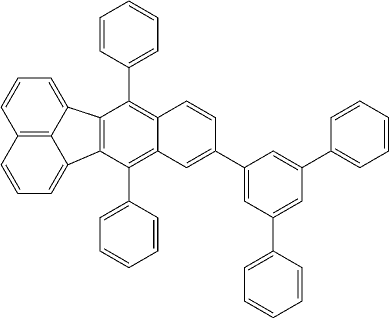 [SMILES: c1ccc(-c2cc(-c3ccccc3)cc(-c3ccc4c(-c5ccccc5)c5c(c(-c6ccccc6)c4c3)-c3cccc4cccc-5c34)c2)cc1] Five rings HB18 | B |
| | 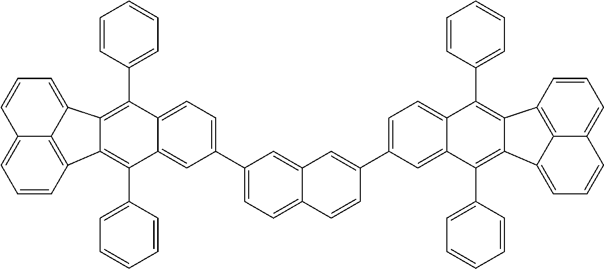 [SMILES: c1ccc(-c2c3c(c(-c4ccccc4)c4cc(-c5ccc6ccc(-c7ccc8c(-c9ccccc9)c9c(c(-c%10ccccc%10)c8c7)-c7cccc8cccc-9c78)cc6c5)ccc24)-c2cccc4cccc-3c24)cc1] Five rings A36 | 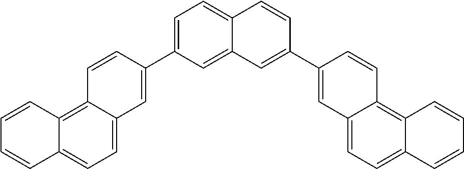 [SMILES: c1ccc2c(c1)ccc1cc(-c3ccc4ccc(-c5ccc6c(ccc7ccccc76)c5)cc4c3)ccc12] Three rings A30 | C |
| Comparative example | 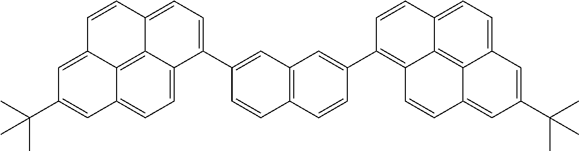 [SMILES: CC(C)(C)c1cc2ccc3ccc(-c4ccc5ccc(-c6ccc7ccc8cc(C(C)(C)C)cc9ccc6c7c89)cc5c4)c4ccc(c1)c2c34] Four rings 1-a | 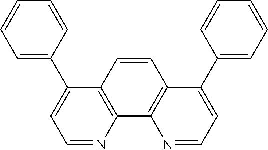 [SMILES: c1ccc(-c2ccnc3c2ccc2c(-c4ccccc4)ccnc23)cc1] Three rings ET1 | D |

From Tables 2 and 3, more preferably, the number of fused rings in Ar₁ and Ar₂ of the host material is the same as the number of fused rings in the organic compound contained in the first organic compound layer. A large effect can be provided when the number of fused rings in the organic compound contained in the first organic compound layer is any of three or more and five or less. More preferably, the number of fused rings in Ar₁ and Ar₂ of the host material contained in the light-emitting layer is four.

A combination in which the number of fused rings is four or more is preferred because thermal stability, such as a glass transition temperature, is higher. In particular, in the case of a combination in which the number of fused rings is four, the planarity is high, and I stacking between molecules is less likely to be too large. As a result, partial crystallization is less likely to occur during driving of the organic light-emitting device, and the effect of compatibility can be exhibited to the maximum extent. Therefore, a combination in which the number of fused rings is four is more preferred.

When the host material has a group that inhibits intermolecular interaction, such as an alkyl group or a fluorine group, or when the fused polycyclic ring of a compound contained in the first organic compound layer is a heterocyclic ring in which the electronic state varies greatly, the above effect cannot be provided. For comparison, the durability characteristics in the combination described in Patent Literature 1 are described in Table 3. In the comparative example, an organic compound contained in the light-emitting layer has alkyl groups, and an organic compound contained in the first organic compound layer does not contain a fused polycyclic hydrocarbon skeleton having three or more rings and five or less rings. Therefore, the effect of compatibility is not provided, and the durability characteristics are not improved.

The first organic compound layer may be functionally separated into two layers. For example, a second organic compound layer may be disposed between the first organic compound layer and the cathode and in contact with the first organic compound layer. The second organic compound layer may contain a compound containing at least one fused polycyclic hydrocarbon skeleton having three or more rings and five or less rings, as in the first organic compound layer.

### <3> Host Material (Organic Compound Contained in Light-Emitting Layer)

An organic compound used as a host material in the light-emitting layer will be described. The host material is a hydrocarbon compound whose carbon atoms are SP² carbon atoms only, and the hydrocarbon compound is represented by any of the following general formulae [1-1] to [1-6]. The host material is preferably a compound represented by the following general formula [1-3].

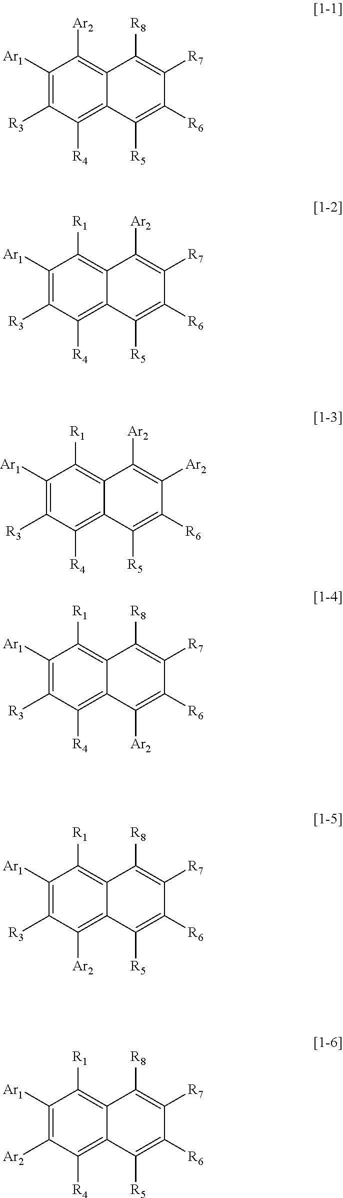

Ar₁ and Ar₂

In general formula [1-1] to [1-6], Ar₁ and Ar₂ are each independently selected from an anthracene residue, a phenanthrene residue, a pyrene residue, a fluoranthene residue, a chrysene residue, a triphenylene residue, a benzanthracene residue, a benzophenanthrene residue, a benzpyrene residue, a benzofluoranthene residue, a benzochrysene residue, and a picene residue. Each of Ar₁ and Ar₂ is preferably a fused ring having four rings, more preferably, a pyrene residue, a fluoranthene residue, a chrysene residue, or a triphenylene residue.

Each of Ar₁ and Ar₂ may further contain a phenyl group, a biphenyl group, a terphenyl group, or a naphthyl group.

R₁ to R₈

R₁ to Re are each independently selected from a hydrogen atom and a substituted or unsubstituted aryl group.

Examples of the aryl group include, but are not limited to, a phenyl group, a naphthyl group, an indenyl group, a biphenyl group, a terphenyl group, a fluorenyl group, a phenanthryl group, a pyrenyl group, and a triphenylenyl group. Among these, an aryl group having 6 to 18 carbon atoms is preferred.

### Feature

The host material represented by any of general formulae [1-1] to [1-6] has the following two features.

(1) The host material is a hydrocarbon compound whose carbon atoms are SP² carbon atoms only.

(2) The host material has a partial structure that reduces linearity.

These features will be described below.

(1) The host material is a hydrocarbon compound whose carbon atoms are SP² carbon atoms only.

In inventing the organic light-emitting device of the present disclosure, the inventors focused on the bonding strength of the structure of the host compound. Specifically, the host material was a hydrocarbon compound whose carbon atoms were SP² carbon atoms only, and the molecular design was attempted so as not to contain a structure having low bond stability. This is because a compound having a bond having low bond stability in the molecular structure, that is, an unstable bond having small bond energy is likely to cause deterioration of the compound at the time of driving the organic EL device, and is likely to adversely affect the durability life of the device.

In the case of taking the following compound [4,4′-bis(carbazol-9-yl) biphenyl] (CBP) as an example, the bond having low bond stability is a bond that connects the carbazole ring to the phenylene group (nitrogen-carbon bond). The following presents a comparison of the calculated values of the bond energies of CBP and exemplified compound A2 of the host material. The calculation method used was b3-lyp/def2-SV(P).

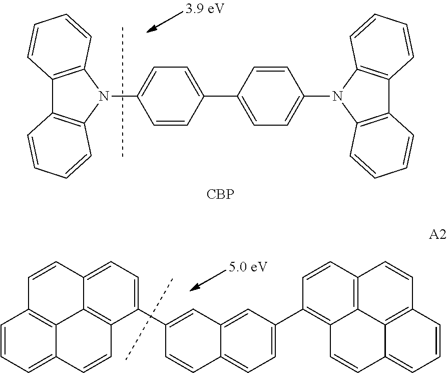

From the above results, it is understood that the nitrogen-carbon bond in CBP is a bond having low bond stability. It is not preferable that such a bond be contained in the structure of the host material, especially in the light-emitting layer. In contrast, since exemplified compound A2 is composed only of carbon-carbon bonds and carbon-hydrogen bonds, it is understood that exemplified compound A2 has a structure having high bond stability.

In addition, an attempt was made to design the molecule in such a manner that substituents (R₁ to R₈, Ar₁, and Ar₂) contained in the host material have high bond stability. Table 4 presents the bond dissociation energies of carbon-hydrogen bonds described in ACC. Chem. Res. 36, 255-263, (2003).

TABLE 4

| | | Bond dissociation | |
|---|---|---|---|
| | | energy | Hybrid orbital of |
| | Bond | (Kcal/mol) | carbon atom |
| Methyl group | 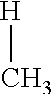 | 105 | SP3 |
| Ethyl group | 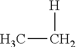 | 101 | SP3 |
| Benzyl group | 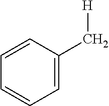 | 90 | SP3 |
| Phenyl group | 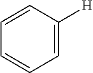 | 113 | SP2 |

A larger value of the bond dissociation energy indicates a stronger bond, and a smaller value thereof indicates a weaker bond. That is, substituents having SP³ carbons, such as a methyl group, an ethyl group, and a benzyl group, are not preferred because they are substituents from which hydrogen atoms are easily eliminated to generate radicals.

As described above, the carbon atoms of the host material are SP² carbon atoms only, and thus the host material is a compound having excellent durability characteristics. The organic light-emitting device containing the host material has excellent durability characteristics. In addition, since the carbon atoms of the host material are SP² carbon atoms only, the host material has high electron mobility. Therefore, the effect of lowering the voltage of the device should be provided.

(2) The host material has a partial structure that reduces linearity.

As described in feature (1), the carbon atoms of the host material are SP² carbon atoms only. For this reason, molecular aggregation due to π-π stacking between molecules may easily occur, thus causing deteriorations in film properties and sublimability.

Thus, as feature (2), the host material has a structure, represented by any of general formulae [1-1] to [1-6], for reducing the linearity of the molecular structure, in order to inhibit molecular aggregation. It has been found that the structure of the following general formula [1-7], as a comparative structure, has high molecular linearity, easily causes molecular aggregation, and deteriorates film properties and sublimability. In general formula [1-7], Ar₁, Ar₂, R₁, R₃ to R₅, R₇, and R₈ are the same as those in general formulae [1-1] to [1-6].

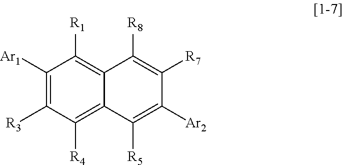

As presented in Table 5, exemplified compound A2 serving as a host material and comparative compound 2 represented by general formula [1-7] were subjected to a solubility test for comparison. The solubility test was performed by heating 100 mg of the host material to reflux in toluene under stirring and comparing the amount of toluene solvent when the host material was dissolved. The amount of toluene solvent required to completely dissolve comparative compound 2 is presented when the amount of solvent to completely dissolve exemplified compound A2 is 1.

TABLE 5

| | Structure | Solubility test |
|---|---|---|
| Exemplified compound A2 | 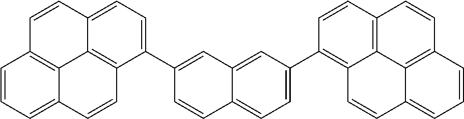 [SMILES: c1cc2ccc3ccc(-c4ccc5ccc(-c6ccc7ccc8cccc9ccc6c7c89)cc5c4)c4ccc(c1)c2c34] | 1 |
| Comparative compound 2 | 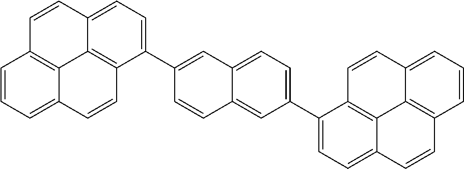 [SMILES: c1cc2ccc3ccc(-c4ccc5cc(-c6ccc7ccc8cccc9ccc6c7c89)ccc5c4)c4ccc(c1)c2c34] | 80 |

From Table 5, it can be seen that each of exemplified compound A2 and comparative compound 2 is a compound composed of pyrene and naphthalene, but the solubility varies greatly depending on the substitution positions.

Comparative compound 2 has a structure having high linearity because pyrene moieties are bonded to the 2- and 6-positions of naphthalene. In contrast, exemplified compound A2 has a bent molecular structure because pyrene moieties are bonded to the 2- and 7-positions of naphthalene, which is considered to contribute to the solubility.

In the case of a highly linear molecular structure, molecules easily overlap each other and thus easily aggregate. For this reason, the solubility is poor, and thus it is not suitable for mass production from the viewpoint of material synthesis. In addition, it is not preferred as a material for an organic light-emitting device because it leads to a deterioration in film properties and a decrease in sublimability. In contrast, the host material represented by any of general formulae [1-1] to [1-6] has a bent structure, and thus the molecules are inhibited from overlapping with each other, and molecular aggregation is less likely to occur. This improves the solubility, the amorphous nature of the film, and the sublimability.

In an organic light-emitting device, the film properties of an organic compound contained in the device are important. This is because the high amorphous nature makes it difficult for grain boundaries, trap levels, and quenchers to be generated due to minute crystallization even during driving of the device, so that good carrier transport properties and high-efficiency light emission characteristics can be maintained. Therefore, an organic light-emitting device having excellent durability and efficiency can be provided.

Similarly, in the organic light-emitting device, the sublimability of the organic compound contained in the device is important. This is because the compound having high sublimability can be stably subjected to sublimation purification without decomposition during sublimation. This is also because vapor deposition stability is high when an organic light-emitting device is produced. That is, a high-purity vapor deposition film can be produced without decomposition during vapor deposition, and a long-life organic light-emitting device can be provided.

That is, the host material used in the present disclosure has a structure whose carbon atoms are SP² carbon atoms only, in which the structure is a molecular structure having high bond stability and improving the film properties. Therefore, it can be said that the compound has chemical stability as a molecule, the stability of a film that can be suitably used for an organic EL device, and sublimability.

### Preferred Compound

The compound represented by any of general formulae [1-1] to [1-6] is preferably a compound represented by any of general formulae [1-2] to [1-5], more preferably a compound represented by general formula [1-3].

The host material preferably has high planarity. Thus, dihedral angles were calculated when Ar₁ and Ar₂ were each a phenyl group. The results are presented in Table 6. It was found that each of the compounds represented by general formulae [1-2] to [1-5] had a small dihedral angle, and the compound represented by general formula [1-3] had a particularly small dihedral angle and high planarity. That is, the organic compounds represented by general formulae [1-2] to [1-5] are preferred, and the organic compound represented by general formula [1-3] is more preferred, because they have higher compatibility and exhibit better durability characteristics.

TABLE 6

| General | | Dihedral |
|---|---|---|
| formula | Molecular structure | angle |
| [1-3] | 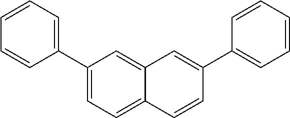 [SMILES: c1ccc(-c2ccc3ccc(-c4ccccc4)cc3c2)cc1] | 36°, 36° |
| [1-2] | 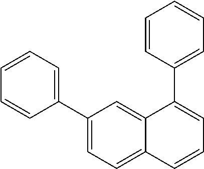 [SMILES: c1ccc(-c2ccc3cccc(-c4ccccc4)c3c2)cc1] | 36°, 55° |
| [1-4] | 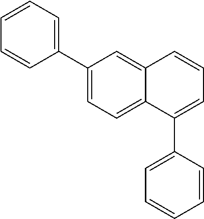 [SMILES: c1ccc(-c2ccc3c(-c4ccccc4)cccc3c2)cc1] | 36°, 55° |
| [1-5] | 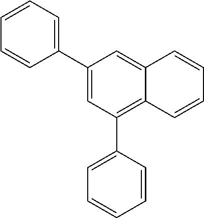 [SMILES: c1ccc(-c2cc(-c3ccccc3)c3ccccc3c2)cc1] | 36°, 55° |
| [1-1] | 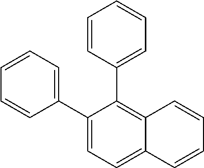 [SMILES: c1ccc(-c2ccc3ccccc3c2-c2ccccc2)cc1] | 51°, 66° |
| [1-6] | 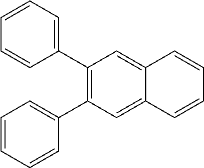 [SMILES: c1ccc(-c2cc3ccccc3cc2-c2ccccc2)cc1] | 51°, 51° |

The foregoing dihedral angles were calculated by molecular orbital calculation. As the molecular orbital calculation method, the density functional theory (DFT), which is widely used at present, was used with the B3LYP functional and 6-31G* as the basis function. The molecular orbital calculation method was performed using Gaussian 09 (Gaussian 09, Revision C.01, M. J. Frisch, G. W. Trucks, H. B. Schlegel, G. E. Scuseria, M. A. Robb, J. R. Cheeseman, G. Scalmani, V. Barone, B. Mennucci, G. A. Petersson, H. Nakatsuji, M. Caricato, X. Li, H. P. Hratchian, A. F. Izmaylov, J. Bloino, G. Zheng, J. L. Sonnenberg, M. Hada, M. Ehara, K. Toyota, R. Fukuda, J. Hasegawa, M. Ishida, T. Nakajima, Y. Honda, O. Kitao, H. Nakai, T. Vreven, J. A. Montgomery, Jr., J. E. Peralta, F. Ogliaro, M. Bearpark, J. J. Heyd, E. Brothers, K. N. Kudin, V. N. Staroverov, T. Keith, R. Kobayashi, J. Normand, K. Raghavachari, A. Rendell, J. C. Burant, S. S. Iyengar, J. Tomasi, M. Cossi, N. Rega, J. M. Millam, M. Klene, J. E. Knox, J. B. Cross, V. Bakken, C. Adamo, J. Jaramillo, R. Gomperts, R. E. Stratmann, O. Yazyev, A. J. Austin, R. Cammi, C. Pomelli, J. W. Ochterski, R. L. Martin, K. Morokuma, V. G. Zakrzewski, G. A. Voth, P. Salvador, J. J. Dannenberg, S. Dapprich, A. D. Daniels, O. Farkas, J. B. Foresman, J. V. Ortiz, J. Cioslowski, and D. J. Fox, Gaussian, Inc., Wallingford CT, 2010), which is widely used at present.

### SPECIFIC EXAMPLES

Specific examples of the host material will be described below. However, these compounds are merely specific examples, and the present invention is not limited thereto.

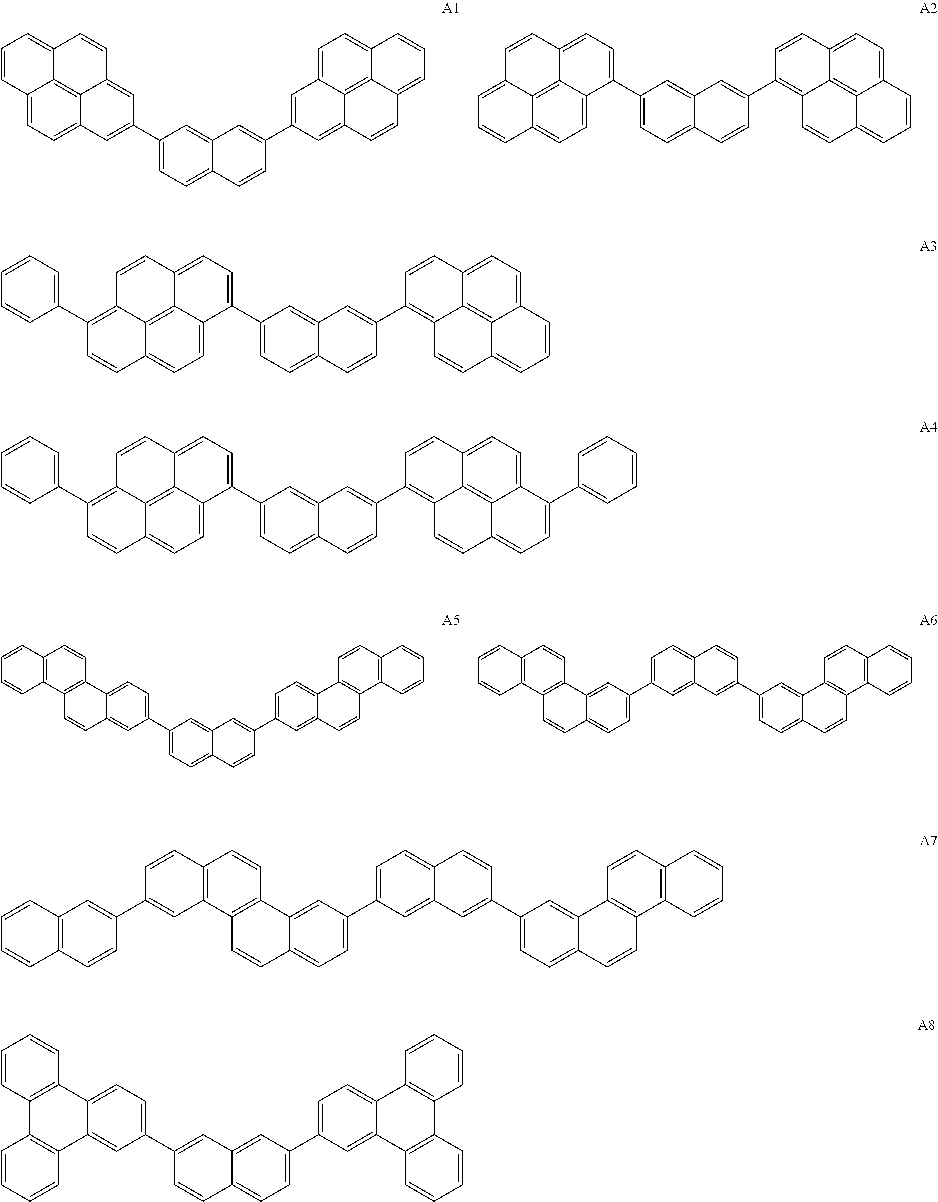

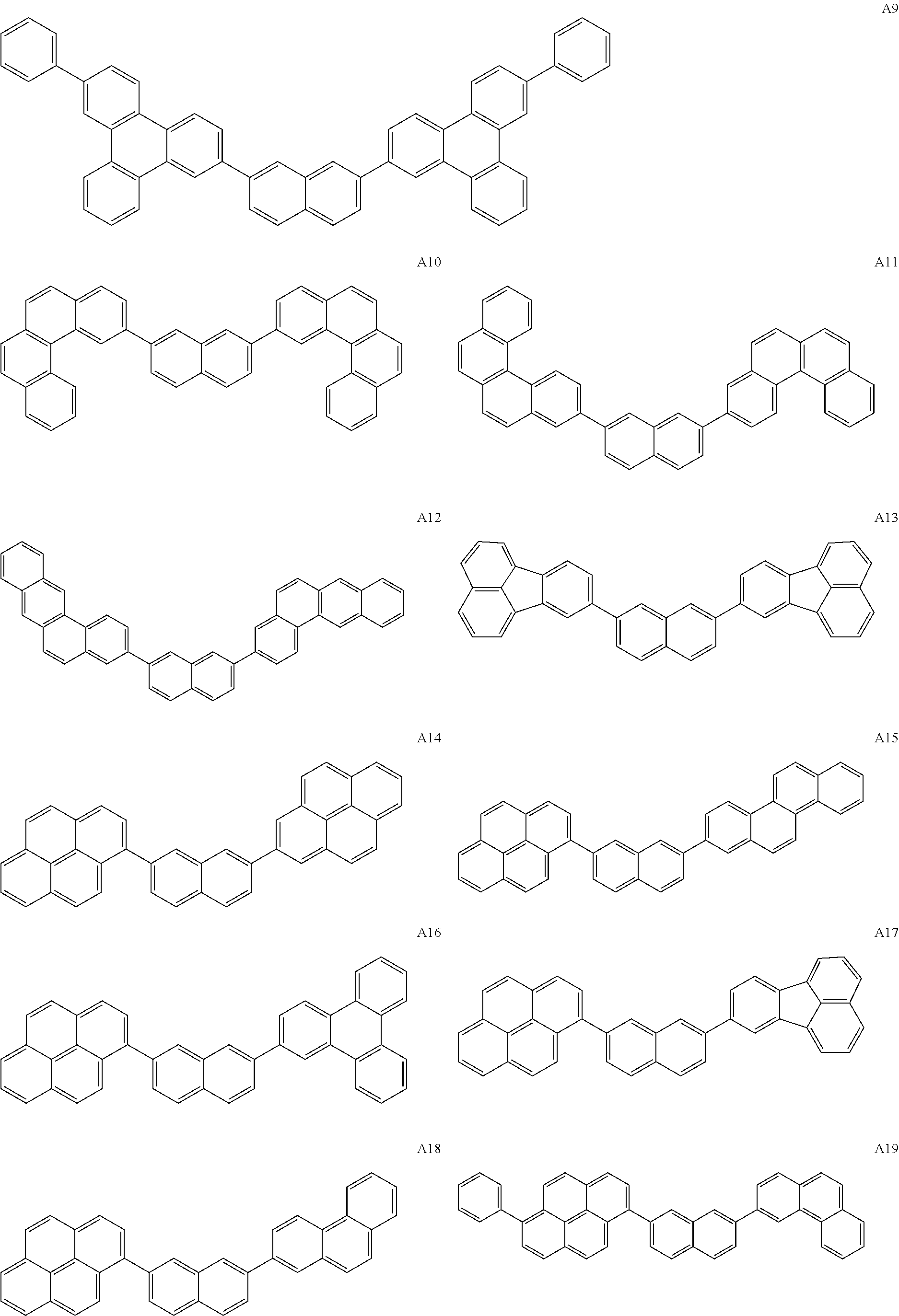

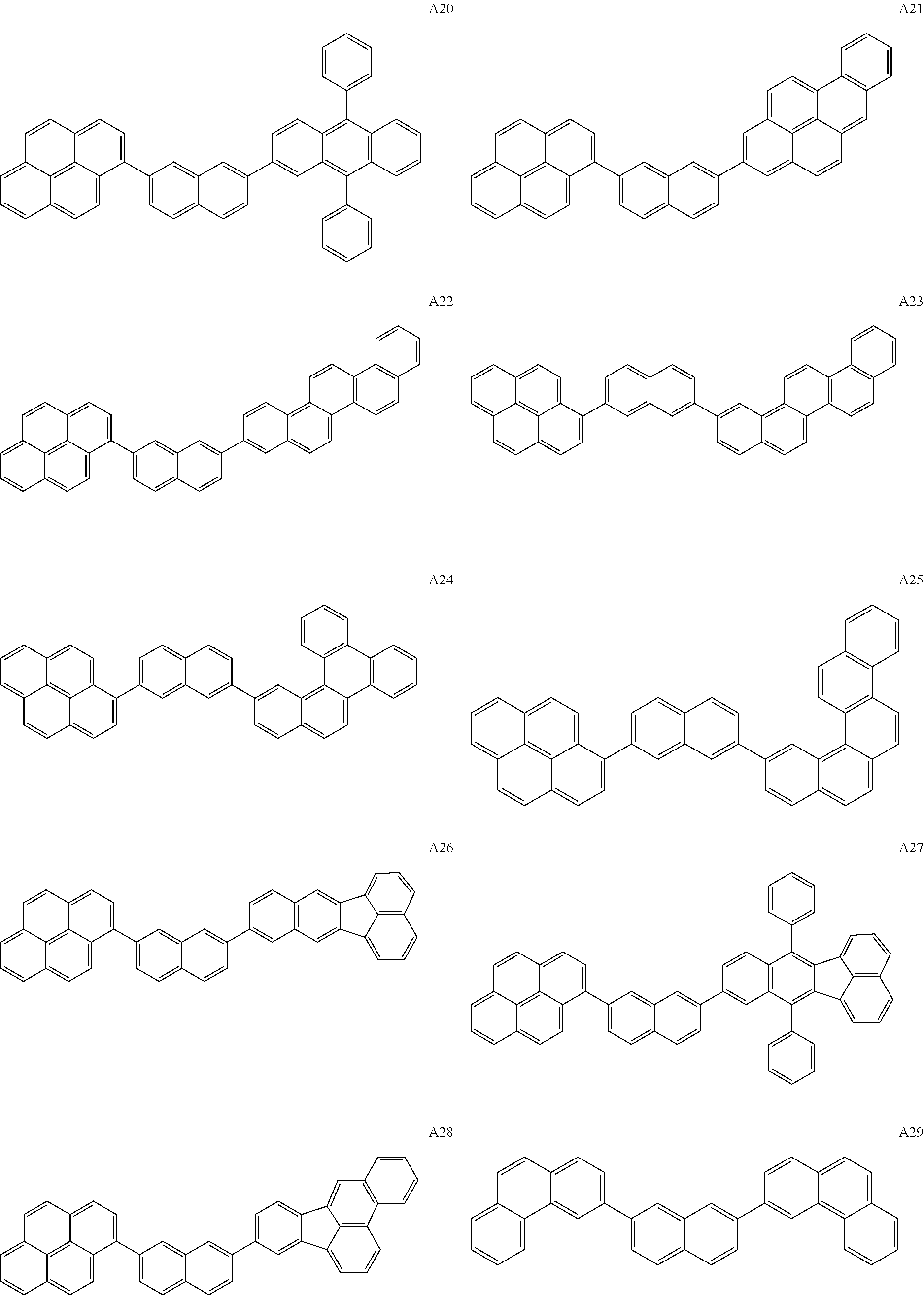

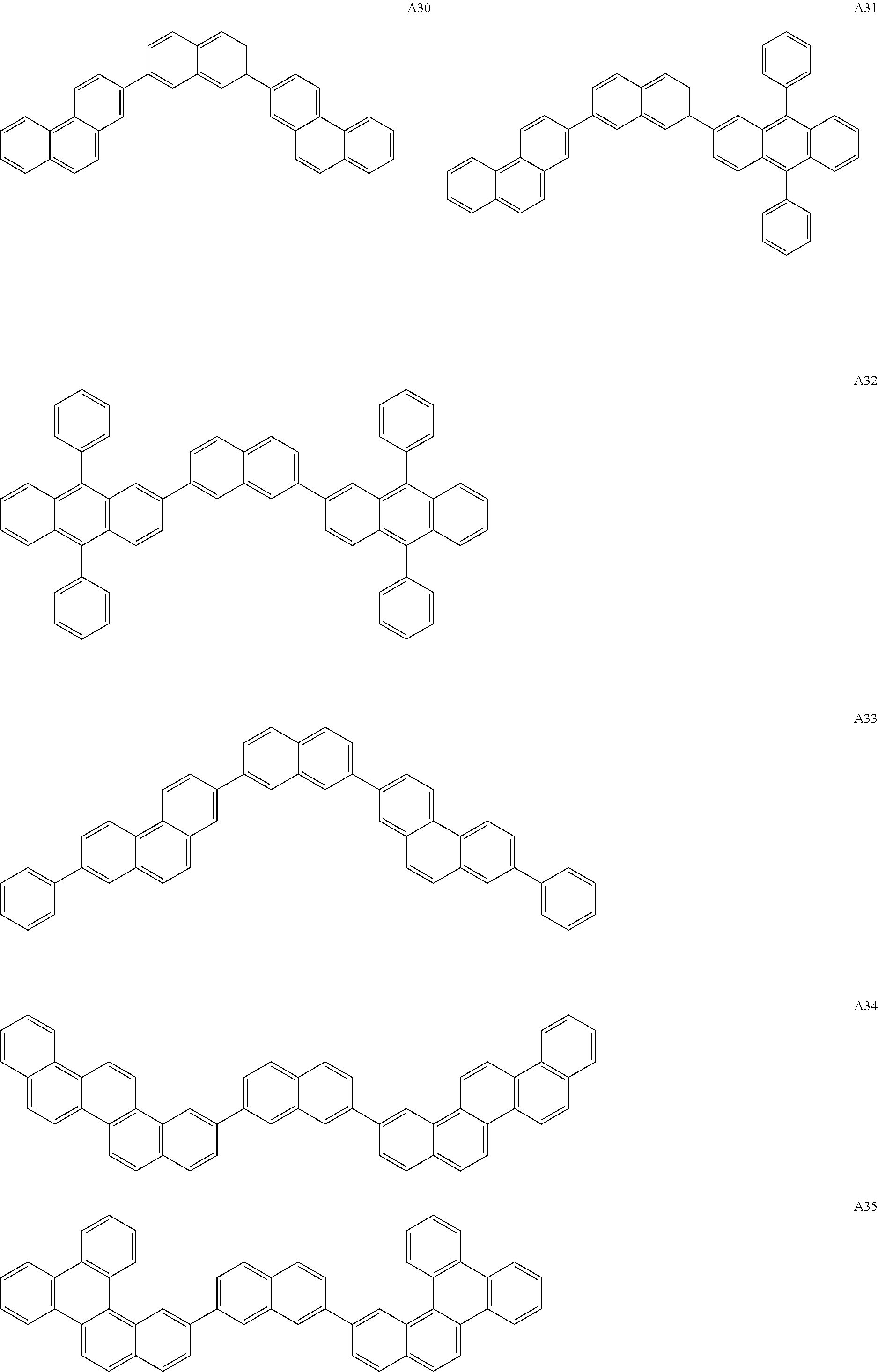

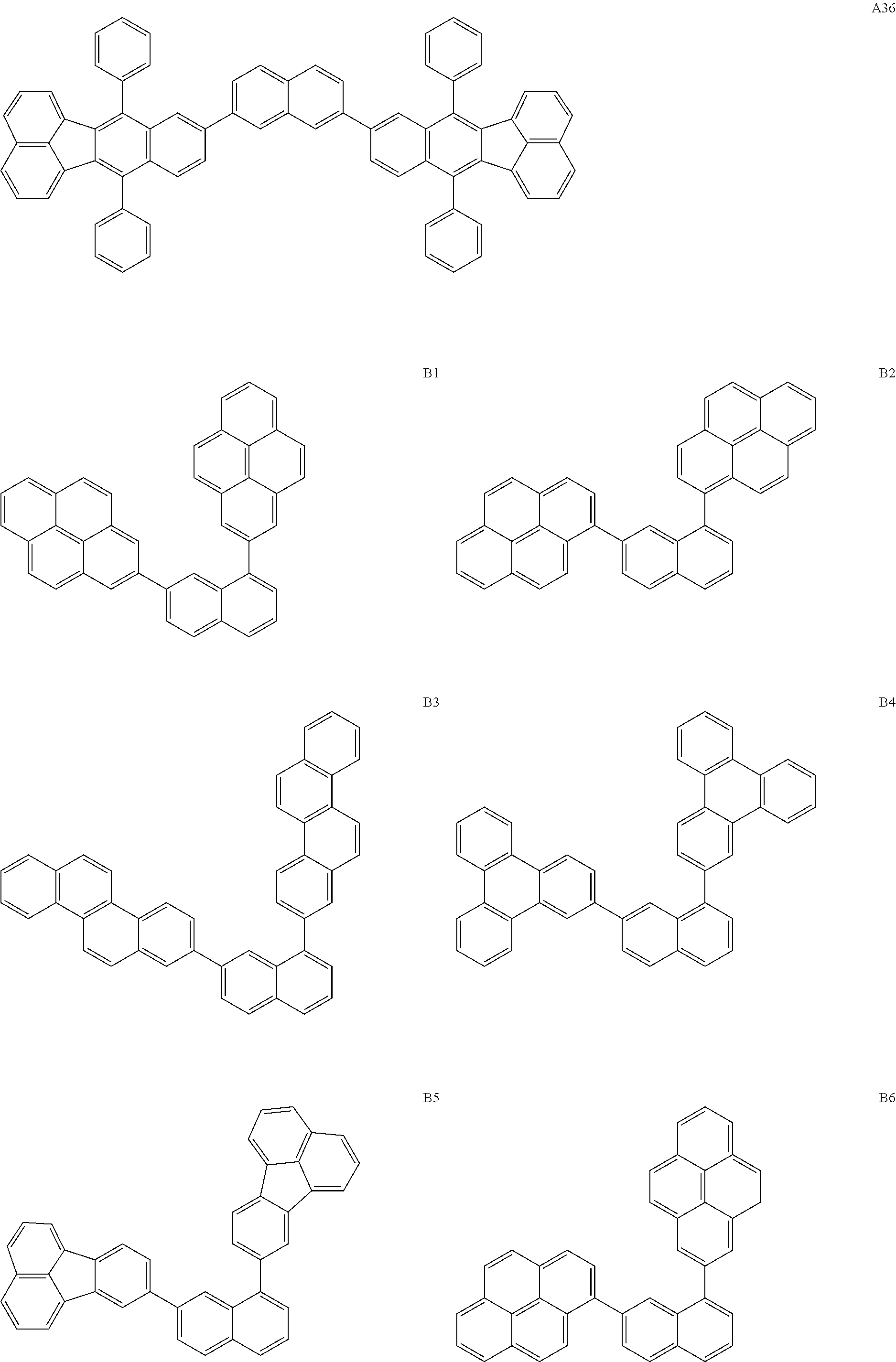

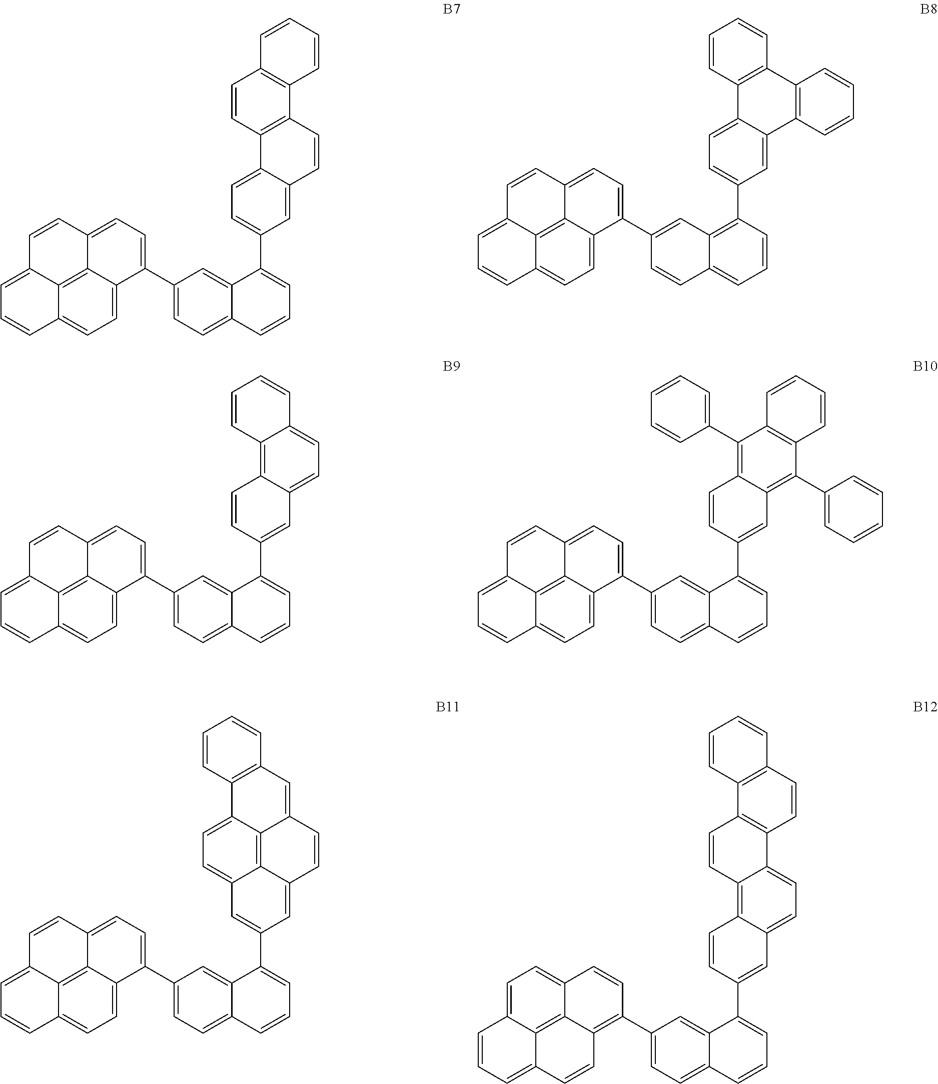

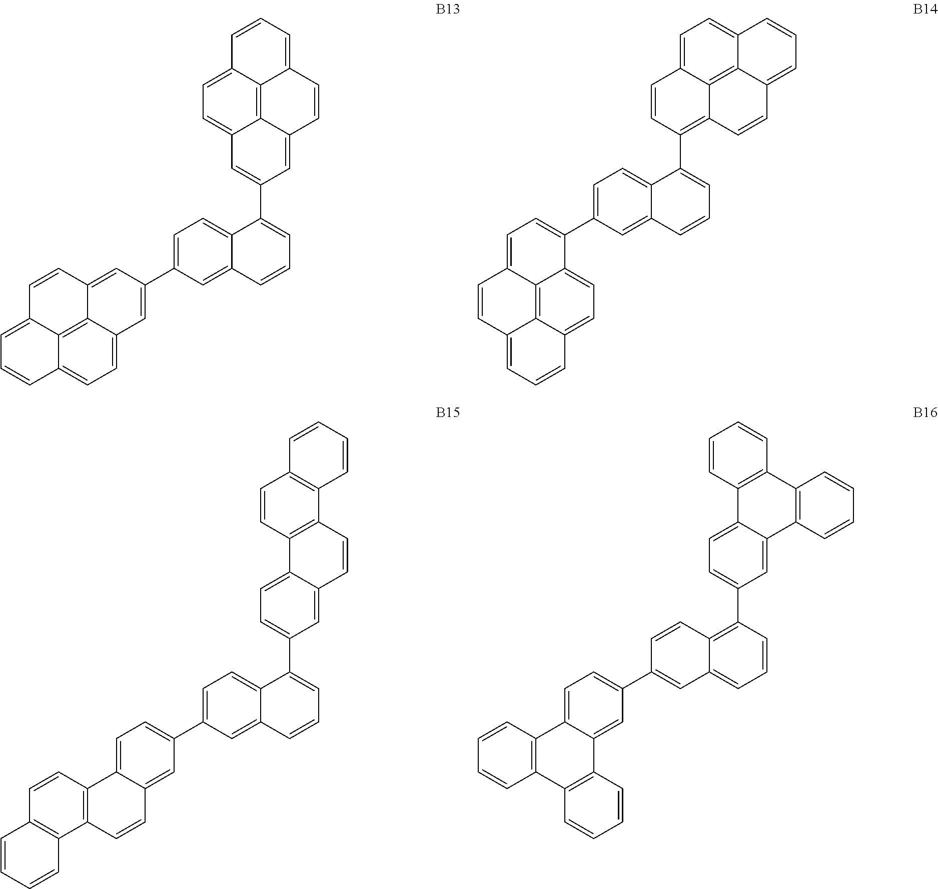

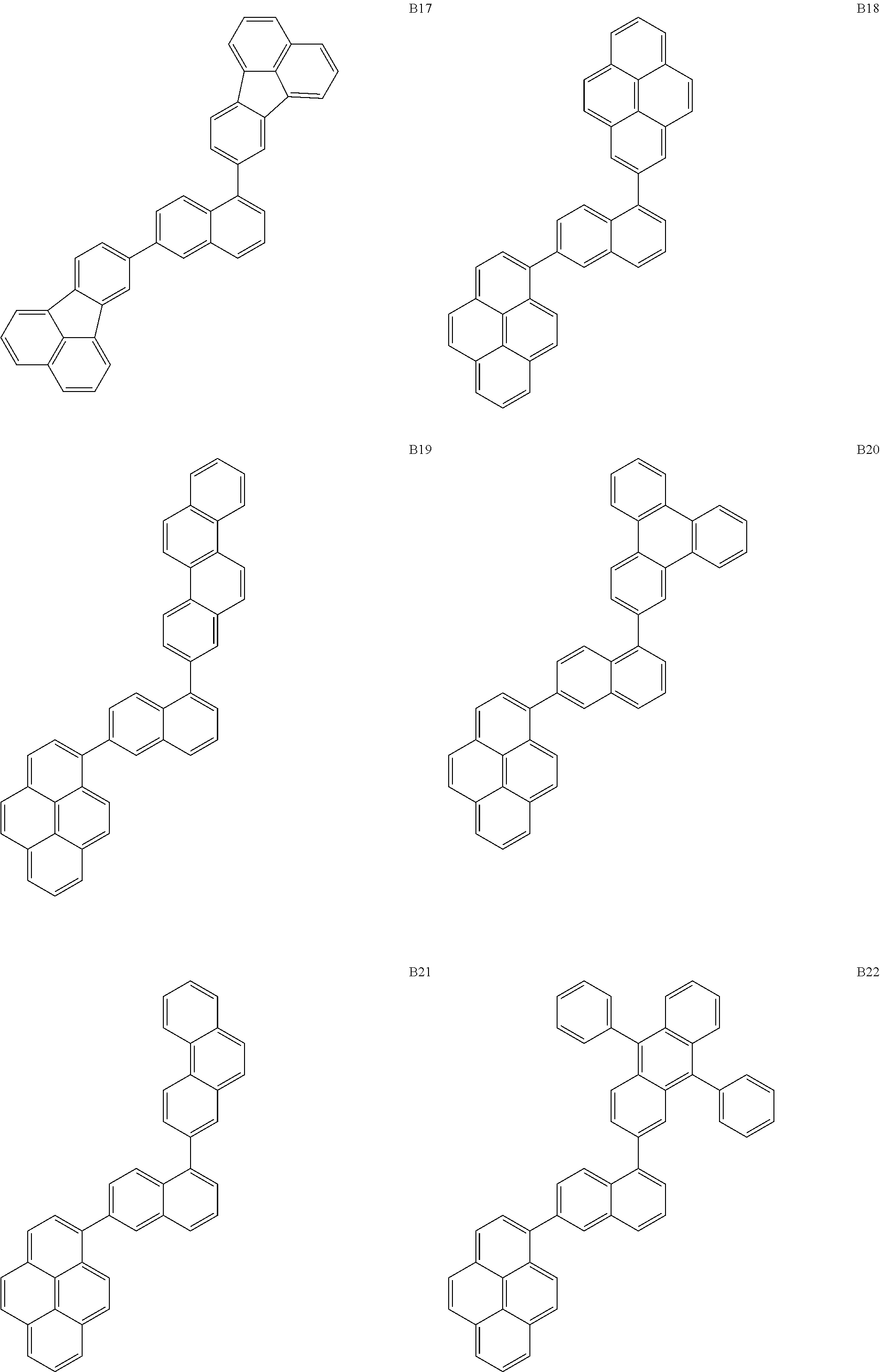

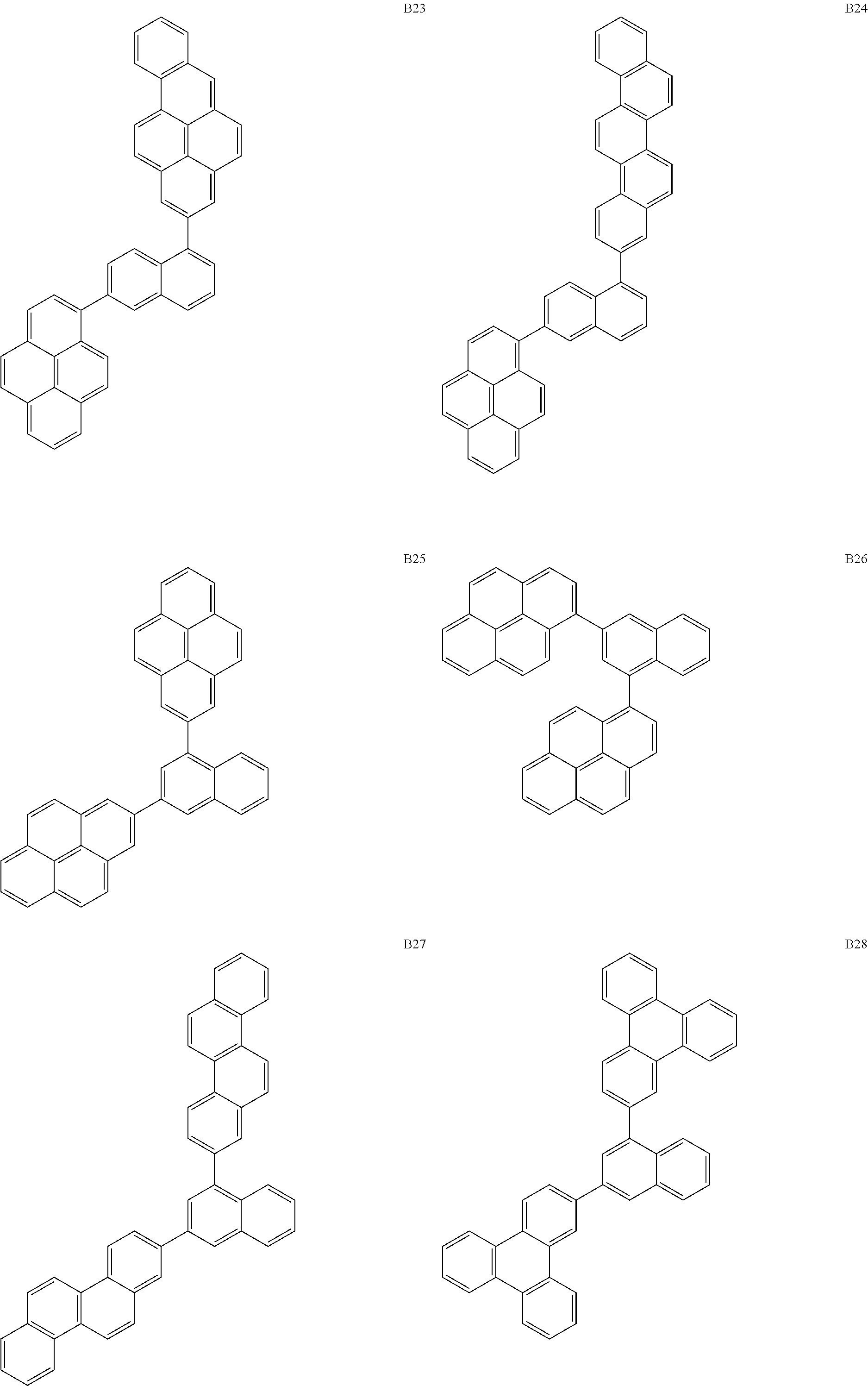

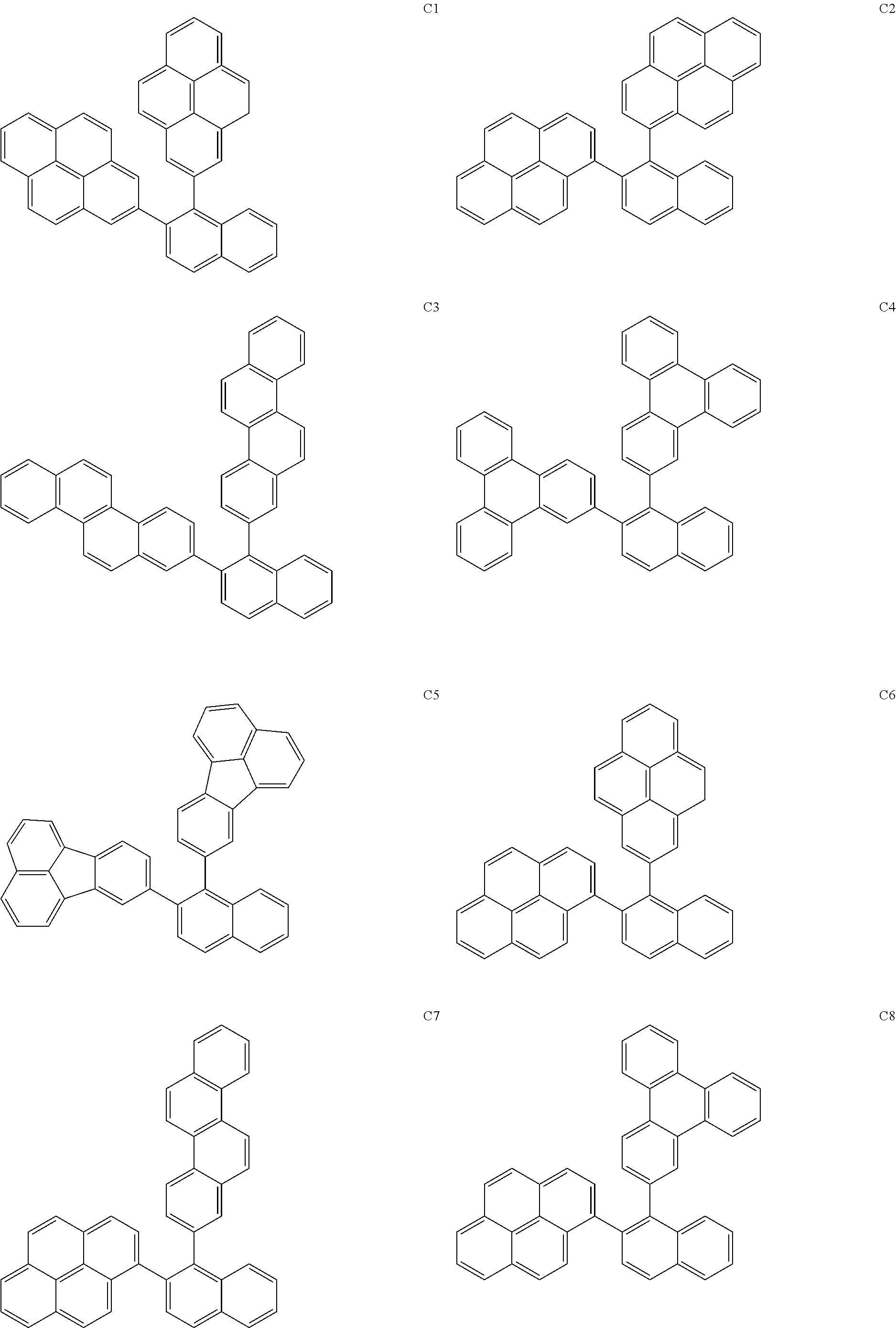

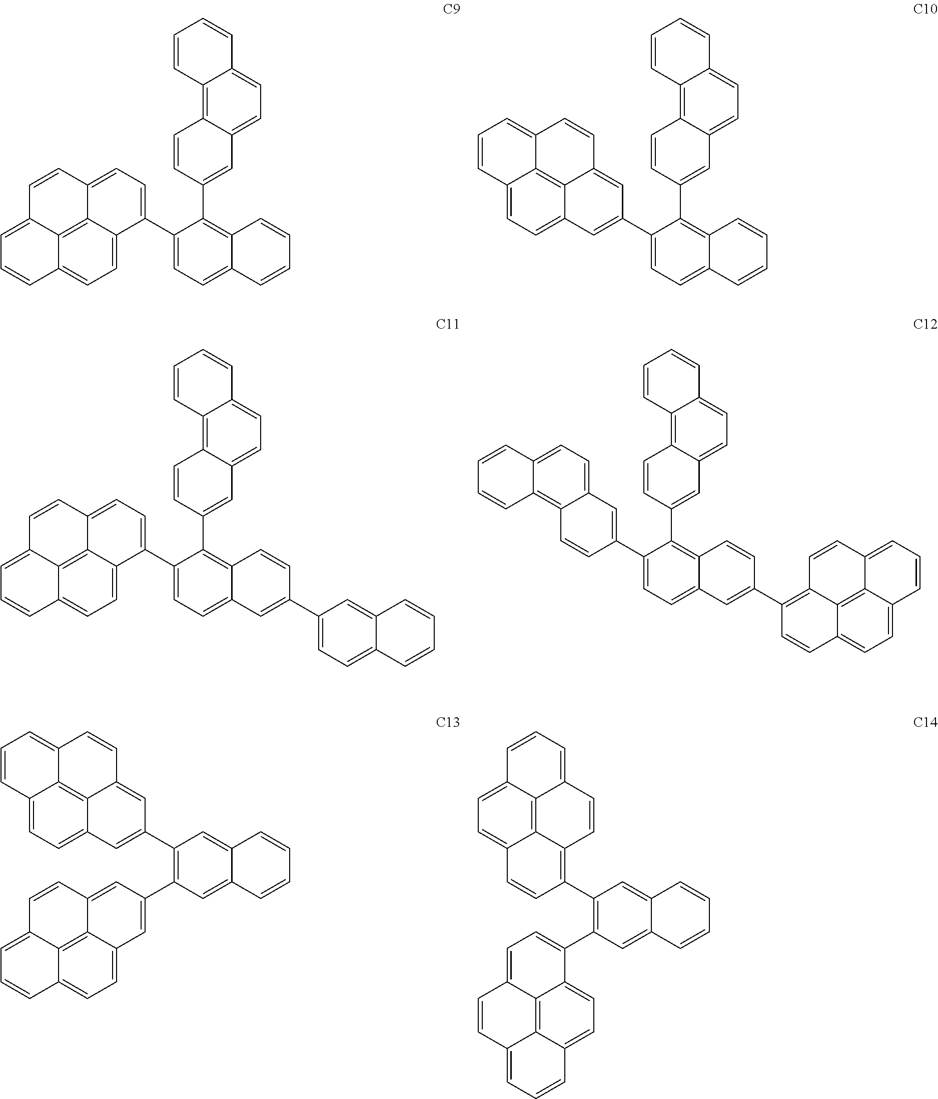

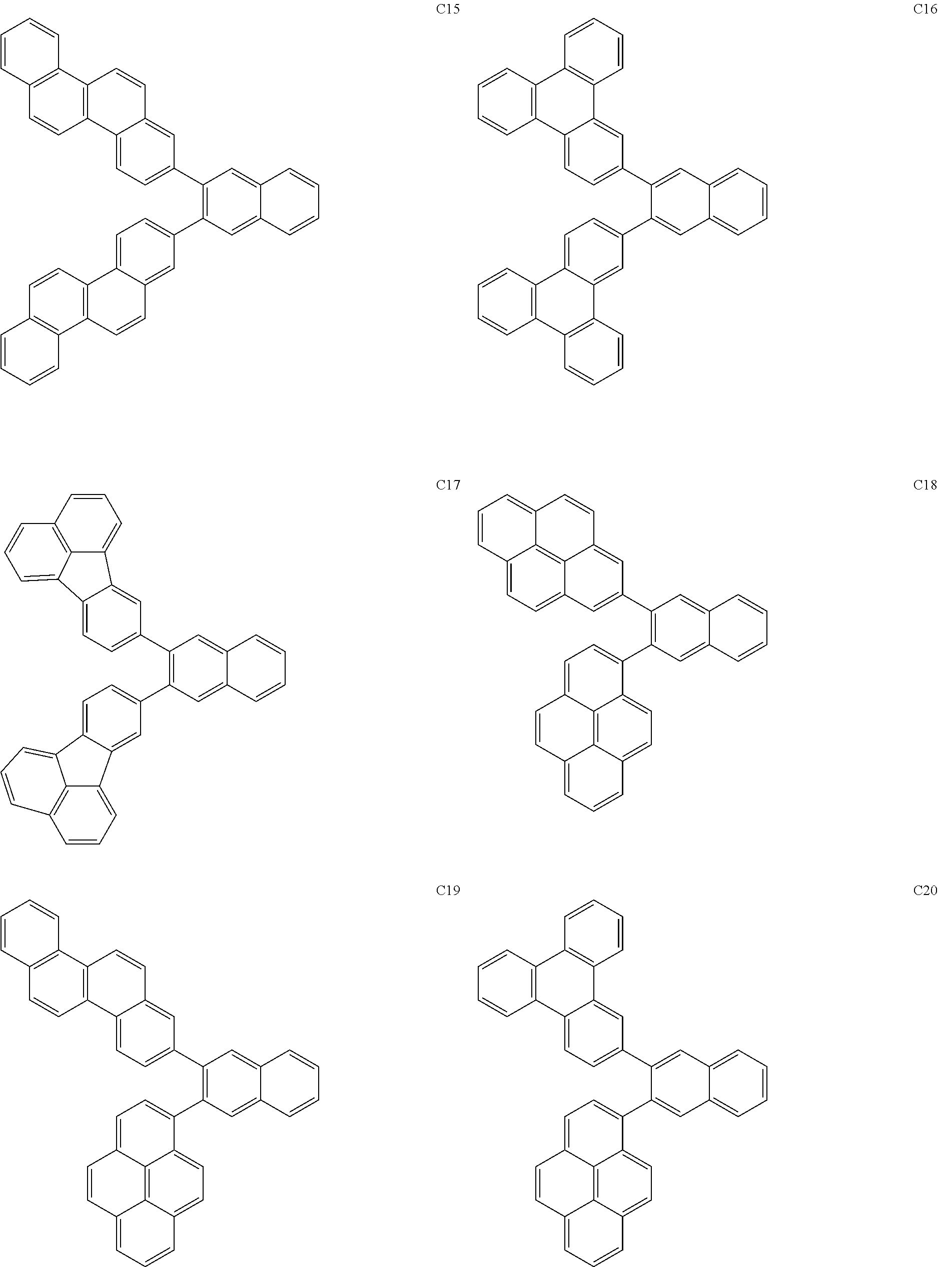

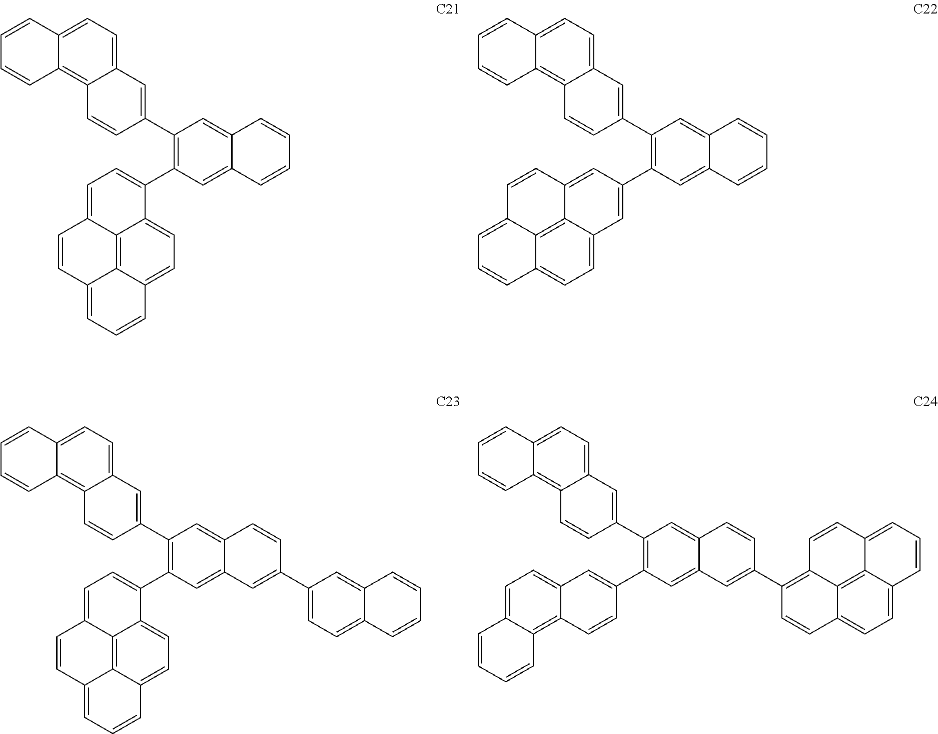

Exemplified compounds belonging to group A are organic compounds represented by general formula [1-3]. Among the compounds according to the present embodiment, the compounds belonging to group A have higher planarity and higher compatibility with the first organic compound layer.

That is, group A is a group of compounds having better durability characteristics when used in an organic light-emitting device. In addition, A1 to A28 are a group of compounds having a fused-ring skeleton having four rings, and it is easy to adjust compatibility with the first organic compound layer.

Exemplified compounds belonging to group B are organic compounds represented by formulae [1-2], [1-4], and [1-5]. Among the compounds according to the present embodiment, the compounds belonging to group B have low molecular symmetry and thus have high solubility in an organic solvent, and the purity thereof is easily improved by purification. That is, group B is a group of compounds that easily provide good durability characteristics when used in an organic light-emitting device.

Exemplified compounds belonging to group C are organic compounds represented by general formulae [1-1] and [1-6]. Among the compounds according to the present embodiment, the compounds belonging to group C have bulkier molecular structures and higher glass transition temperatures. That is, group C is a group of compounds that, when used in an organic light-emitting device, can provide uniform light emission characteristics even when driven for a longer period of time.

### <4> Compound Contained in First Organic Compound Layer

As described in the section <2>, when the compound contained in the first organic compound layer adjacent to the light-emitting layer on the cathode side has at least one fused polycyclic hydrocarbon skeleton having three or more rings and five or less rings, the compatibility with the host material in the light-emitting layer is improved to improve the durability characteristics of the organic light-emitting device. The compound contained in the first organic compound layer is preferably a compound having at least one fused polycyclic hydrocarbon skeleton having four rings. In addition, the compound having at least one fused polycyclic hydrocarbon skeleton having three or more rings and five or more rings is preferably a hydrocarbon.

Specific examples of the compound having at least one fused polycyclic hydrocarbon skeleton having three or more rings and five or less rings are illustrated below. However, these compounds are merely specific examples, and the present invention is not limited thereto. In addition, the compound represented by any of general formulae [1-1] to [1-6] may be used in the first organic compound layer adjacent to the light-emitting layer on the cathode side.

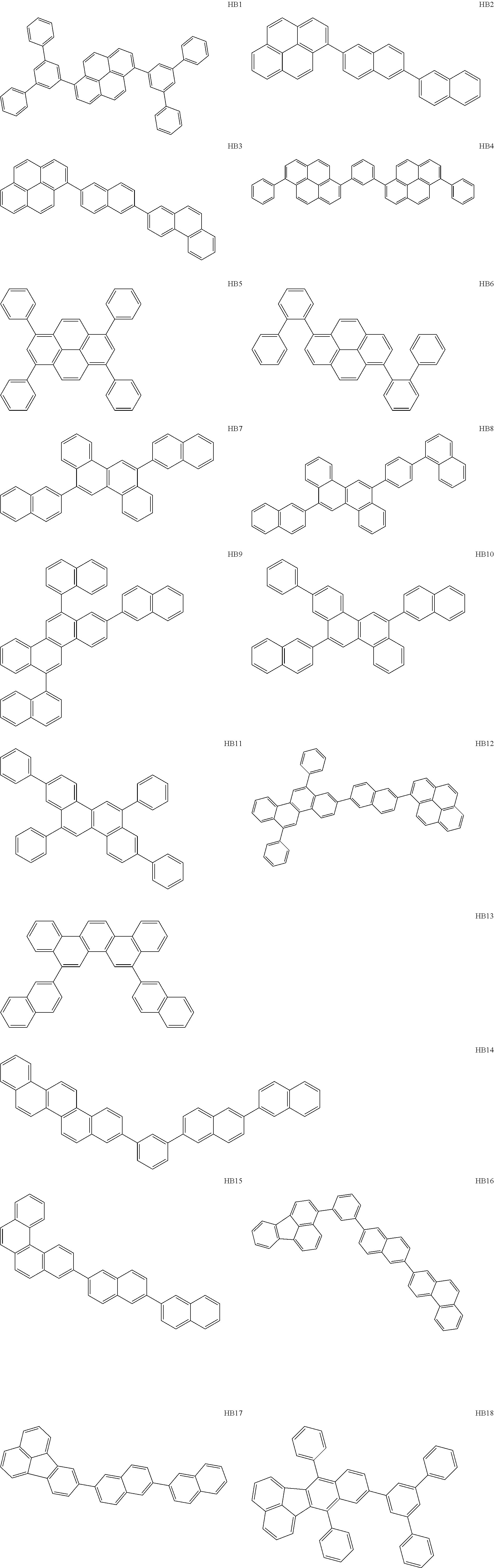

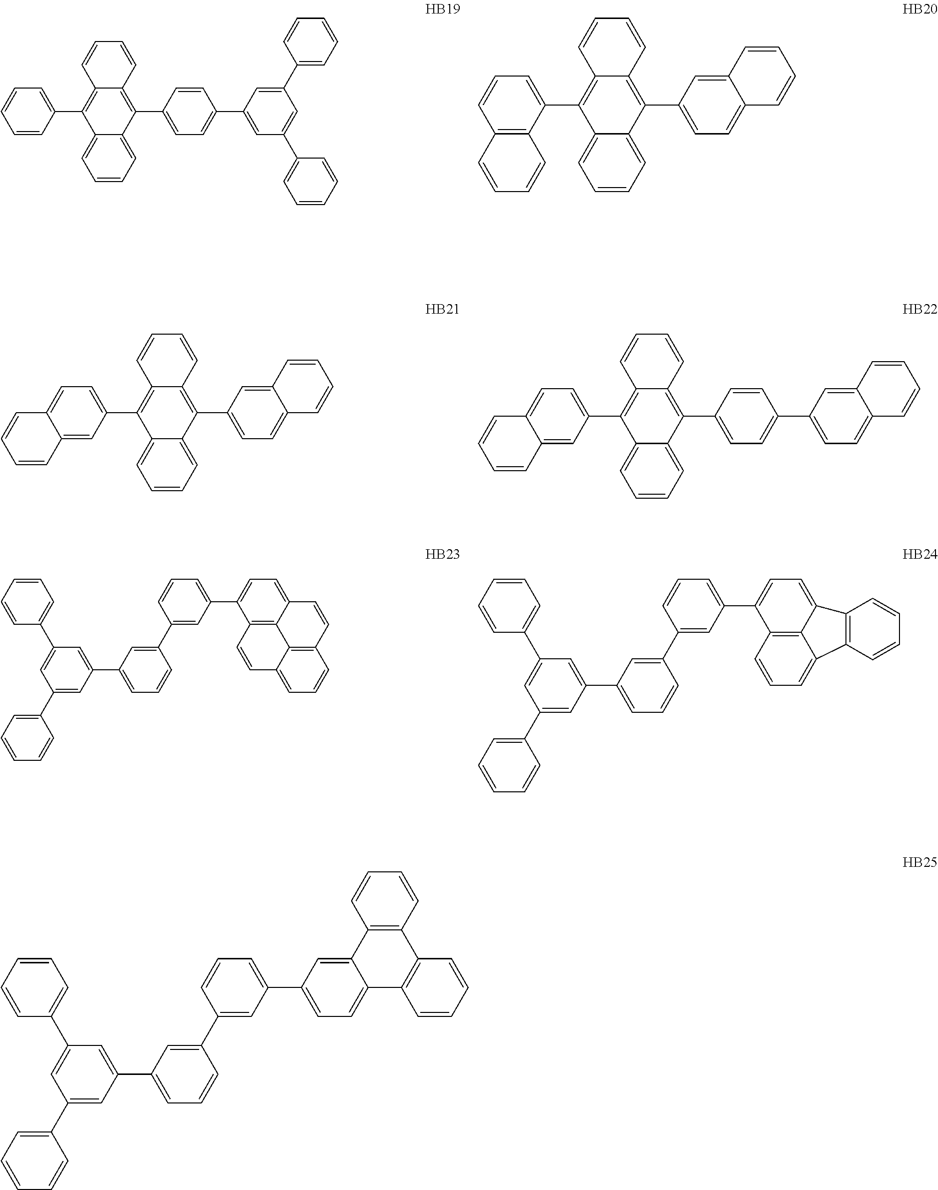

### <5> Guest Material

The guest material is a light-emitting material containing a fluoranthene skeleton, preferably a hydrocarbon containing a fluoranthene skeleton. As described above, the light-emitting material containing a fluoranthene skeleton is characterized by having low HOMO and LUMO energies (far from the vacuum level) due to containing an electron-deficient five-membered ring. Accordingly, the light-emitting material itself is stable against oxidation and reaction, and the effect of improving the electron-trapping properties when used as an organic light-emitting device can be provided. Therefore, an organic EL device having excellent durability characteristics can be provided.

To impart sufficient electron-trapping properties, the compound preferably has a partial structure containing two or more fluoranthene skeletons. This is because the LUMO energy is lower (farther from the vacuum level) by further adding a fluoranthene skeleton containing an electron-deficient five-membered ring. Thereby, the difference in LUMO energy with respect to the host material is larger, and the electron-trapping properties can be further improved.

Specific examples of a partial structure containing two or more fluoranthene skeletons are illustrated below. However, these partial structures are merely specific examples, and the present invention is not limited thereto. The fluoranthene skeletons may be fused to each other by, for example, as in FF1, allowing benzene rings in the fluoranthene skeletons to form a fused ring, by, for example, as in FF8, allowing benzene rings other than the benzene rings in the fluoranthene skeletons to form a fused ring, or by, for example, as in FF17, allowing benzene rings in the fluoranthene skeletons to be bonded together to form a fused ring. The fluoranthene skeletons may share a benzene ring forming the fluoranthene skeletons, for example, as in FF5 and FF11.

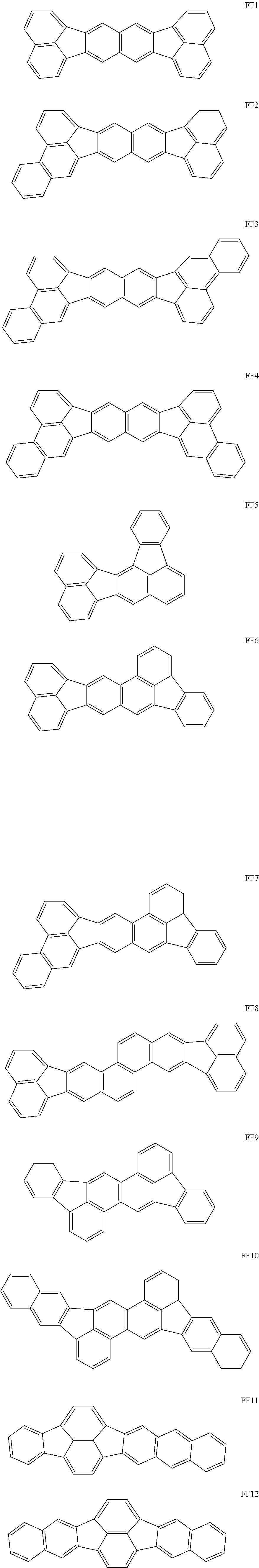

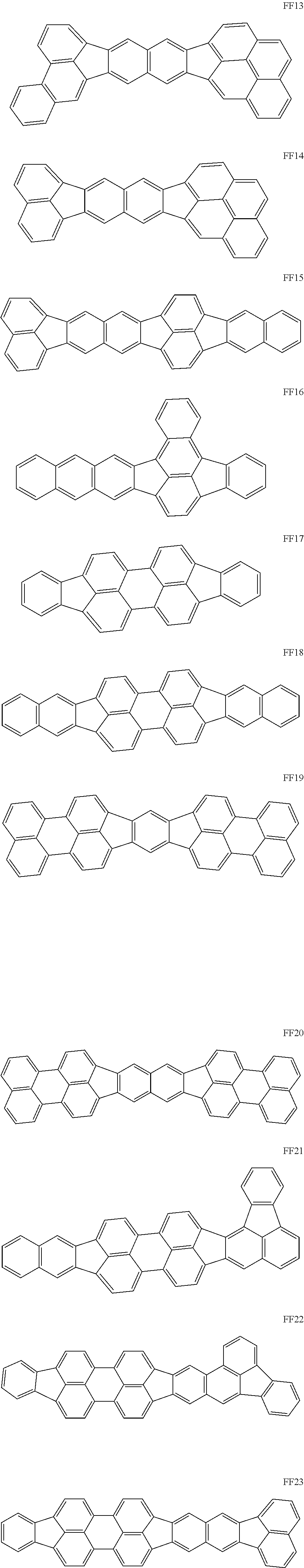

Specific examples of the guest material that emits blue light will be illustrated below. However, these compounds are merely specific examples, and the guest material is not limited thereto. Among the following blue light-emitting guest materials, a structure whose carbon atoms are SP² carbon atoms only is particularly preferable.

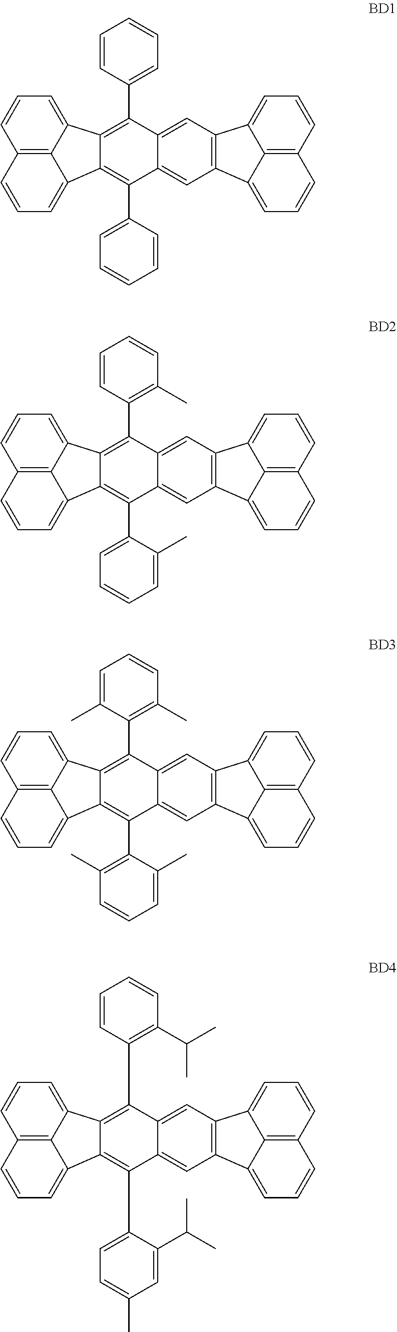

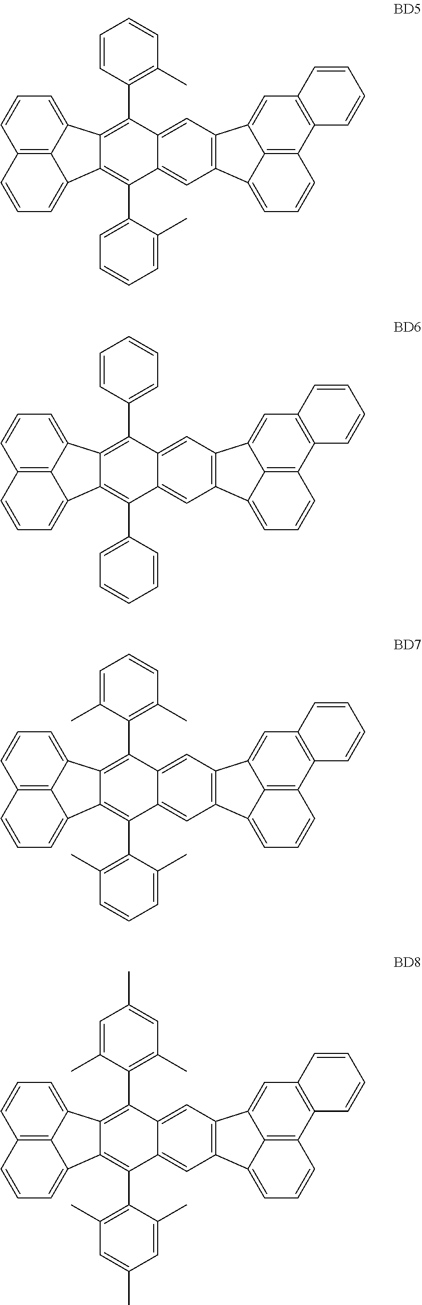

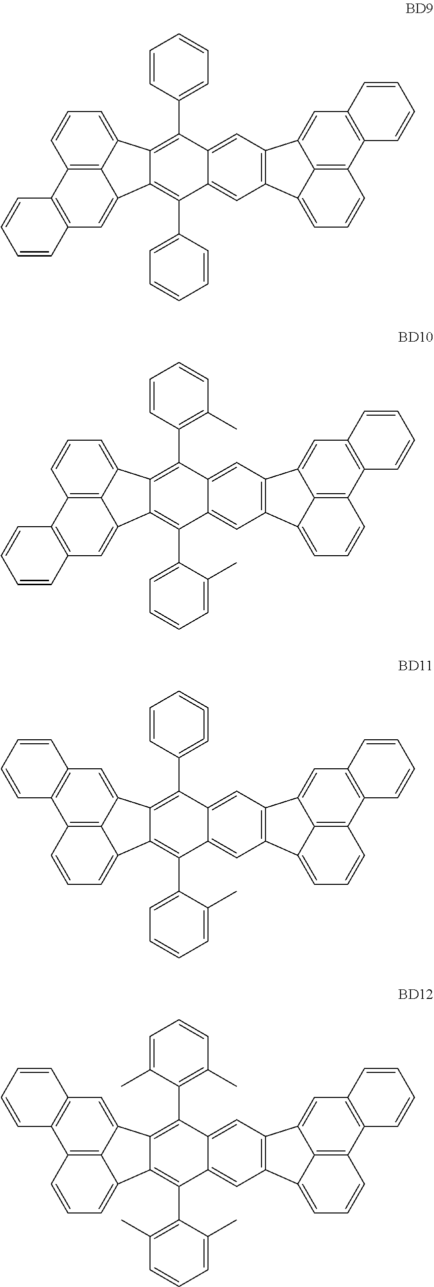

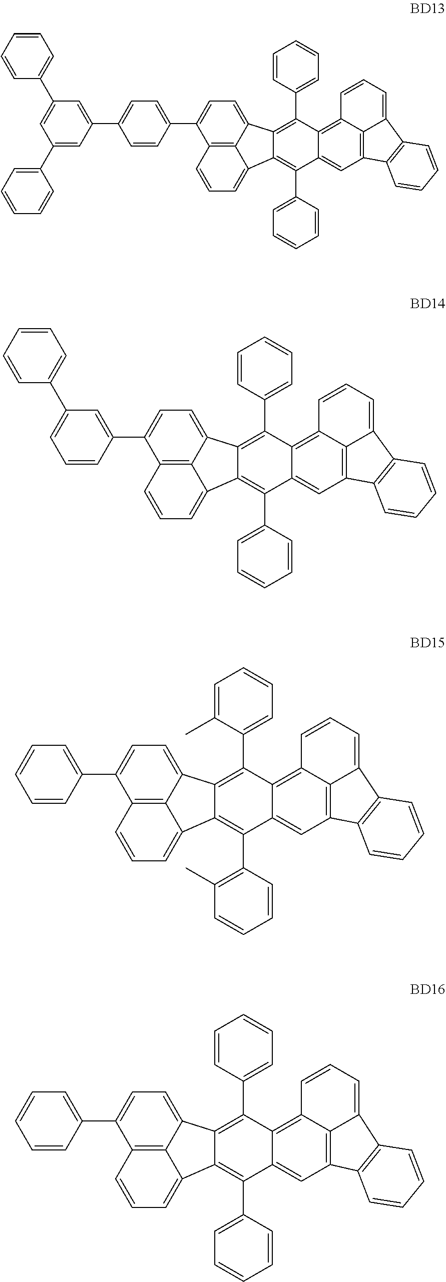

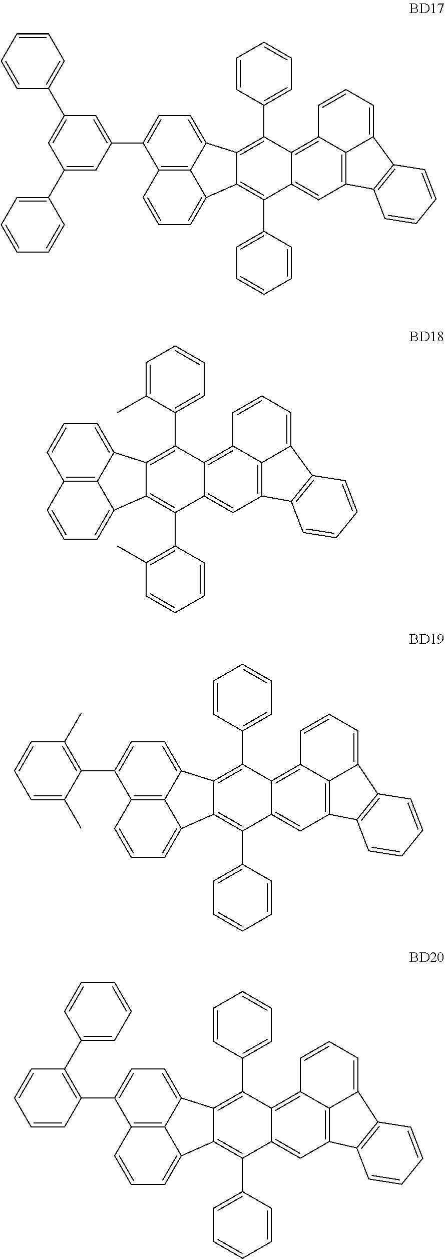

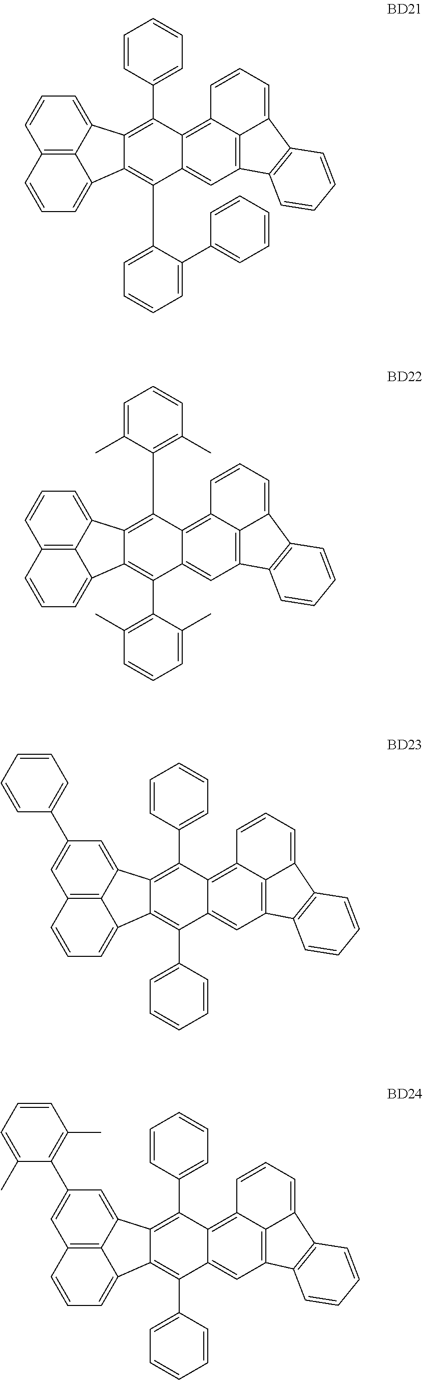

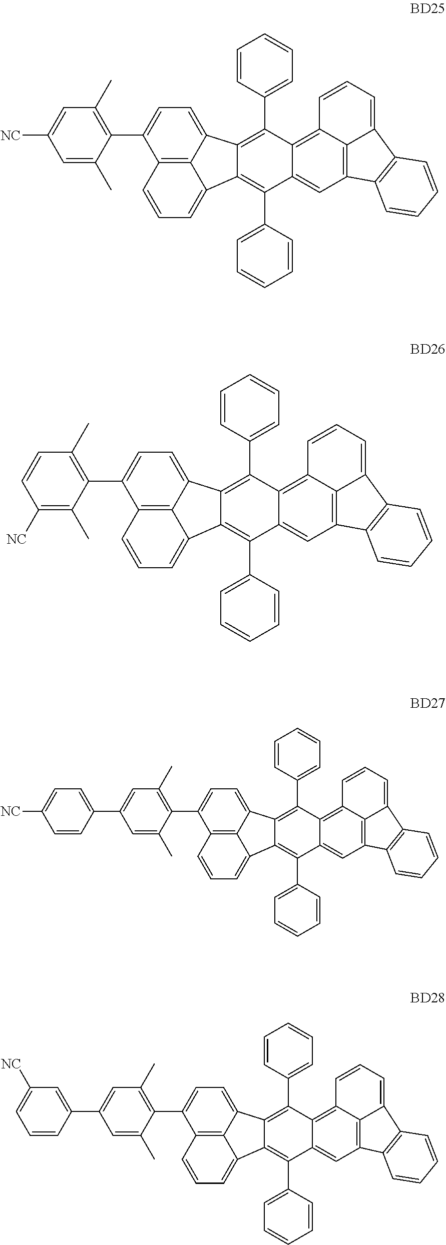 [SMILES: Cc1cc(C#N)cc(C)c1-c1ccc2c3c(-c4ccccc4)c4c(cc5c6ccccc6c6cccc4c65)c(-c4ccccc4)c3c3cccc1c32 ; Cc1ccc(C#N)c(C)c1-c1ccc2c3c(-c4ccccc4)c4c(cc5c6ccccc6c6cccc4c65)c(-c4ccccc4)c3c3cccc1c32 ; Cc1cc(-c2ccc(C#N)cc2)cc(C)c1-c1ccc2c3c(-c4ccccc4)c4c(cc5c6ccccc6c6cccc4c65)c(-c4ccccc4)c3c3cccc1c32 ; Cc1cc(-c2cccc(C#N)c2)cc(C)c1-c1ccc2c3c(-c4ccccc4)c4c(cc5c6ccccc6c6cccc4c65)c(-c4ccccc4)c3c3cccc1c32]

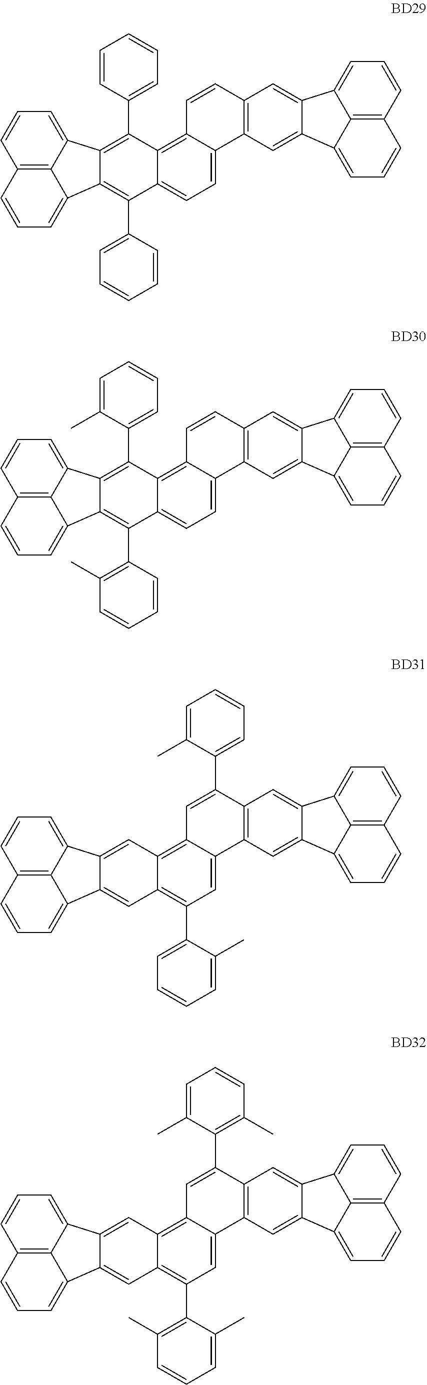

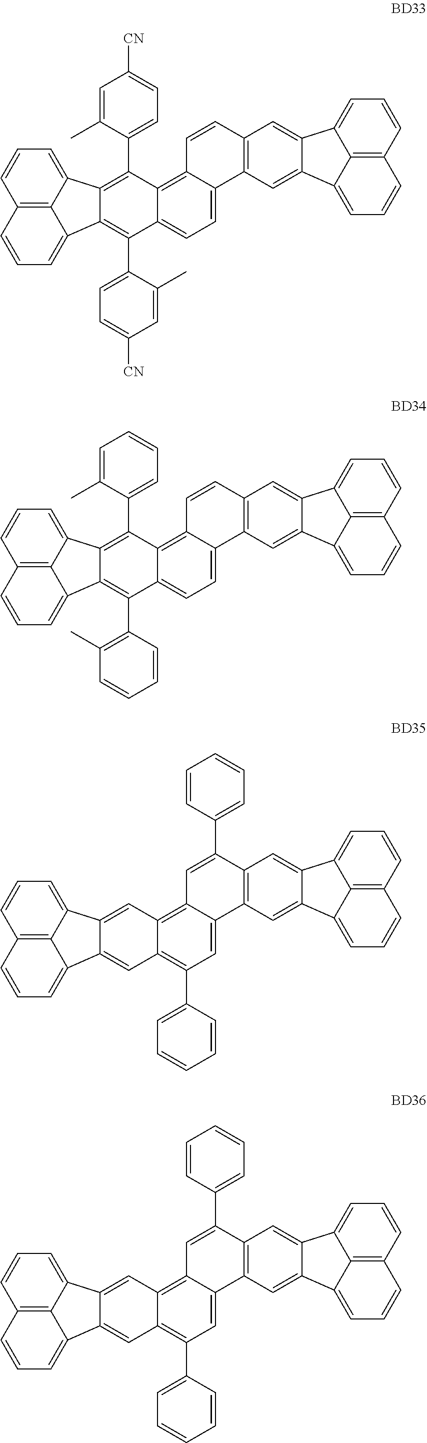

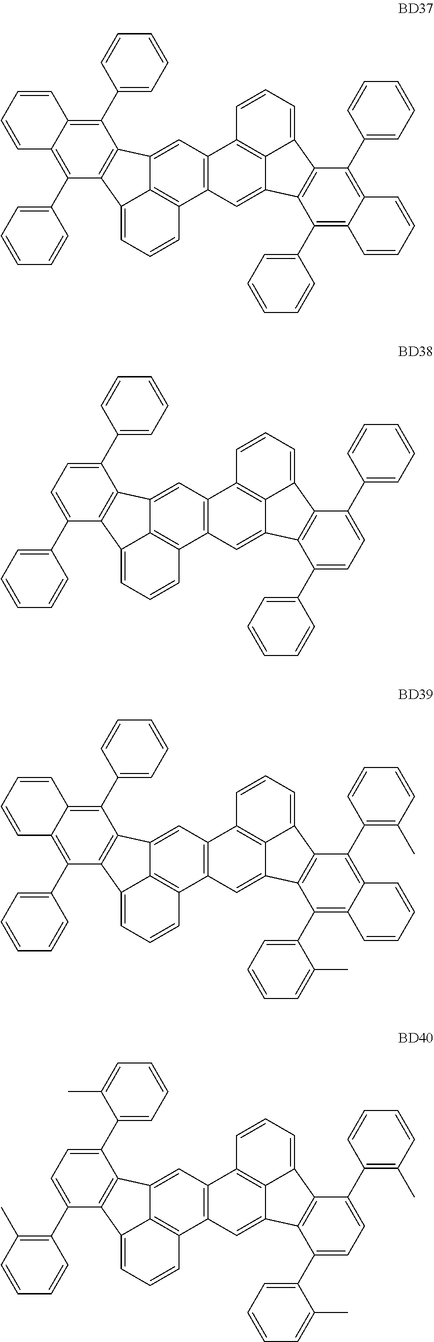

Specific examples of the guest material that emits green light will be illustrated below. However, these compounds are merely specific examples, and the guest material is not limited thereto.

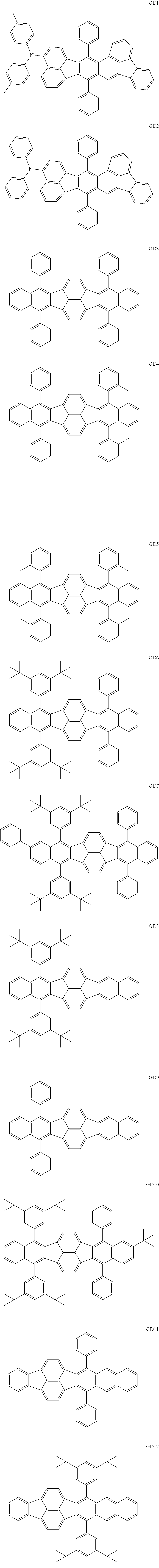

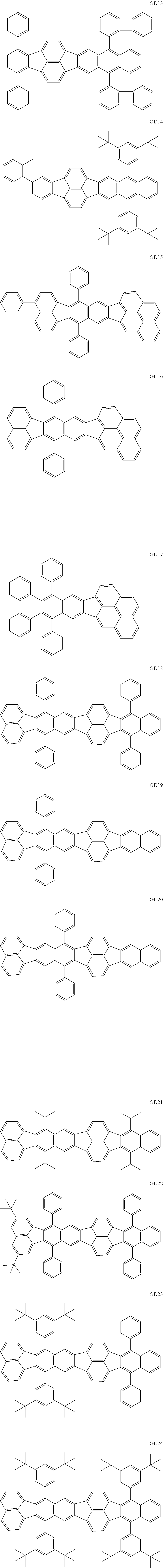

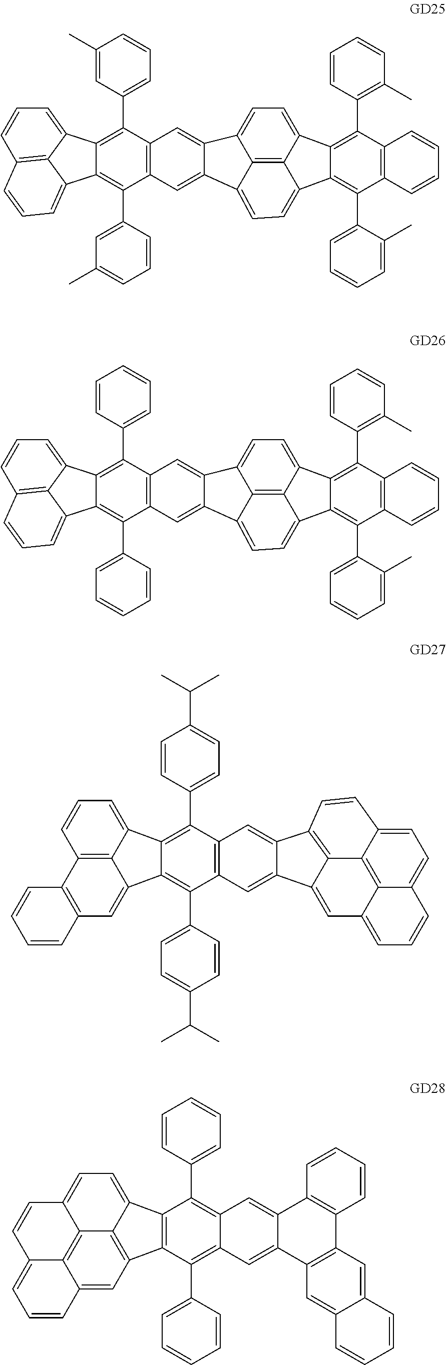

Specific examples of the guest material that emits red light will be illustrated below. However, these compounds are merely specific examples, and the guest material is not limited thereto. Among the following red-light-emitting guest materials, RD1 to RD26 each having a partial structure containing two or more fluoranthene skeletons are particularly preferred.

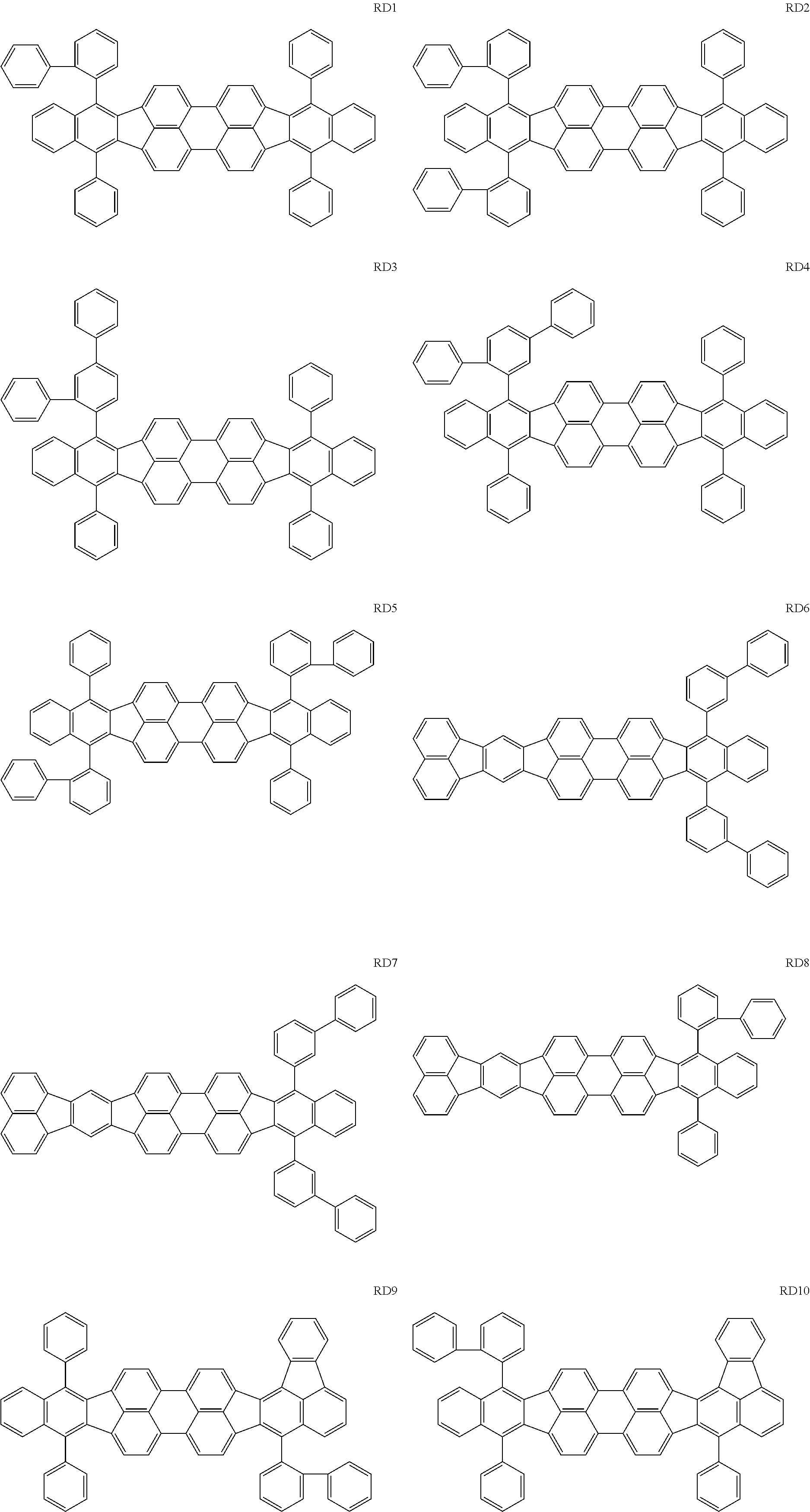

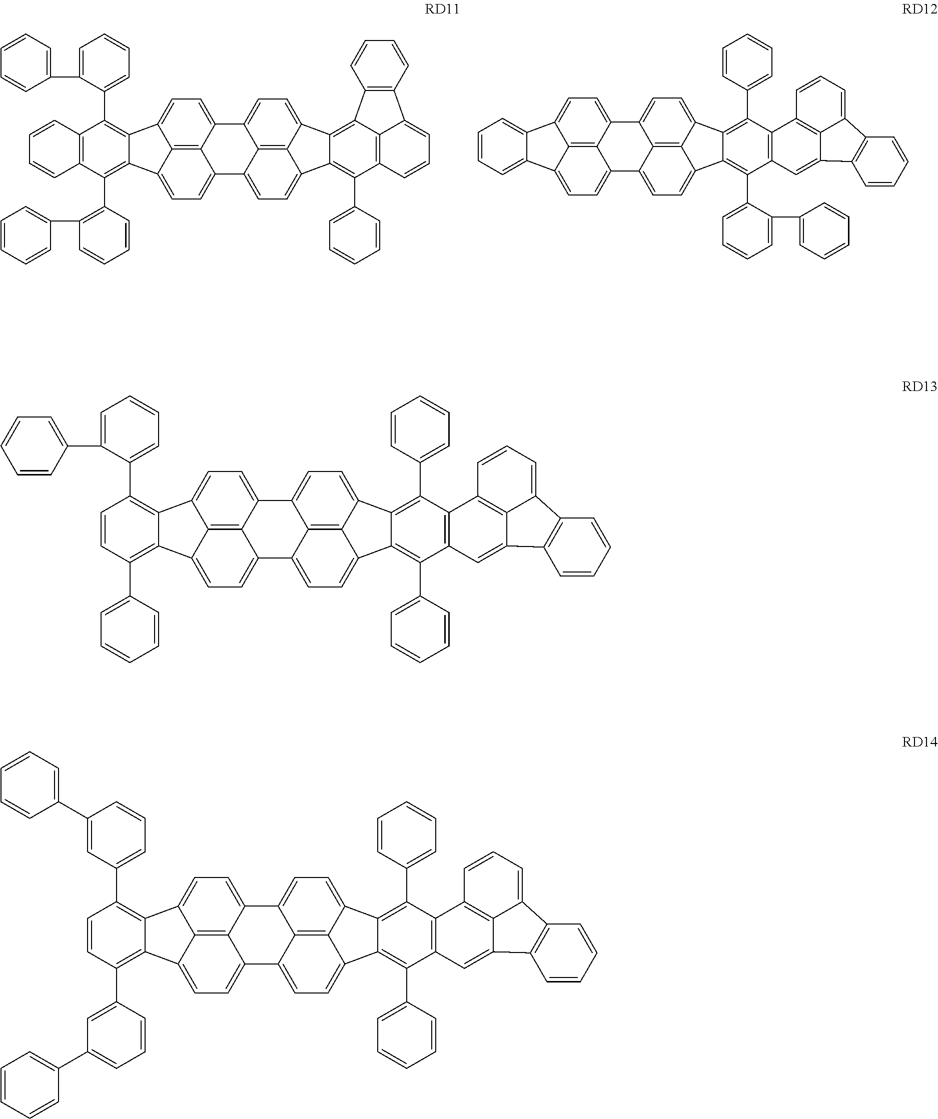

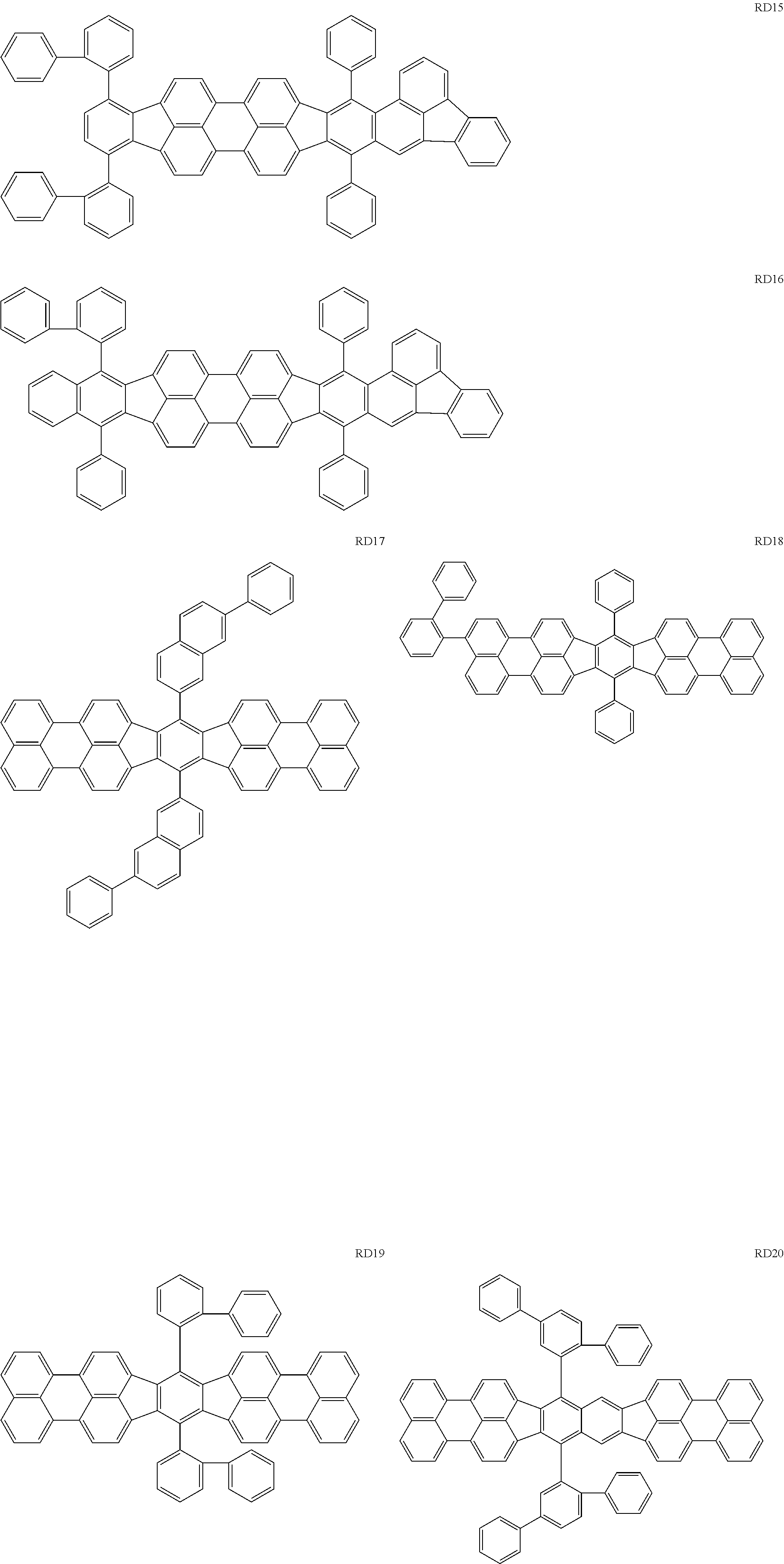

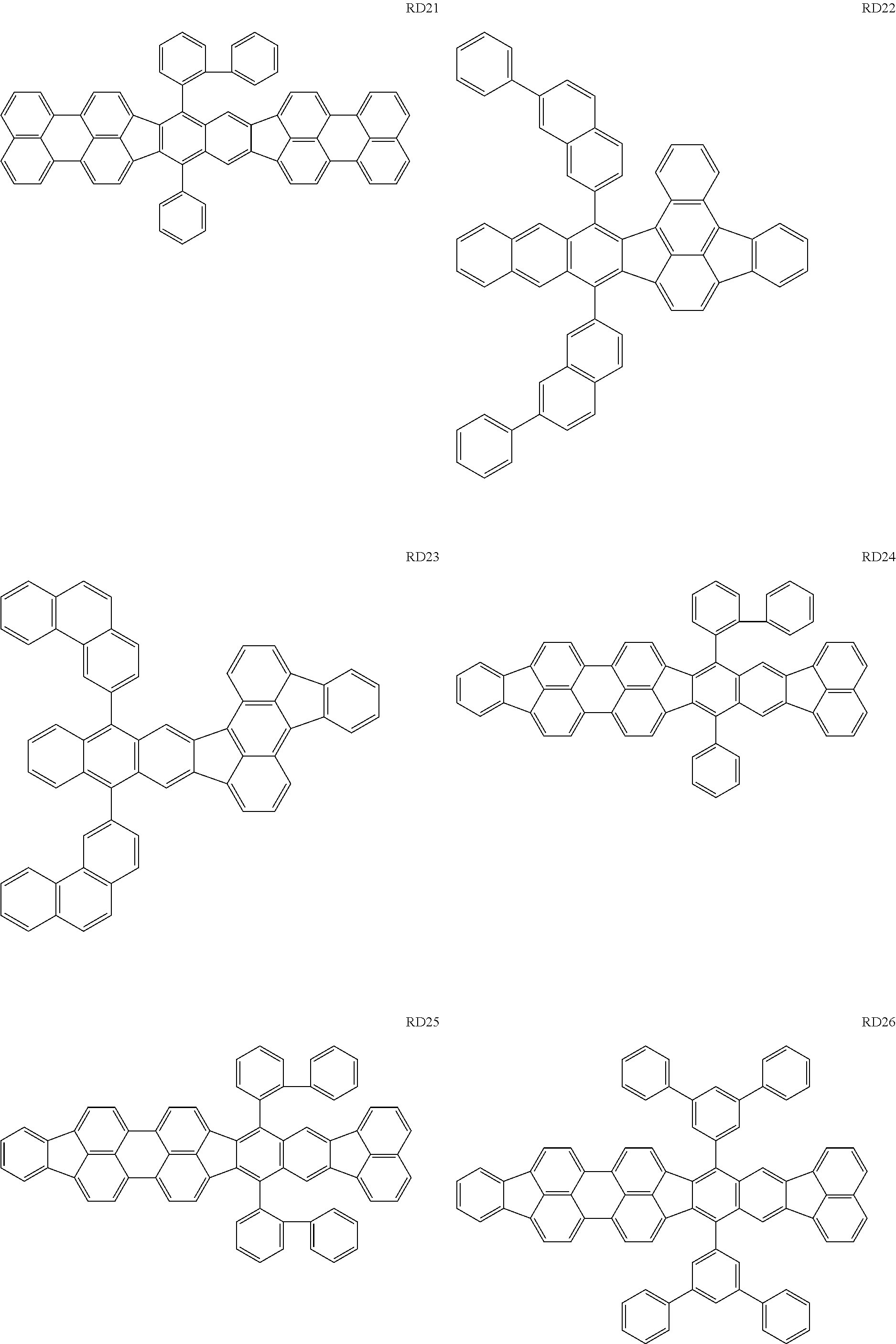

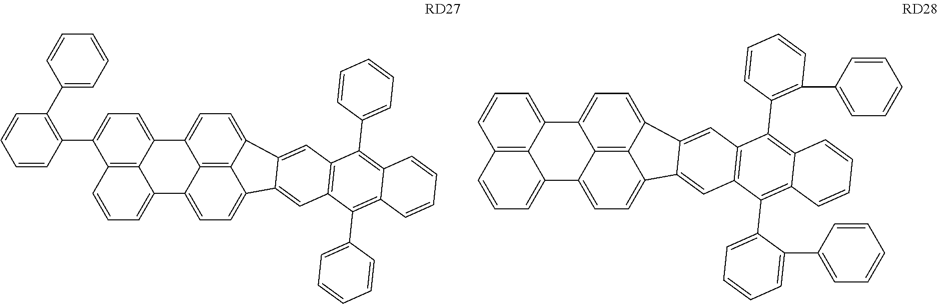

### <6> Other Materials for Organic Light-Emitting Device

For example, a hole injection compound, a hole transport compound, a compound to be used as a host, a light-emitting compound, an electron injection compound, or an electron transport compound, which is known and has a low or high molecular weight, can be used together with the above-described compounds, as needed. Examples of these compounds will be illustrated below.

As a hole injection-transport material, a material having a high hole mobility is preferably used so as to facilitate the injection of holes from the anode and to transport the injected holes to the light-emitting layer. To inhibit a deterioration in film quality, such as crystallization, in the organic light-emitting device, a material having a high glass transition temperature is preferred. Examples of a low- or high-molecular-weight material having the ability to inject and transport holes include triarylamine derivatives, aryl carbazole derivatives, phenylenediamine derivatives, stilbene derivatives, phthalocyanine derivatives, porphyrin derivatives, poly(vinyl carbazole), polythiophene, and other conductive polymers. Moreover, the hole injection-transport material is also suitably used for the electron-blocking layer. Specific examples of a compound used as the hole injection-transport material are illustrated below, but of course, the compound is not limited thereto.

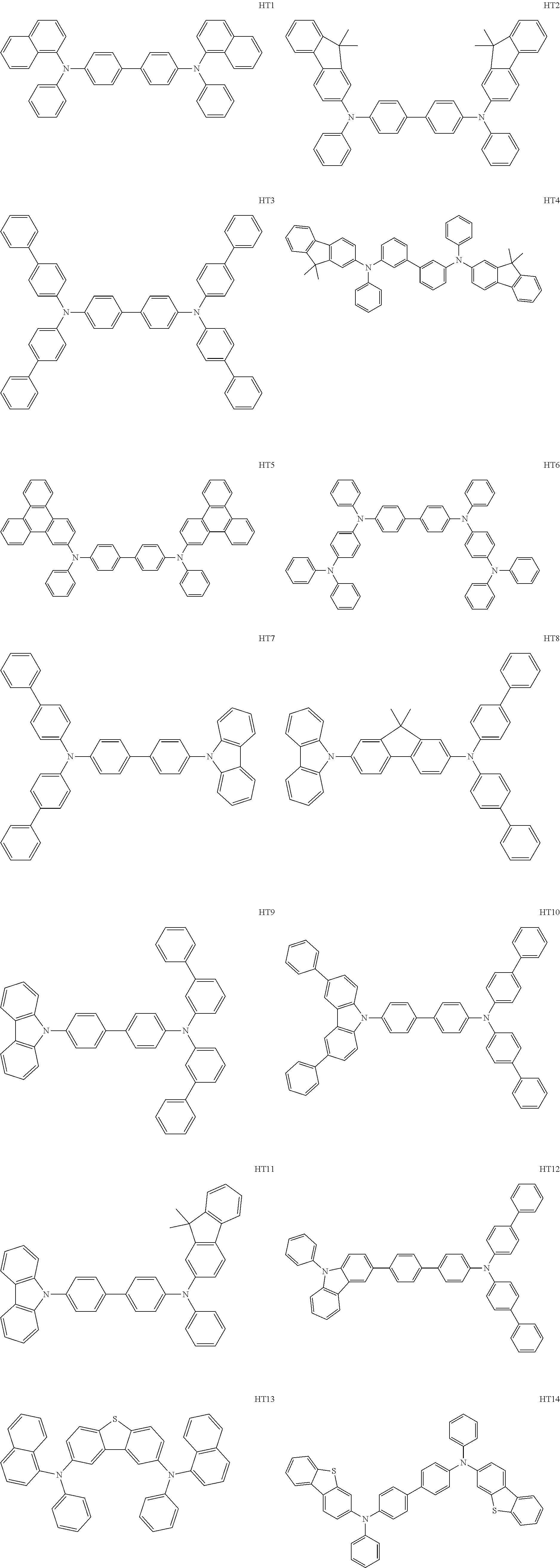

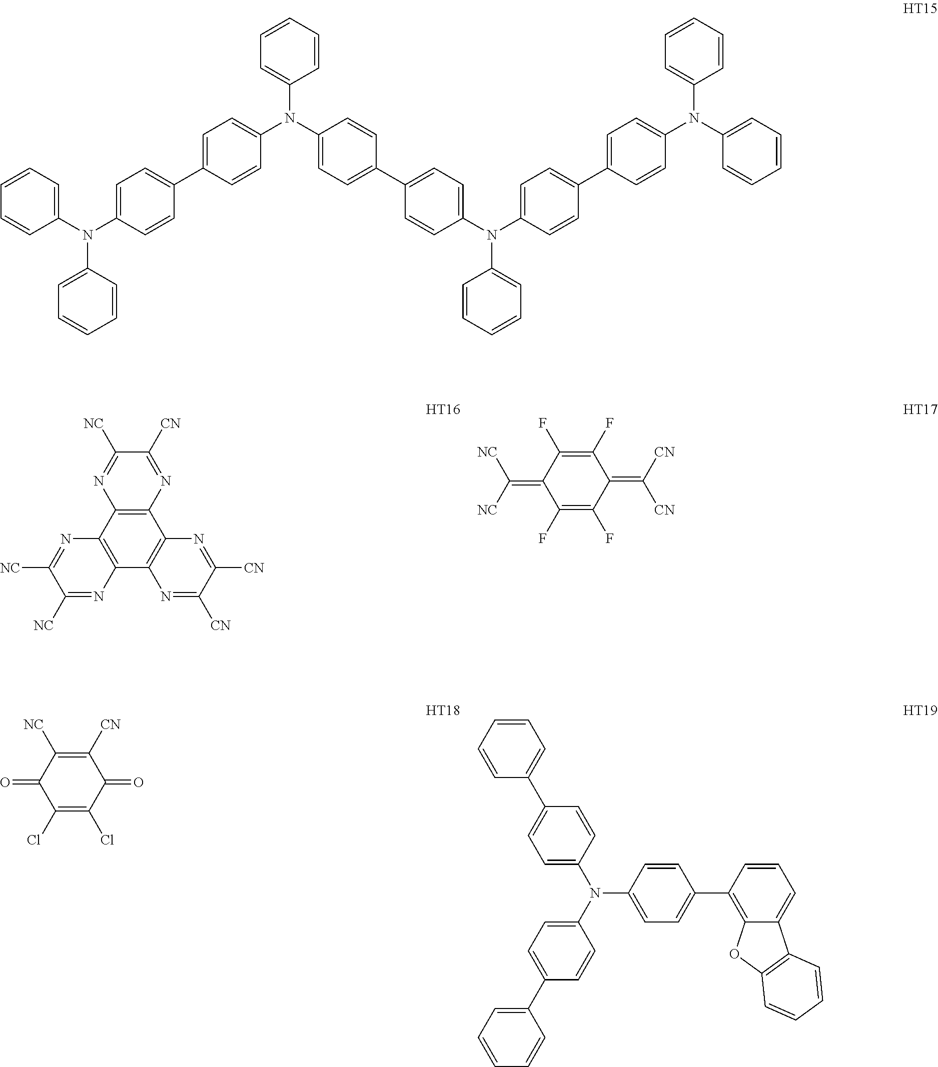 [SMILES: c1ccc(N(c2ccccc2)c2ccc(-c3ccc(N(c4ccccc4)c4ccc(-c5ccc(N(c6ccccc6)c6ccc(-c7ccc(N(c8ccccc8)c8ccccc8)cc7)cc6)cc5)cc4)cc3)cc2)cc1 ; N#Cc1nc2c3nc(C#N)c(C#N)nc3c3nc(C#N)c(C#N)nc3c2nc1C#N ; N#CC(C#N)=c1c(F)c(F)c(=C(C#N)C#N)c(F)c1F ; N#CC1=C(C#N)C(=O)C(Cl)=C(Cl)C1=O ; c1ccc(-c2ccc(N(c3ccc(-c4ccccc4)cc3)c3ccc(-c4cccc5c4oc4ccccc45)cc3)cc2)cc1]

Examples of the light-emitting material mainly related to the light-emitting function include, in addition to the light-emitting material containing a fluoranthene skeleton of the present embodiment, fused-ring compounds (such as fluorene derivatives, naphthalene derivatives, pyrene derivatives, perylene derivatives, tetracene derivatives, anthracene derivatives, and rubrene), quinacridone derivatives, coumarin derivatives, stilbene derivatives, organoaluminum complexes, such as tris(8-quinolinolato)aluminum, iridium complexes, platinum complexes, rhenium complexes, copper complexes, europium complexes, ruthenium complexes, and polymer derivatives, such as poly(phenylene vinylene) derivatives, polyfluorene derivatives, and polyphenylene derivatives. Specific examples of a compound used as a light-emitting material are illustrated below, but of course, the light-emitting material is not limited thereto.

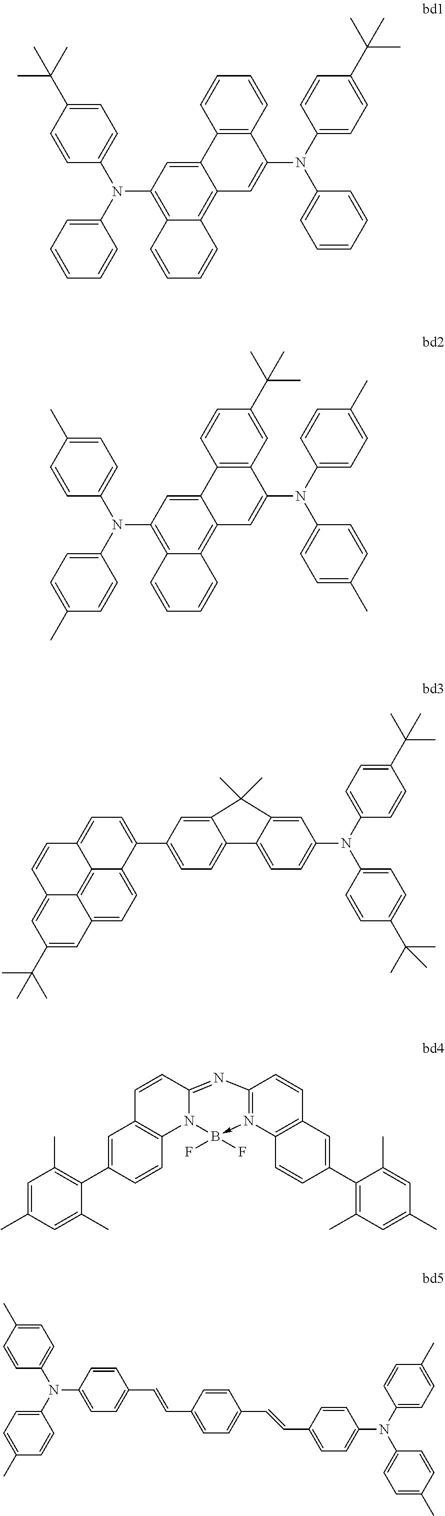

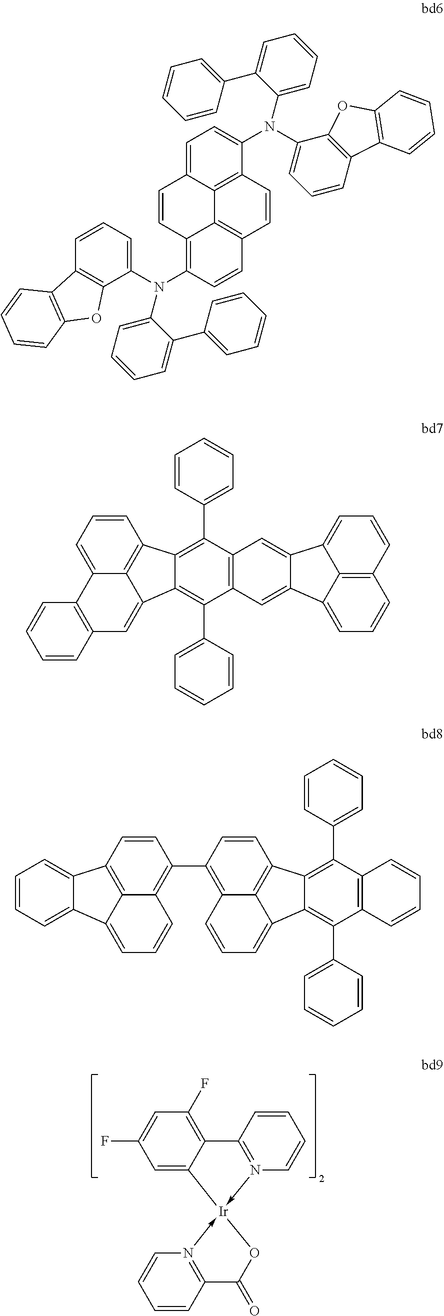

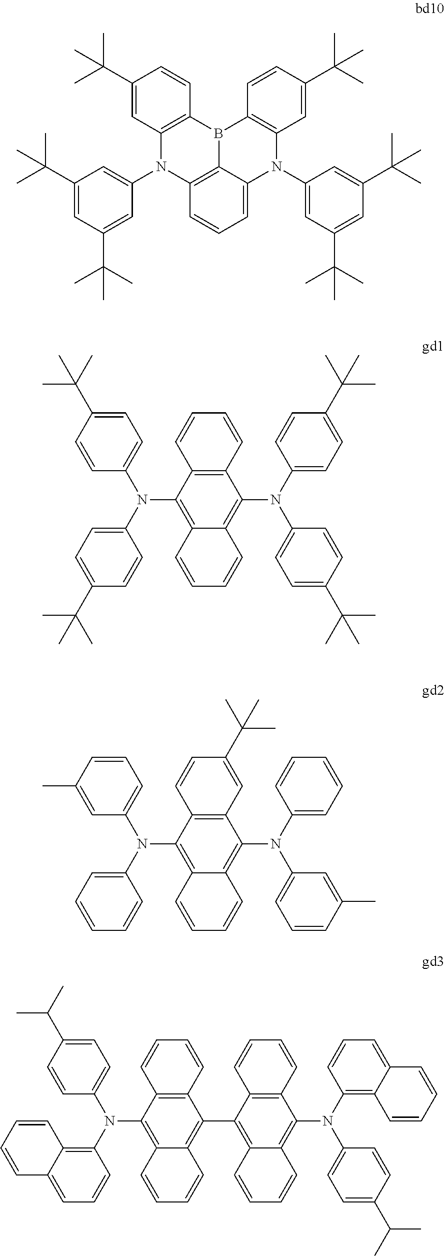

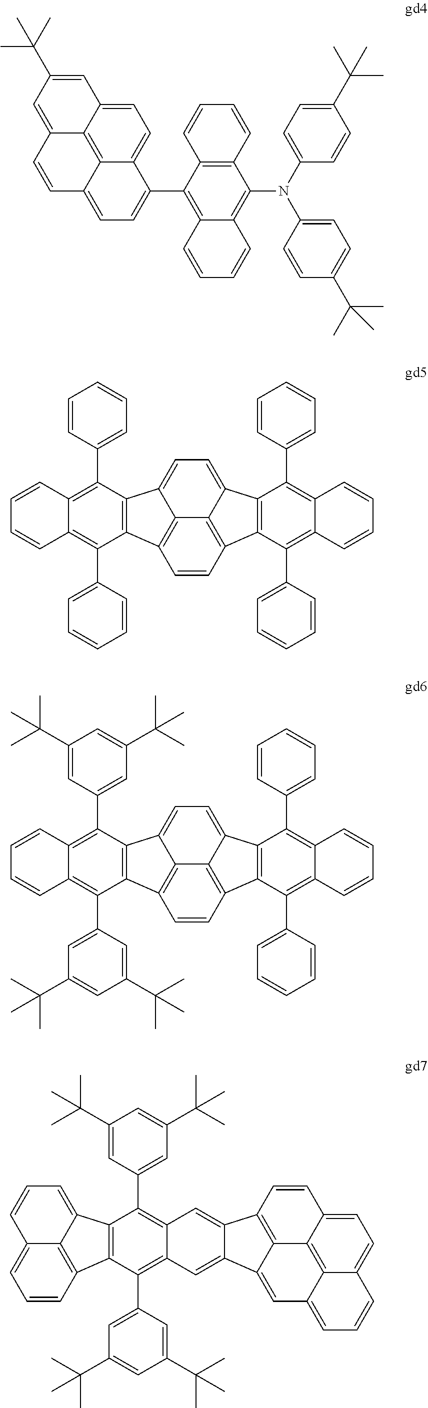

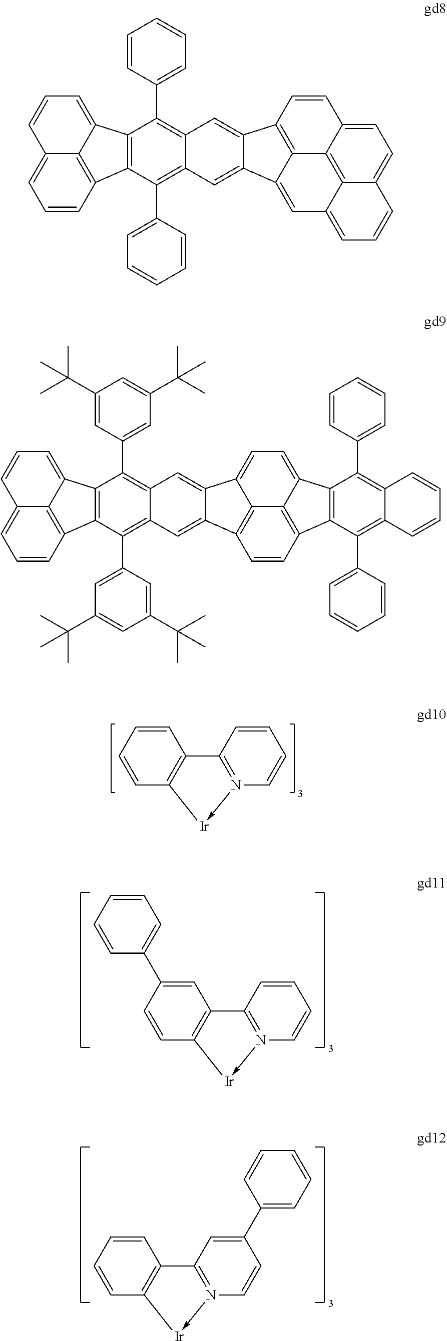

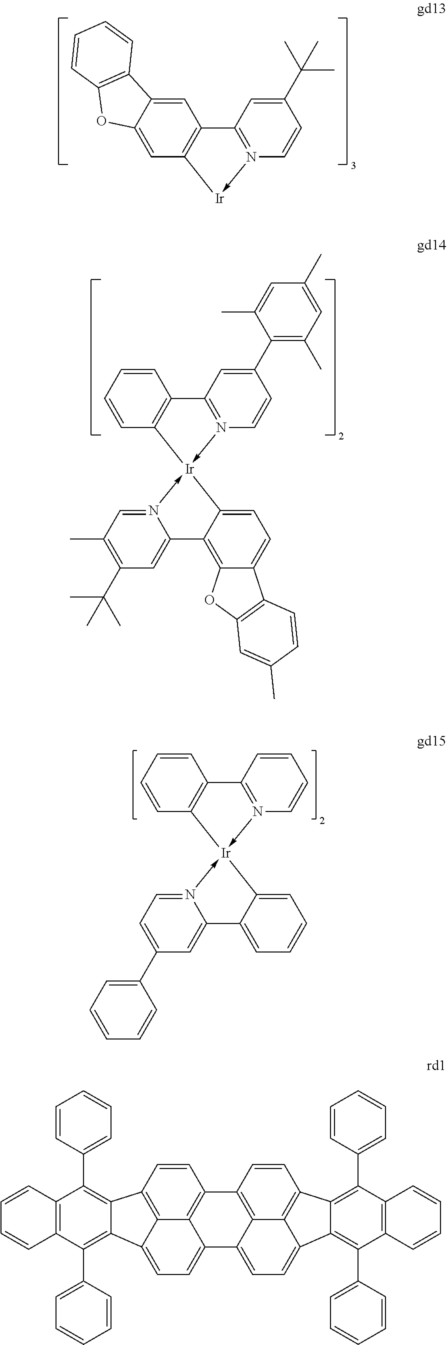

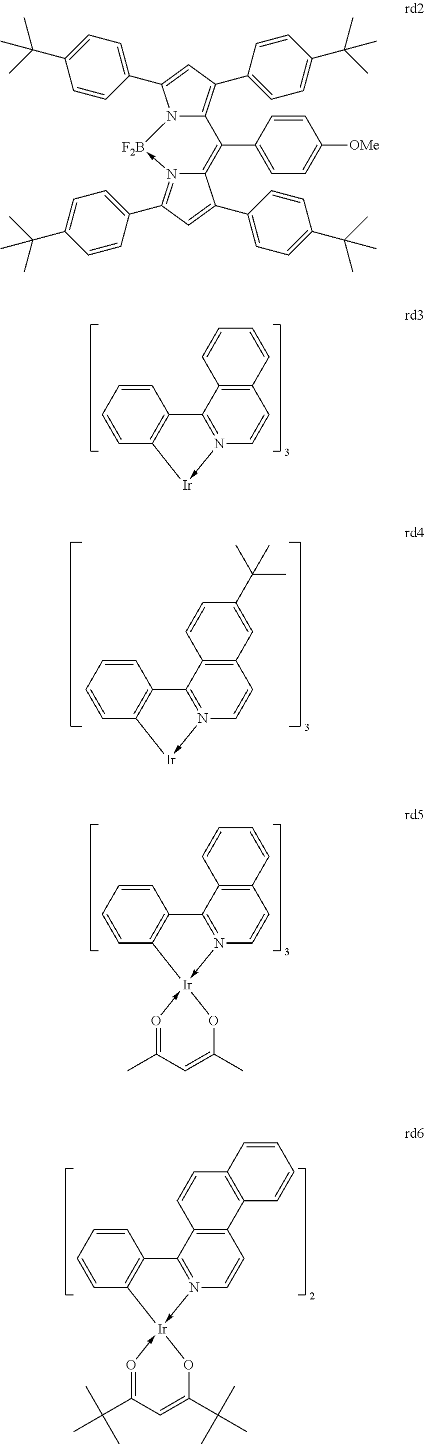

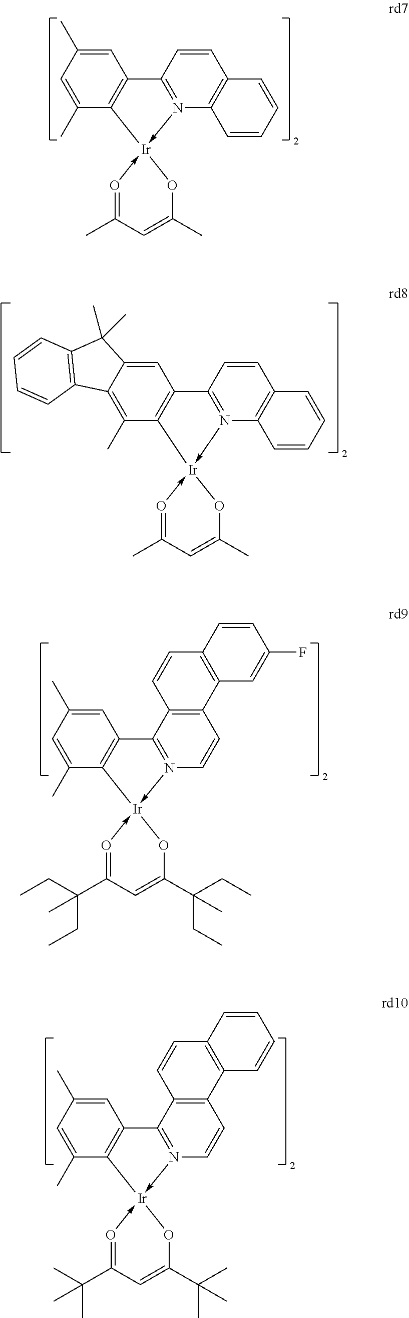

Examples of a light-emitting layer host or a light-emission assist material in the light-emitting layer include, in addition to the above-described compound represented by any of general formulae [1-1] to [1-6], aromatic hydrocarbon compounds and derivatives thereof, carbazole derivatives, dibenzofuran derivatives, dibenzothiophene derivatives, organoaluminum complexes, such as tris(8-quinolinolato)aluminum, and organoberyllium complexes.

In particular, as the assist material, a material having a carbazole skeleton, a material having an azine ring in its skeleton, and a material having xanthone in its skeleton are preferred. This is because these materials are high in electron-donating property and electron-withdrawing property, so that the HOMO and the LUMO are easily adjusted. A good carrier balance can be achieved when these assist materials are combined with the organic compound according to an embodiment of the present disclosure.

Specific examples of the compound for the light-emission assist material contained in the light-emitting layer are illustrated below, but of course, the compound is not limited thereto.

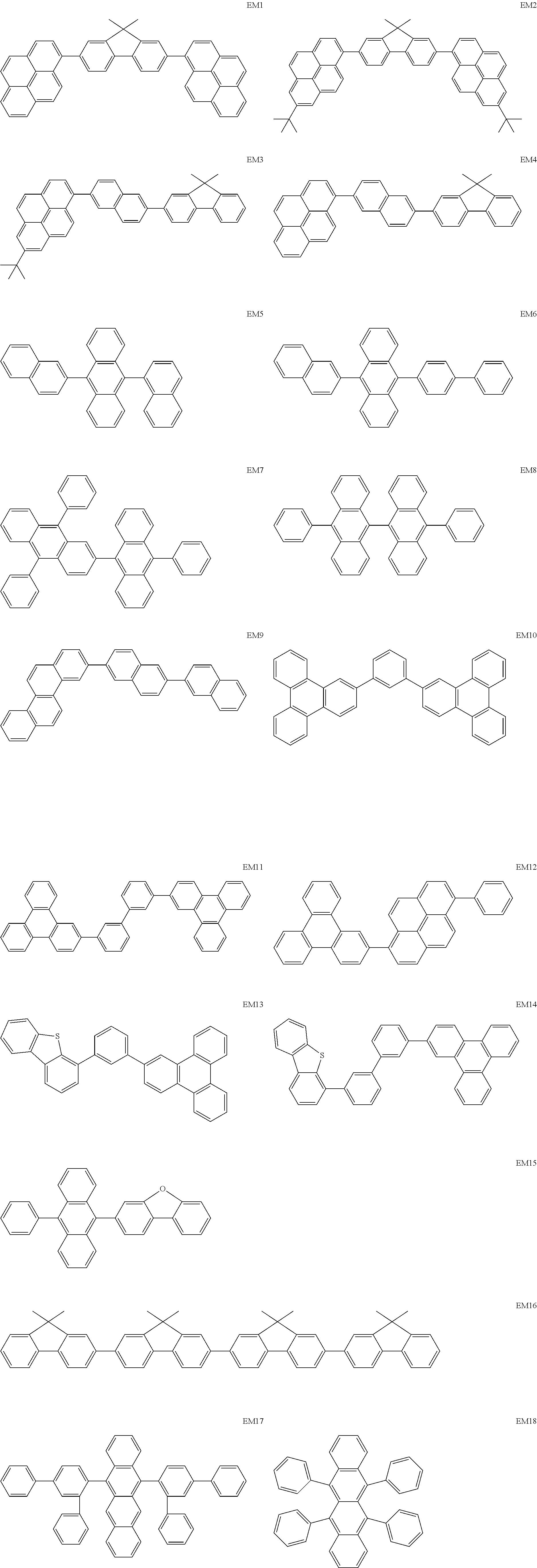

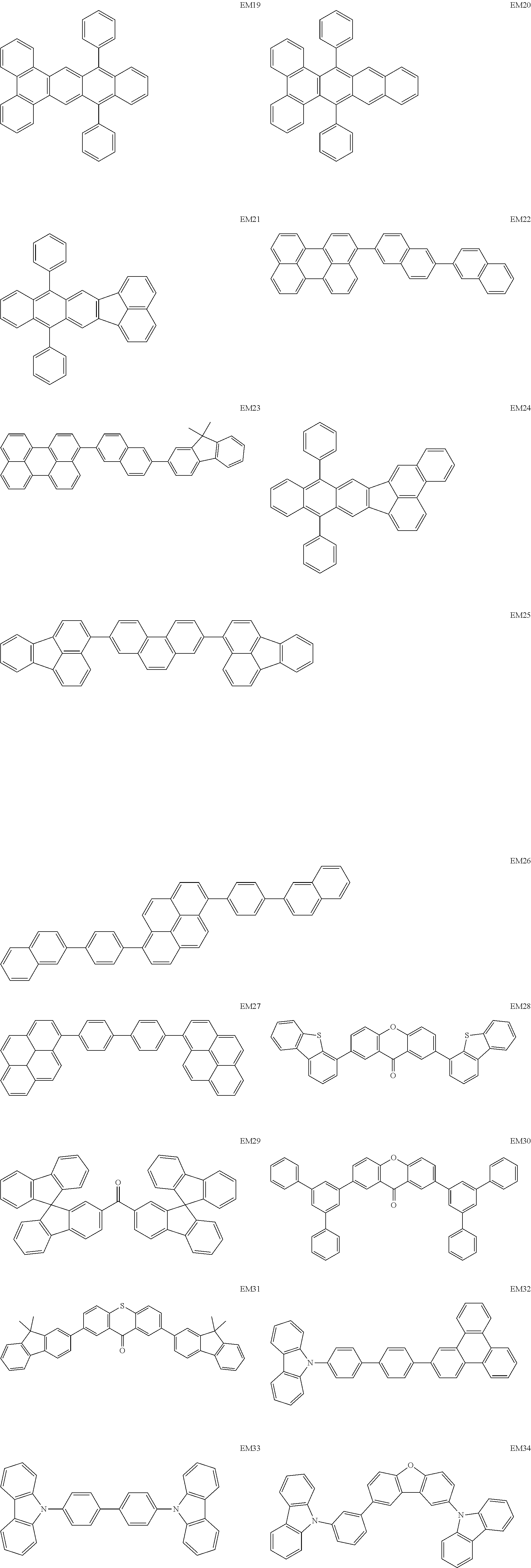

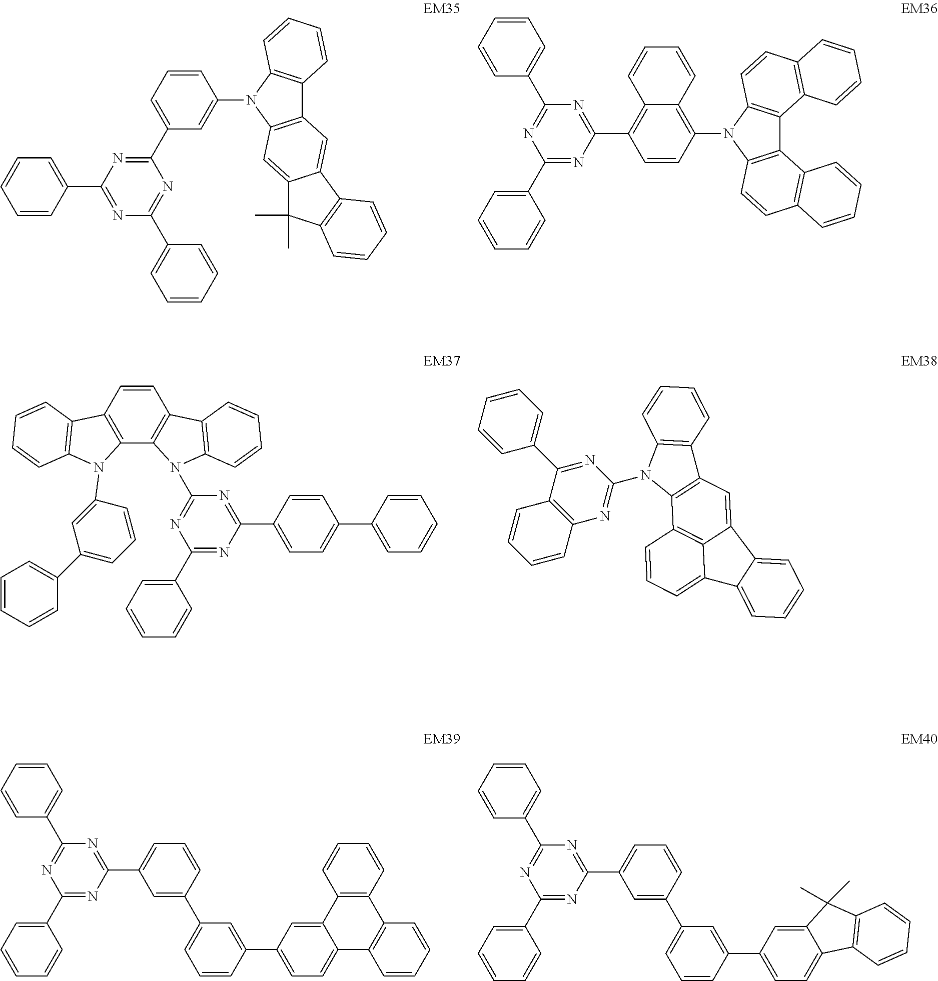 [SMILES: CC1(C)c2ccccc2-c2cc3c4ccccc4n(-c4cccc(-c5nc(-c6ccccc6)nc(-c6ccccc6)n5)c4)c3cc21 ; c1ccc(-c2nc(-c3ccccc3)nc(-c3ccc(-n4c5ccc6ccccc6c5c5c6ccccc6ccc54)c4ccccc34)n2)cc1 ; c1ccc(-c2ccc(-c3nc(-c4ccccc4)nc(-n4c5ccccc5c5ccc6c7ccccc7n(-c7cccc(-c8ccccc8)c7)c6c54)n3)cc2)cc1 ; c1ccc(-c2nc(-n3c4ccccc4c4cc5c6c(cccc6c43)-c3ccccc3-5)nc3ccccc23)cc1 ; c1ccc(-c2nc(-c3ccccc3)nc(-c3cccc(-c4cccc(-c5ccc6c7ccccc7c7ccccc7c6c5)c4)c3)n2)cc1 ; CC1(C)c2ccccc2-c2ccc(-c3cccc(-c4cccc(-c5nc(-c6ccccc6)nc(-c6ccccc6)n5)c4)c3)cc21]

The electron transport material other than the compound containing at least one fused polycyclic hydrocarbon skeleton having three or more rings and five or less rings according to the present embodiment can be freely-selected from materials that can transport electrons injected from the cathode to the light-emitting layer, and is selected in consideration of, for example, the balance with the hole mobility of the hole transport material. Examples of a material having the ability to transport electrons include oxadiazole derivatives, oxazole derivatives, pyrazine derivatives, triazole derivatives, triazine derivatives, quinoline derivatives, quinoxaline derivatives, phenanthroline derivatives, organoaluminum complexes, and fused-ring compounds (such as fluorene derivatives, naphthalene derivatives, chrysene derivatives, and anthracene derivatives). The above-described electron transport materials are also suitably used for the hole-blocking layer. Specific examples of a compound used as the electron transport material are illustrated below, but of course, the electron transport material is not limited thereto.

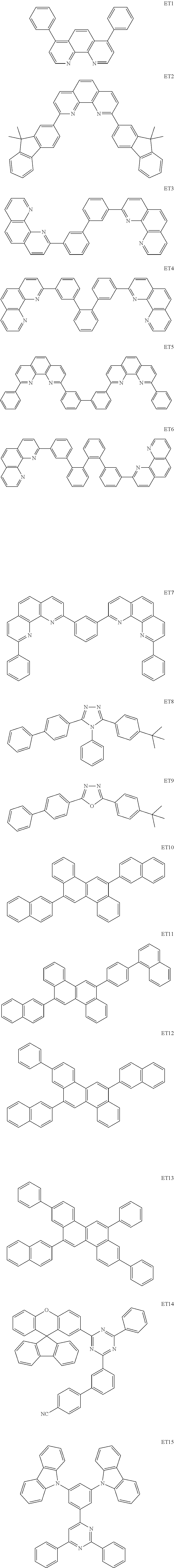

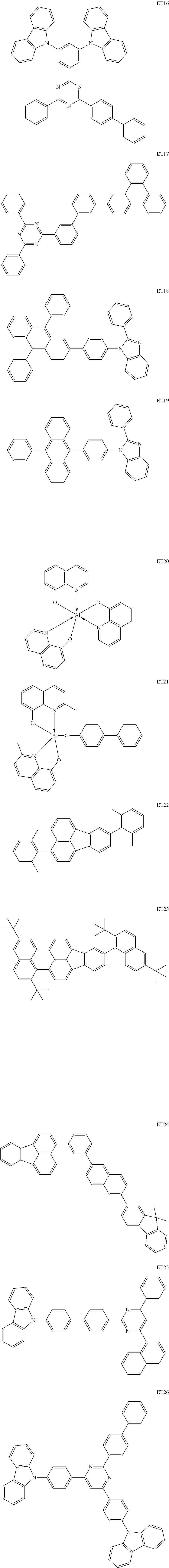

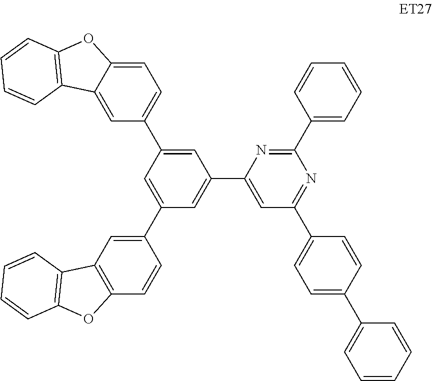 [SMILES: c1ccc(-c2ccc(-c3cc(-c4cc(-c5ccc6oc7ccccc7c6c5)cc(-c5ccc6oc7ccccc7c6c5)c4)nc(-c4ccccc4)n3)cc2)cc1]

An electron injection material can be freely-selected from materials that can easily inject electrons from the cathode, and is selected in consideration of, for example, the balance with the hole injectability. As the organic compound, n-type dopants and reducing dopants are also included. Examples thereof include alkali metal-containing compounds, such as lithium fluoride, lithium complexes, such as lithium quinolinolate, benzimidazolidene derivatives, imidazolidene derivatives, fulvalene derivatives, and acridine derivatives. It can also be used in combination with the above-mentioned electron transport material.

### Configuration of Organic Light-Emitting Device

The organic light-emitting device includes an insulating layer, a first electrode, an organic compound layer, and a second electrode over a substrate. A protective layer, a color filter, a microlens may be disposed over the second electrode. In the case of disposing the color filter, a planarization layer may be disposed between the protective layer and the color filter. The planarization layer can be composed of, for example, an acrylic resin. The same applies when a planarization layer is provided between the color filter and the microlens.

### Substrate

Examples of the substrate include silicon wafers, quartz substrates, glass substrates, resin substrates, and metal substrates. The substrate may include a switching device, such as a transistor, a line, and an insulating layer thereon. Any material can be used for the insulating layer as long as a contact hole can be formed in such a manner that a line can be coupled to the first electrode and as long as insulation with a non-connected line can be ensured. For example, a resin, such as polyimide, silicon oxide, or silicon nitride, can be used.

### Electrode

A pair of electrodes can be used. The pair of electrodes may be an anode and a cathode. When an electric field is applied in the direction in which the organic light-emitting device emits light, an electrode having a higher potential is the anode, and the other is the cathode. It can also be said that the electrode that supplies holes to the light-emitting layer is the anode and that the electrode that supplies electrons is the cathode.

As the component material of the anode, a material having a work function as high as possible can be used. Examples of the material that can be used include elemental metals, such as gold, platinum, silver, copper, nickel, palladium, cobalt, selenium, vanadium, and tungsten, mixtures thereof, alloys of combinations thereof, and metal oxides, such as tin oxide, zinc oxide, indium oxide, indium-tin oxide (ITO), and indium-zinc oxide. Additionally, conductive polymers, such as polyaniline, polypyrrole, and polythiophene, can be used.

These electrode materials may be used alone or in combination of two or more. The anode may be formed of a single layer or multiple layers.

When the anode is used as a reflective electrode, for example, chromium, aluminum, silver, titanium, tungsten, molybdenum, an alloy thereof, or a stack thereof can be used. These materials can also be used to act as a reflective film that does not have the role of an electrode. When the anode is used as a transparent electrode, a transparent conductive oxide layer composed of, for example, indium-tin oxide (ITO) or indium-zinc oxide can be used; however, the anode is not limited thereto. The electrode can be formed by photolithography.

As the component material of the cathode, a material having a lower work function can be used. Examples thereof include elemental metals such as alkali metals, e.g., lithium, alkaline-earth metals, e.g., calcium, aluminum, titanium, manganese, silver, lead, and chromium, and mixtures thereof. Alloys of combinations of these elemental metals can also be used. For example, magnesium-silver, aluminum-lithium, aluminum-magnesium, silver-copper, and zinc-silver can be used. Metal oxides, such as indium-tin oxide (ITO), can also be used. These electrode materials may be used alone or in combination of two or more. The cathode may have a single-layer structure or a multilayer structure. Among them, it is preferable to use silver. To reduce the aggregation of silver, it is more preferable to use a silver alloy. Any alloy ratio may be used as long as the aggregation of silver can be reduced. The ratio of silver to another metal may be, for example, 1:1 or 3:1.

A top emission device may be provided using the cathode formed of a conductive oxide layer composed of, for example, ITO. A bottom emission device may be provided using the cathode formed of a reflective electrode composed of, for example, aluminum (Al). Any type of cathode may be used. Any method for forming the cathode may be employed. For example, a direct-current or alternating-current sputtering technique is more preferably employed because good film coverage is obtained and thus the resistance is easily reduced.

### Organic Compound Layer

The organic compound layer may include a layer other than the light-emitting layer and the first organic compound layer. The layer other than the light-emitting layer and the first organic compound layer may be formed of a single layer or multiple layers. When multiple layers are present, they may be referred to as a hole injection layer, a hole transport layer, an electron-blocking layer, a hole-blocking layer, an electron transport layer, or an electron injection layer in accordance with their functions. The organic compound layer is mainly composed of an organic compound, and may contain inorganic atoms and an inorganic compound. For example, the organic compound layer may contain, for example, copper, lithium, magnesium, aluminum, iridium, platinum, molybdenum, or zinc. The organic compound layer may be disposed between the first electrode and the second electrode, and may be disposed in contact with the first electrode and the second electrode.

The organic compound layer (such as the hole injection layer, the hole transport layer, the electron-blocking layer, the light-emitting layer, the hole-blocking layer, the electron transport layer, or the electron injection layer) included in the organic light-emitting device according to an embodiment of the present disclosure is formed by a method described below.

For the organic compound layer included in the organic light-emitting device according to an embodiment of the present disclosure, a dry process, such as a vacuum evaporation method, an ionized evaporation method, sputtering, or plasma, may be employed. Alternatively, instead of the dry process, it is also possible to employ a wet process in which a material is dissolved in an appropriate solvent and then a film is formed by a known coating method (such as spin coating, dipping, a casting method, an LB technique, or an ink jet method).

When the layer is formed by, for example, the vacuum evaporation method or the solution coating method, crystallization and so forth are less likely to occur, and good stability with time is obtained. In the case of forming a film by the coating method, the film may be formed in combination with an appropriate binder resin.

Examples of the binder resin include, but are not limited to, poly(vinyl carbazole) resins, polycarbonate resins, polyester resins, ABS resins, acrylic resins, polyimide resins, phenolic resins, epoxy resins, silicone resins, and urea resins.

These binder resins may be used alone as a homopolymer or copolymer, or in combination as a mixture of two or more. Furthermore, additives, such as a known plasticizer, antioxidant, and ultraviolet absorber, may be used, as needed.

### Protective Layer

A protective layer may be disposed on the second electrode. For example, a glass member provided with a moisture absorbent can be bonded to the second electrode to reduce the entry of, for example, water into the organic compound layer, thereby reducing the occurrence of display defects. In another embodiment, a passivation film composed of, for example, silicon nitride may be disposed on the second electrode to reduce the entry of, for example, water into the organic compound layer. For example, after the formation of the second electrode, the substrate may be transported to another chamber without breaking the vacuum, and a silicon nitride film having a thickness of 2 μm may be formed by a CVD method to provide a protective layer. After the film deposition by the CVD method, a protective layer may be formed by an atomic layer deposition (ALD) method. Examples of the material of the layer formed by the ALD method may include, but are not limited to, silicon nitride, silicon oxide, and aluminum oxide. Silicon nitride may be deposited by the CVD method on the layer formed by the ALD method. The film formed by the ALD method may have a smaller thickness than the film formed by the CVD method. Specifically, the thickness may be 50% or less, even 10% or less.

### Color Filter

A color filter may be disposed on the protective layer. For example, a color filter may be disposed on another substrate in consideration of the size of the organic light-emitting device and bonded to the substrate provided with the organic light-emitting device. A color filter may be formed by patterning on the protective layer using photolithography. The color filter may be composed of a polymer.

### Planarization Layer

A planarization layer may be disposed between the color filter and the protective layer. The planarization layer is provided for the purpose of reducing the unevenness of the layer underneath. The planarization layer may be referred to as a “material resin layer” without limiting its purpose. The planarization layer may be composed of an organic compound. A low- or high-molecular-weight organic compound may be used. A high-molecular-weight organic compound is preferred.

The planarization layers may be disposed above and below (or on) the color filter and may be composed of the same or different component materials. Specific examples thereof include poly(vinyl carbazole) resins, polycarbonate resins, polyester resins, ABS resins, acrylic resins, polyimide resins, phenolic resins, epoxy resins, silicone resins, and urea resins.

### Microlens

The organic light-emitting device or an organic light-emitting apparatus may include an optical component, such as a microlens, on the outgoing light side. The microlens can be composed of, for example, an acrylic resin or an epoxy resin. The microlens may be used to increase the amount of light emitted from the organic light-emitting device or the organic light-emitting apparatus and to control the direction of the light emitted. The microlens may have a hemispherical shape. In the case of a hemispherical shape, among tangents to the hemisphere, there is a tangent parallel to the insulating layer. The point of contact of the tangent with the hemisphere is the vertex of the microlens. The vertex of the microlens can be determined in the same way for any cross-sectional view. That is, among the tangents to the semicircle of the microlens in the cross-sectional view, there is a tangent parallel to the insulating layer, and the point of contact of the tangent with the semicircle is the vertex of the microlens.

The midpoint of the microlens can be defined. In the cross section of the microlens, when a segment is hypothetically drawn from the point where an arc shape ends to the point where another arc shape ends, the midpoint of the segment can be referred to as the midpoint of the microlens. The cross section to determine the vertex and midpoint may be a cross section perpendicular to the insulating layer.

### Opposite Substrate

An opposite substrate may be disposed on the planarization layer. The opposite substrate is disposed at a position corresponding to the substrate described above and thus is called an opposite substrate. The opposite substrate may be composed of the same material as the substrate described above. When the above-described substrate is referred to as a first substrate, the opposite substrate may be referred to as a second substrate.

### Pixel Circuit

An organic light-emitting apparatus including organic light-emitting devices may include pixel circuits coupled to the organic light-emitting devices. Each of the pixel circuits may be of an active matrix type, which independently controls the emission of first and second light-emitting devices. The active matrix type circuit may be voltage programming or current programming. A driving circuit includes the pixel circuit for each pixel. The pixel circuit may include a light-emitting device, a transistor to control the luminance of the light-emitting device, a transistor to control the timing of the light emission, a capacitor to retain the gate voltage of the transistor to control the luminance, and a transistor to connect to GND without using the light-emitting device.

The light-emitting apparatus includes a display area and a peripheral area disposed around the display area. The display area includes a pixel circuit, and the peripheral area includes a display control circuit. The mobility of a transistor contained in the pixel circuit may be lower than the mobility of a transistor contained in the display control circuit. The gradient of the current-voltage characteristics of the transistor contained in the pixel circuit may be smaller than the gradient of the current-voltage characteristic of the transistor contained in the display control circuit. The gradient of the current-voltage characteristics can be measured by what is called Vg-Ig characteristics. The transistor contained in the pixel circuit is a transistor coupled to a light-emitting device, such as a first light-emitting device.

### Pixel

An organic light-emitting apparatus including an organic light-emitting device may include multiple pixels. Each pixel includes subpixels configured to emit colors different from each other. The subpixels may have respective red, green, and blue (RGB) emission colors.

Light emerges from a region of the pixel, also called a pixel aperture. The pixel aperture may be 15 μm or less, and may be 5 μm or more. More specifically, the pixel aperture may be, for example, 11 μm, 9.5 μm, 7.4 μm, or 6.4 μm. The distance between subpixels may be 10 μm or less. Specifically, the distance may be 8 μm, 7.4 μm, or 6.4 μm.

The pixels may be arranged in a known pattern in plan view. For example, a stripe pattern, a delta pattern, a Pen Tile matrix pattern, or the Bayer pattern may be used. The shape of each subpixel in plan view may be any known shape. Examples of the shape of the subpixel include quadrilaterals, such as rectangles and rhombi, and hexagons. Of course, when the shape is close to a rectangle, rather than an exact shape, it is included in the rectangle. The shape of the subpixel and the pixel arrangement can be used in combination.

### Application of Organic Light-Emitting Device

The organic light-emitting device according to the present embodiment can be used as a component member of a display apparatus or lighting apparatus. Other applications include exposure light sources for electrophotographic image-forming apparatuses, backlights for liquid crystal display apparatuses, and light-emitting apparatuses including white-light sources and color filters.

The display apparatus may be an image information-processing apparatus including an image input unit that receives image information from an area CCD, a linear CCD sensor, a memory card, or the like, an information-processing unit that processes the input information, and a display unit that displays the input image. The display apparatus includes multiple pixels, and at least one of the multiple pixels may include the organic light-emitting device according to the present embodiment and a transistor coupled to the organic light-emitting device.

The display unit of an image pickup apparatus or an inkjet printer may have a touch panel function. The driving mode of the touch panel function may be, but is not particularly limited to, an infrared mode, an electrostatic capacitance mode, a resistive film mode, or an electromagnetic inductive mode. The display apparatus may also be used for a display unit of a multifunction printer.

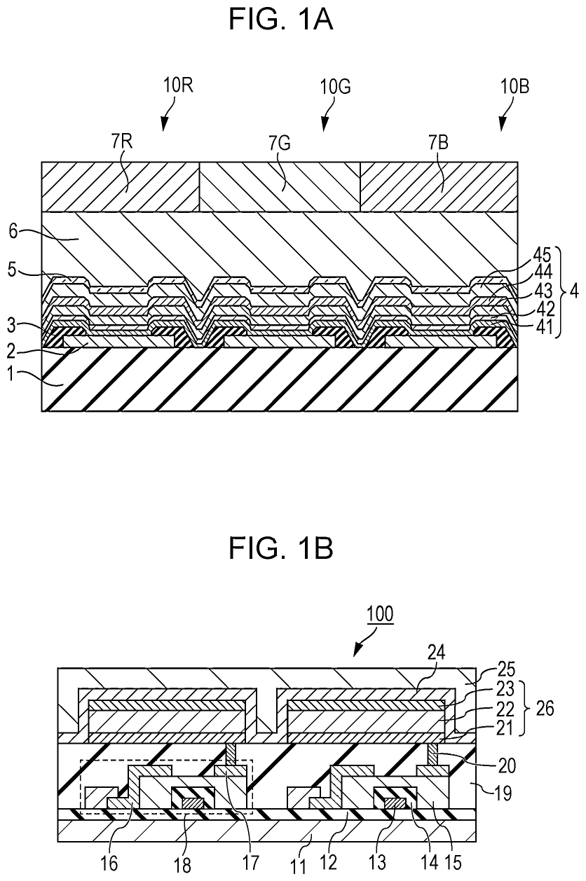

The following describes a display apparatus according to the present embodiment with reference to the attached drawings. FIGS. 1A and 1B are each a schematic cross-sectional view of an example of a display apparatus including organic light-emitting devices and transistors coupled to the respective organic light-emitting devices. Each of the transistors is an example of an active element. The transistors may be thin-film transistors (TFTs).

FIG. 1A illustrates an example of pixels that are constitutional elements of the display apparatus according to the present embodiment. Each of the pixels includes subpixels 10. The subpixels are divided into 10R, 10G, and 10B according to their light emission. The emission color may be distinguished based on the wavelength of light emitted from the light-emitting layer. Alternatively, light emitted from the subpixels may be selectively transmitted or color-converted with, for example, a color filter. Each subpixel 10 includes a reflective electrode serving as a first electrode 2, an insulating layer 3 covering the edge of the first electrode 2, an organic compound layer 4 covering the first electrode 2 and the insulating layer 3, a transparent electrode serving as a second electrode 5, a protective layer 6, and a color filter 7 over an interlayer insulating layer 1.

The transistors and capacitive elements may be disposed under or in the interlayer insulating layer 1. Each transistor may be electrically coupled to a corresponding one of the first electrodes 2 through a contact hole, which is not illustrated.

The insulating layer 3 is also referred to as a bank or pixel separation film. The insulating layer covers the edge of each first electrode 2 and surrounds the first electrode 2. Portions that are not covered with the insulating layer 3 are in contact with the organic compound layer 4 and serve as light-emitting regions.

The organic compound layer 4 includes a hole injection layer 41, a hole transport layer 42, a first light-emitting layer 43, a second light-emitting layer 44, and an electron transport layer 45.

The second electrode 5 may be a transparent electrode, a reflective electrode, or a semi-transparent electrode.

The protective layer 6 reduces the penetration of moisture into the organic compound layer 4. Although the protective layer 6 is illustrated as a single layer, the protective layer 6 may be formed of multiple layers. Each layer may be an inorganic compound layer or an organic compound layer.

The color filter 7 is separated into 7R, 7G, and 7B according to its color. The color filter may be disposed on a planarization film, which is not illustrated. A resin protective layer, which is not illustrated, may be disposed on the color filter 7. The color filter 7 may be disposed on the protective layer 6. Alternatively, the color filter 7 may be disposed on an opposite substrate, such as a glass substrate, and then bonded.

A display apparatus 100 illustrated in FIG. 1B includes organic light-emitting devices 26 and TFTs 18 as an example of transistors. A substrate 11 composed of a material, such as glass or silicon, is provided, and an insulating layer 12 is disposed thereon. Active elements, such as the TFTs 18, are disposed on the insulating layer 12. The gate electrode 13, the gate insulating film 14, and the semiconductor layer 15 of each of the active elements are disposed thereon. Each TFT 18 further includes a drain electrode 16 and a source electrode 17. The TFTs 18 are overlaid with an insulating film 19. Anodes 21 included in the organic light-emitting devices 26 are coupled to the source electrodes 17 through contact holes 20 provided in the insulating film 19.

The mode of electrical connection between the electrodes (anode 21 and cathode 23) included in each organic light-emitting device 26 and the electrodes (source electrode 17 and drain electrode 16) included in a corresponding one of the TFTs 18 is not limited to the mode illustrated in FIG. 1B. That is, it is sufficient that any one of the anode 21 and the cathode 23 is electrically coupled to any one of the source electrode 17 and the drain electrode 16 of the TFT 18. The term “TFT” refers to a thin-film transistor.

In the display apparatus 100 illustrated in FIG. 1B, although each organic compound layer 22 is illustrated as a single layer, the organic compound layer 22 may include multiple layers. To reduce the deterioration of the organic light-emitting devices 26, a first protective layer 24 and a second protective layer 25 are disposed over the cathodes 23.

In the display apparatus 100 illustrated in FIG. 1B, although the transistors are used as switching elements, other switching elements may be used instead.

The transistors used in the display apparatus 100 illustrated in FIG. 1B are not limited to transistors using a single-crystal silicon wafer, but may also be thin-film transistors including active layers on the insulating surface of a substrate. As the active layers, single-crystal silicon, non-single-crystal silicon, such as amorphous silicon and microcrystalline silicon, and non-single-crystal oxide semiconductors, such as indium zinc oxide and indium gallium zinc oxide, are exemplified. Thin-film transistors are also referred to as TFT elements.

The transistors in the display apparatus 100 illustrated in FIG. 1B may be formed in the substrate, such as a Si substrate. The expression “formed in the substrate” indicates that the transistors are produced by processing the substrate, such as a Si substrate. In the case where the transistors are formed in the substrate, the substrate and the transistors can be deemed to be integrally formed.

In the organic light-emitting device according to the present embodiment, the luminance is controlled by the TFT elements, which are an example of switching elements; thus, an image can be displayed at respective luminance levels by arranging multiple organic light-emitting devices in the plane. The switching elements according to the present embodiment are not limited to the TFT elements and may be low-temperature polysilicon transistors or active-matrix drivers formed on a substrate such as a Si substrate. The expression “on a substrate” can also be said to be “in the substrate”. Whether transistors are formed in the substrate or TFT elements are used is selected in accordance with the size of a display unit. For example, when the display unit has a size of about 0.5 inches, organic light-emitting devices are preferably disposed on a Si substrate.

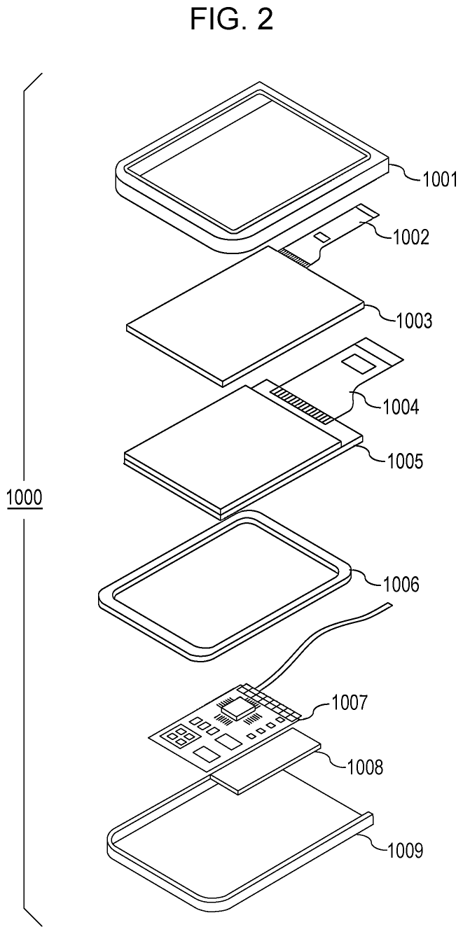

FIG. 2 is a schematic view illustrating an example of a display apparatus according to the present embodiment. A display apparatus 1000 may include a touch panel 1003, a display panel 1005, a frame 1006, a circuit substrate 1007, and a battery 1008 disposed between an upper cover 1001 and a lower cover 1009. The touch panel 1003 and the display panel 1005 are coupled to flexible printed circuits FPCs 1002 and 1004, respectively. The circuit substrate 1007 includes printed transistors. The battery 1008 need not be provided unless the display apparatus is a portable apparatus. The battery 1008 may be disposed at a different position even if the display apparatus is a portable apparatus.

The display apparatus according to the present embodiment may include a color filter having red, green, and blue portions. In the color filter, the red, green, and blue portions may be arranged in a delta arrangement.

The display apparatus according to the present embodiment may be used for the display unit of a portable terminal. In that case, the display apparatus may have both a display function and an operation function. Examples of the portable terminal include mobile phones such as smartphones, tablets, and head-mounted displays.

The display apparatus according to the present embodiment may be used for a display unit of an image pickup apparatus including an optical unit including multiple lenses and an image pickup device that receives light passing through the optical unit. The image pickup apparatus may include a display unit that displays information acquired by the image pickup device. The display unit may be a display unit exposed to the outside of the image pickup apparatus or a display unit disposed in a finder. The image pickup apparatus may be a digital camera or a digital camcorder.

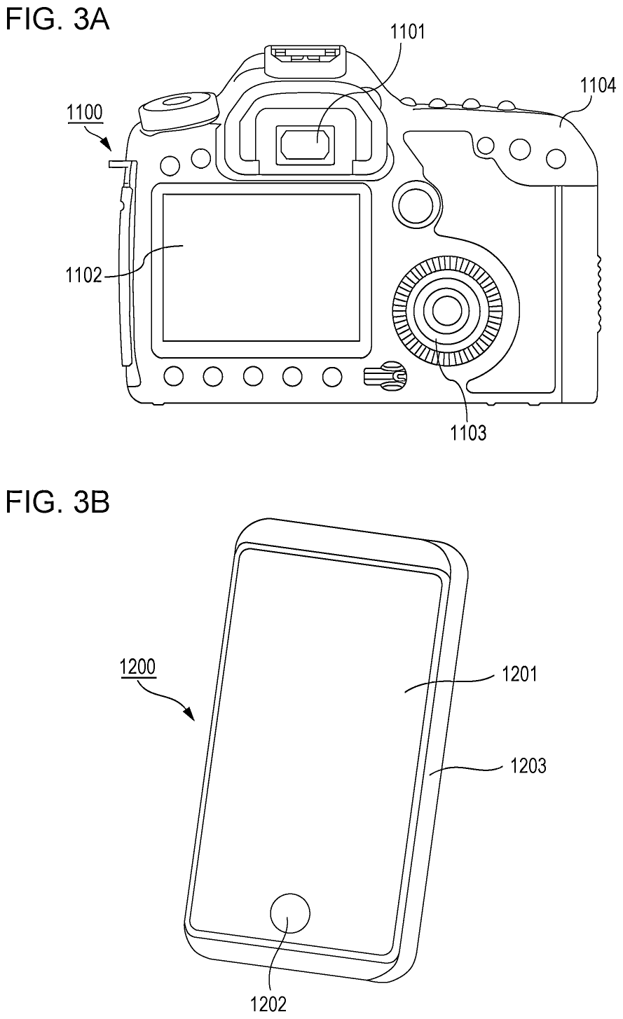

FIG. 3A is a schematic view illustrating an example of an image pickup apparatus according to the present embodiment. An image pickup apparatus 1100 may include a viewfinder 1101, a rear display 1102, an operation unit 1103, and a housing 1104. The viewfinder 1101 may include the display apparatus according to the present embodiment. In this case, the display apparatus may display environmental information, imaging instructions, and so forth in addition to an image to be captured. The environmental information may include, for example, the intensity of external light, the direction of the external light, the moving speed of a subject, and the possibility that a subject is shielded by a shielding material.

The timing suitable for imaging is only for a short time; thus, it is better to display the information as soon as possible. Accordingly, it is preferable to use a display apparatus including the organic light-emitting device of the present embodiment. This is because organic light-emitting devices have a fast response time. The display apparatus including the organic light-emitting device can be used more suitably than liquid crystal display apparatuses for such apparatuses required to have a high display speed.

The image pickup apparatus 1100 includes an optical unit, which is not illustrated. The optical unit includes multiple lenses and is configured to form an image on an image pickup device in the housing 1104. The relative positions of the multiple lenses can be adjusted to adjust the focal point. This operation can also be performed automatically. The image pickup apparatus can also be referred to as a photoelectric conversion apparatus. Examples of an image capturing method employed in the photoelectric conversion apparatus can include a method for detecting a difference from the previous image and a method for cutting out an image from images always recorded, instead of sequentially capturing images.

FIG. 3B is a schematic view illustrating an example of an electronic apparatus according to the present embodiment. An electronic apparatus 1200 includes a display unit 1201, an operation unit 1202, and a housing 1203. The housing 1203 may accommodate a circuit, a printed circuit board including the circuit, a battery, and a communication unit. The operation unit 1202 may be a button or a touch-panel-type reactive unit. The operation unit 1202 unit may be a biometric recognition unit that recognizes a fingerprint to release the lock or the like. An electronic apparatus including a communication unit can also be referred to as a communication apparatus. The electronic apparatus 1200 may further have a camera function by being equipped with a lens and an image pickup device. An image captured by the camera function is displayed on the display unit 1201. Examples of the electronic apparatus 1200 include smartphones and notebook computers.

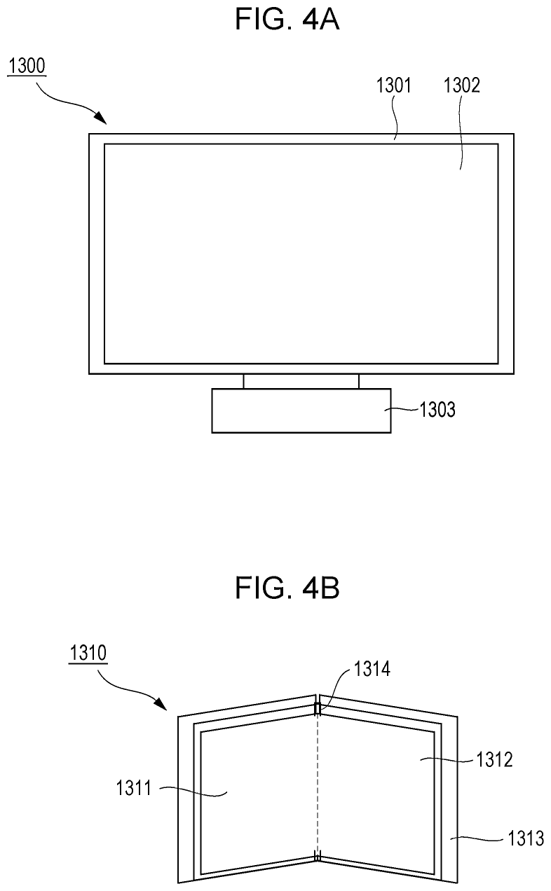

FIGS. 4A and 4B are each a schematic view illustrating an example of a display apparatus according to the present embodiment. FIG. 4A illustrates a display apparatus, such as a television monitor or a PC monitor. A display apparatus 1300 includes a frame 1301 and a display unit 1302. The light-emitting device according to the present embodiment may be used for the display unit 1302. A base 1303 that supports the frame 1301 and the display unit 1302 is provided. The base 1303 is not limited to the structure illustrated in FIG. 4A. The lower side of the frame 1301 may also serve as a base. The frame 1301 and the display unit 1302 may be curved. These may have a radius of curvature of 5,000 mm or more and 6,000 mm or less.

FIG. 4B is a schematic view illustrating another example of a display apparatus according to the present embodiment. A display apparatus 1310 illustrated in FIG. 4B can be folded and is what is called a foldable display apparatus. The display apparatus 1310 includes a first display portion 1311, a second display portion 1312, a housing 1313, and an inflection point 1314. The first display portion 1311 and the second display portion 1312 may include the light-emitting device according to the present embodiment. The first display portion 1311 and the second display portion 1312 may be a single, seamless display apparatus. The first display portion 1311 and the second display portion 1312 can be divided from each other at the inflection point. The first display portion 1311 and the second display portion 1312 may display different images from each other. Alternatively, a single image may be displayed in the first and second display portions.

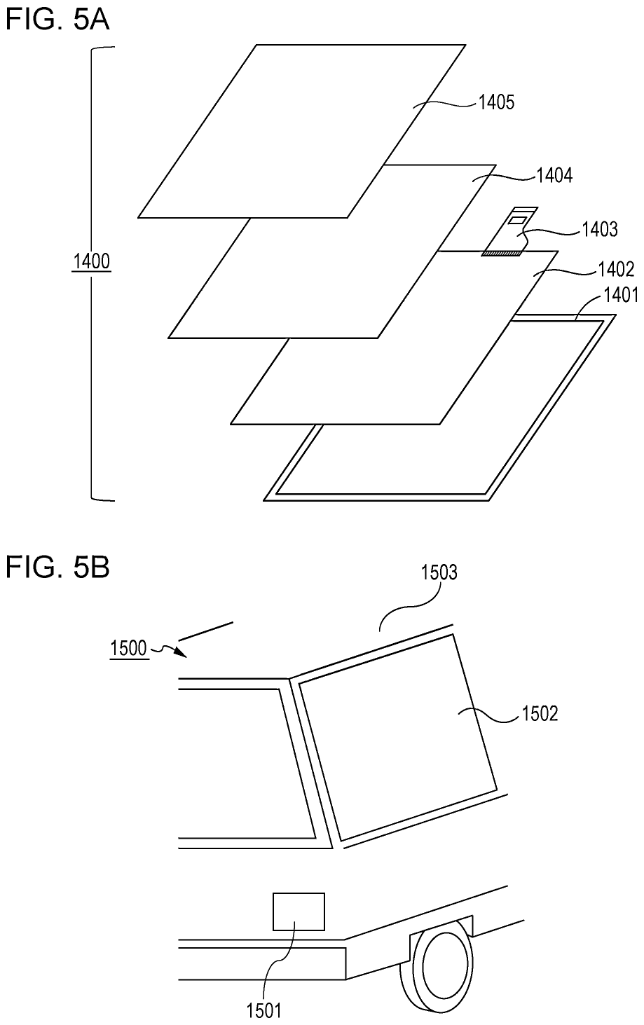

FIG. 5A is a schematic view illustrating an example of a lighting apparatus according to the present embodiment. A lighting apparatus 1400 may include a housing 1401, a light source 1402, a circuit board 1403, an optical filter 1404 that transmits light emitted from the light source 1402, and a light diffusion unit 1405. The light source 1402 may include an organic light-emitting device according to the present embodiment. The optical filter 1404 may be a filter that improves the color rendering properties of the light source. The light diffusion unit 1405 can effectively diffuse light from the light source to deliver the light to a wide range when used for illumination and so forth. The optical filter 1404 and the light diffusion unit 1405 may be disposed on the light emission side of the lighting apparatus. A cover may be disposed at the outermost portion, as needed.

The lighting apparatus is, for example, an apparatus that lights a room. The lighting apparatus may emit light of white, neutral white, or any color from blue to red. A light control circuit that controls the light may be provided. The lighting apparatus may include the organic light-emitting device according to the present embodiment and a power supply circuit coupled thereto. The power supply circuit is a circuit that converts an AC voltage into a DC voltage. The color temperature of white is 4,200 K, and the color temperature of neutral white is 5,000 K. The lighting apparatus may include a color filter.

The lighting apparatus according to the present embodiment may include a heat dissipation unit. The heat dissipation unit is configured to release heat in the apparatus to the outside of the apparatus and is composed of, for example, a metal having a high specific heat or liquid silicone.

FIG. 5B is a schematic view illustrating an automobile, as an example of a moving object, according to the present embodiment. The automobile includes a tail lamp, which is an example of lighting units. An automobile 1500 includes a tail lamp 1501 and may be configured to light the tail lamp when a braking operation or the like is performed.

The tail lamp 1501 may include an organic light-emitting device according to the present embodiment. The tail lamp 1501 may include a protective member that protects the organic light-emitting device. The protective member may be composed of any transparent material having high strength to some extent and is preferably composed of polycarbonate or the like. The polycarbonate may be mixed with, for example, a furandicarboxylic acid derivative or an acrylonitrile derivative.

The automobile 1500 may include an automobile body 1503 and windows 1502 attached thereto. The windows 1502 may be transparent displays, except when the windows are used to check areas in front of and behind of the automobile. The transparent displays may include organic light-emitting devices according to the present embodiment. In this case, the constituent materials, such as the electrodes, of the organic light-emitting device are formed of transparent members.

The moving object according to the present embodiment may be, for example, a ship, an aircraft, or a drone. The moving object may include a body and a lighting unit attached to the body. The lighting unit may emit light to indicate the position of the body. The lighting unit includes the organic light-emitting device according to the present embodiment.

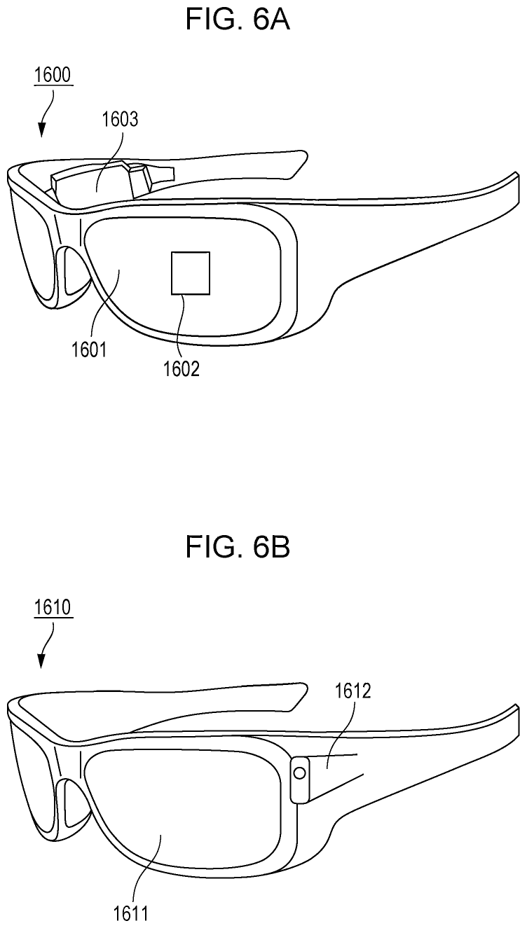

Examples of applications of the display apparatuses of the above embodiments will be described with reference to FIGS. 6A and 6B. The display apparatus can be used for systems that can be worn as wearable devices, such as smart glasses, HMDs, and smart contact lenses. An image pickup and display apparatus used in such an application has an image pickup apparatus that can photoelectrically convert visible light and a display apparatus that can emit visible light.

FIG. 6A is a schematic view of an example of a wearable device according to an embodiment of the present disclosure. Glasses 1600 (smart glasses) according to an example of applications will be described with reference to FIG. 6A. An image pickup apparatus 1602, such as a CMOS sensor or SPAD, is provided on a front side of a lens 1601 of the glasses 1600. The display apparatus according to any of the above-mentioned embodiments is provided on the back side of the lens 1601.

The glasses 1600 further include a control unit 1603. The control unit 1603 functions as a power supply that supplies electric power to the image pickup apparatus 1602 and the display apparatus. The control unit 1603 controls the operation of the image pickup apparatus 1602 and the display apparatus. The lens 1601 has an optical system for focusing light on the image pickup apparatus 1602.

FIG. 6B is a schematic view of another example of a wearable device according to an embodiment of the present disclosure. Glasses 1610 (smart glasses) according to an example of applications will be described with reference to FIG. 6B. The glasses 1610 include a control unit 1612. The control unit 1612 includes an image pickup apparatus corresponding to the image pickup apparatus 1602 illustrated in FIG. 6A and a display apparatus. A lens 1611 is provided with the image pickup apparatus in the control unit 1612 and an optical system that projects light emitted from the display apparatus. An image is projected onto the lens 1611. The control unit 1612 functions as a power source that supplies electric power to the image pickup apparatus and the display apparatus and controls the operation of the image pickup apparatus and the display apparatus.

The control unit 1612 may include a gaze detection unit that detects the gaze of a wearer. Infrared light may be used for gaze detection. An infrared light-emitting unit emits infrared light to an eyeball of a user who is gazing at a displayed image. An image of the eyeball is captured by detecting the reflected infrared light from the eyeball with an image pickup unit having light-receiving elements. The deterioration of image quality is reduced by providing a reduction unit that reduces light from the infrared light-emitting unit to the display unit when viewed in plan. The user's gaze at the displayed image is detected from the image of the eyeball captured with the infrared light. Any known method can be employed to the gaze detection using the captured image of the eyeball. As an example, a gaze detection method based on a Purkinje image of the reflection of irradiation light on a cornea can be employed. More specifically, the gaze detection process is based on a pupil-corneal reflection method. Using the pupil-corneal reflection method, the user's gaze is detected by calculating a gaze vector representing the direction (rotation angle) of the eyeball based on the image of the pupil and the Purkinje image contained in the captured image of the eyeball.

A display apparatus according to an embodiment of the present disclosure may include an image pickup apparatus including light-receiving elements, and may control an image displayed on the display apparatus based on the gaze information of the user from the image pickup apparatus. Specifically, in the display apparatus, a first field-of-view area at which the user gazes and a second field-of-view area other than the first field-of-view area are determined on the basis of the gaze information. The first field-of-view area and the second field-of-view area may be determined by the control unit of the display apparatus or may be determined by receiving those determined by an external control unit. In the display area of the display apparatus, the display resolution of the first field-of-view area may be controlled to be higher than the display resolution of the second field-of-view area. That is, the resolution of the second field-of-view area may be lower than that of the first field-of-view area.

The display area includes a first display area and a second display area different from the first display area. Based on the gaze information, an area of higher priority is determined from the first display area and the second display area. The first display area and the second display area may be determined by the control unit of the display apparatus or may be determined by receiving those determined by an external control unit. The resolution of an area of higher priority may be controlled to be higher than the resolution of an area other than the area of higher priority. In other words, the resolution of an area of a relatively low priority may be low.

Artificial intelligence (AI) may be used to determine the first field-of-view and the high-priority area. The AI may be a model configured to estimate the angle of gaze from the image of the eyeball and the distance to a target object located in the gaze direction, using the image of the eyeball and the actual direction of gaze of the eyeball in the image as teaching data. The AI program may be stored in the display apparatus, the image pickup apparatus, or an external apparatus. When the AI program is stored in the external apparatus, the AI program is transmitted to the display apparatus via communications.

In the case of controlling the display based on visual detection, smart glasses that further include an image pickup apparatus that captures an external image can be used. The smart glasses can display the captured external information in real time.

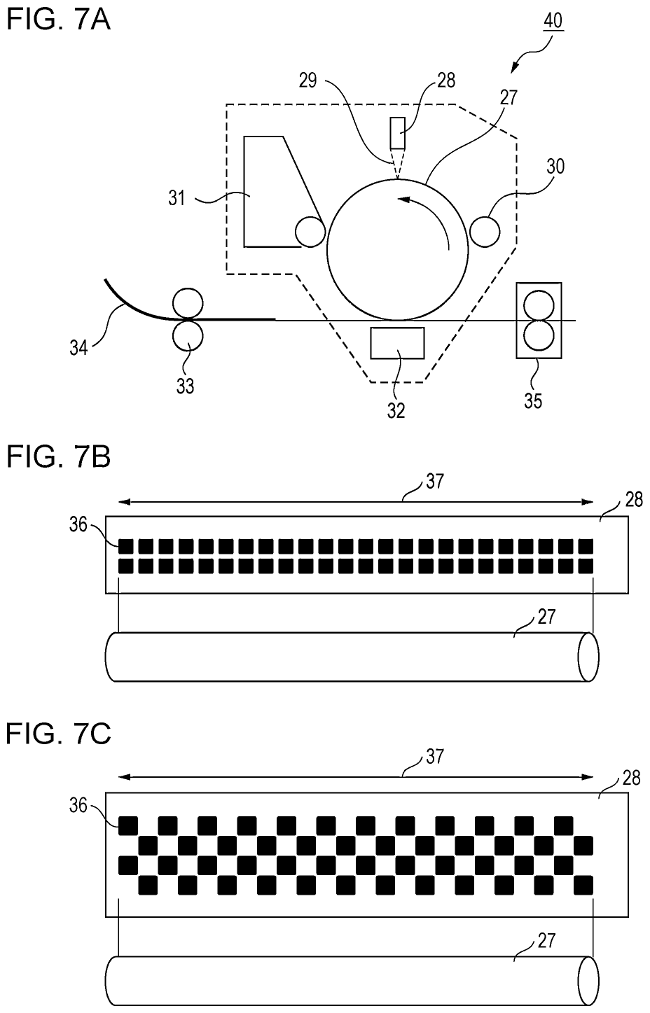

FIG. 7A is a schematic view of an example of an image-forming apparatus according to an embodiment of the present disclosure. An image-forming apparatus 40 is an electrophotographic image-forming apparatus and includes a photoconductor 27, an exposure light source 28, a charging unit 30, a developing unit 31, a transfer unit 32, a transport roller 33, and a fusing unit 35. The irradiation of light 29 is performed from the exposure light source 28 to form an electrostatic latent image on the surface of the photoconductor 27. The exposure light source 28 includes the organic light-emitting device according to the present embodiment. The developing unit 31 contains, for example, a toner. The charging unit 30 charges the photoconductor 27. The transfer unit 32 transfers the developed image to a recording medium 34. The transport roller 33 transports the recording medium 34. The recording medium 34 is paper, for example. The fusing unit 35 fixes the image formed on the recording medium 34.

FIGS. 7B and 7C each illustrate the exposure light source 28 and are each a schematic view illustrating multiple light-emitting portions 36 arranged on a long substrate. Arrows 37 are parallel to the axis of the photoconductor and each represent the row direction in which the organic light-emitting devices are arranged. The row direction is the same as the direction of the axis on which the photoconductor 27 rotates. This direction can also be referred to as the long-axis direction of the photoconductor 27. FIG. 7B illustrates a configuration in which the light-emitting portions 36 are arranged in the long-axis direction of the photoconductor 27. FIG. 7C is different from FIG. 7B in that the light-emitting portions 36 are arranged alternately in the row direction in a first row and a second row. The first row and the second row are located at different positions in the column direction. In the first row, the multiple light-emitting portions 36 are spaced apart. The second row has the light-emitting portions 36 at positions corresponding to the positions between the light-emitting portions 36 in the first row. In other words, the multiple light-emitting portions 36 are also spaced apart in the column direction. The arrangement in FIG. 7C can be rephrased as, for example, a lattice arrangement, a staggered arrangement, or a checkered pattern.

As described above, the use of an apparatus including the organic light-emitting device according to the present embodiment enables a stable display with good image quality even for a long time.

### EXAMPLES

### Example 1

An organic light-emitting device having a bottom-emission structure was produced in which an anode, a hole injection layer, a hole transport layer, an electron-blocking layer, a light-emitting layer, a hole-blocking layer (first organic compound layer), an electron transport layer, an electron injection layer, and a cathode were sequentially formed over a substrate.

An ITO film was formed on a glass substrate and subjected to desired patterning to form an ITO electrode (anode). The ITO electrode had a thickness of 100 nm. The substrate on which the ITO electrode had been formed in this way was used as an ITO substrate in the following steps. Next, vacuum evaporation was performed by resistance heating in a vacuum chamber at 1.33×10⁻⁴ Pa to successively form organic compound layers and an electrode layer presented in Table 7 on the ITO substrate. Here, the opposing electrode (metal electrode layer, cathode) had an electrode area of 3 mm².

TABLE 7

| | | | | Thickness |
|---|---|---|---|---|
| | Material | | | (nm) |
| Cathode | A1 | | | 100 |
| Electron injection layer (EIL) | LiF | | | 1 |
| Electron transport layer (ETL) | ET2 | | | 15 |
| Hole-blocking layer (HBL) | HB11 | | | 10 |
| Light-emitting layer | Host | A2 | Ratio by mass | 30 |
| | Guest | BD1 | EM1:BD6 = | |
| | | | 99:1 | |

| | | |
|---|---|---|
| Electron-blocking layer (EBL) | HT7 | 15 |
| Hole transport layer (HTL) | HT3 | 45 |
| Hole injection layer (HIL) | HT16 | 10 |

The characteristics of the resulting device were measured and evaluated. The emission color of the light-emitting device was blue, and the maximum external quantum efficiency (E.Q.E.) was 58. The device was subjected to a continuous operation test at a current density of 100 mA/cm². The time when the percentage of luminance degradation reached 5% was measured. When the time when the percentage of luminance degradation of Comparative Example 1 reached 5% was defined as 1.0, the percentage ratio of luminance degradation in this example was 2.7.

With regard to measurement instruments, in this example, the current-voltage characteristics were measured with a Hewlett-Packard 4140B microammeter, and the luminance was measured with a Topcon BM7.

### Examples 2 to 31 and Comparative Examples 1 to 4

Organic light-emitting devices were produced in the same manner as in Example 1, except that the compounds were changed to compounds given in Tables 8 and 9 as appropriate. The characteristics of the resulting devices were measured and evaluated as in Example 1. Tables 8 and 9 present the measurement results. Comparative compound 1-a is organic compound 1-a described in Patent Literature 1. Comparative compound 1-b is a dopant described in Patent Literature 1, and its molecular structure is illustrated below.

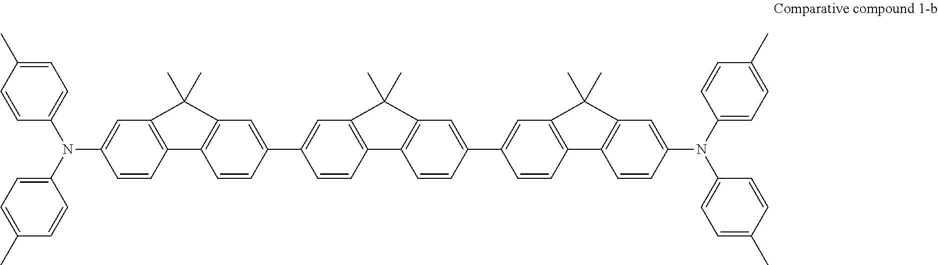 [SMILES: Cc1ccc(N(c2ccc(C)cc2)c2ccc3c(c2)C(C)(C)c2cc(-c4ccc5c(c4)C(C)(C)c4cc(-c6ccc7c(c6)C(C)(C)c6cc(N(c8ccc(C)cc8)c8ccc(C)cc8)ccc6-7)ccc4-5)ccc2-3)cc1]

TABLE 8

| | | | EML | | | | E.Q.E | Percentage ratio of |
|---|---|---|---|---|---|---|---|---|
| | HTL | EBL | Host | Guest | HBL | ETL | [%] | luminance degradation |
| Example 2 | HT3 | HT12 | A2 | BD6 | HB4 | ET3 | 5 | 2.7 |
| Example 3 | HT3 | HT10 | A2 | BD13 | HB9 | ET3 | 5 | 2.9 |
| Example 4 | HT3 | HT10 | A2 | BD16 | HB10 | ET3 | 5 | 2.7 |
| Example 5 | HT2 | HT7 | A2 | BD17 | HB11 | ET2 | 5 | 2.8 |
| Example 6 | HT2 | HT7 | A2 | BD20 | HB15 | ET2 | 5 | 2.7 |
| Example 7 | HT3 | HT7 | A2 | BD27 | HB3 | ET3 | 5 | 2.5 |
| Example 8 | HT2 | HT12 | A2 | BD32 | HB16 | ET2 | 5 | 2.6 |
| Example 9 | HT3 | HT7 | A2 | BD21 | HB10 | ET3 | 5 | 2.7 |
| Example 10 | HT3 | HT7 | A2 | BD21 | HB22 | ET3 | 5 | 2.3 |
| Example 11 | HT3 | HT7 | A2 | BD21 | HB18 | ET3 | 5 | 2.3 |
| Example 12 | HT3 | HT7 | A30 | BD21 | HB14 | ET3 | 5 | 1.7 |
| Example 13 | HT3 | HT7 | A31 | BD21 | HB18 | ET3 | 5 | 1.6 |
| Example 14 | HT3 | HT7 | A34 | BD21 | HB22 | ET3 | 4 | 1.8 |
| Example 15 | HT3 | HT7 | A36 | BD21 | HB22 | ET3 | 4 | 1.7 |
| Example 16 | HT3 | HT7 | A4 | BD21 | HB10 | ET3 | 5 | 2.7 |
| Example 17 | HT3 | HT7 | A5 | BD21 | HB10 | ET3 | 5 | 2.7 |
| Example 18 | HT3 | HT7 | A13 | BD21 | HB10 | ET3 | 5 | 2.7 |
| Example 19 | HT3 | HT7 | A15 | BD21 | HB10 | ET3 | 5 | 2.7 |
| Example 20 | HT3 | HT7 | A16 | BD21 | HB10 | ET3 | 5 | 2.7 |
| Example 21 | HT3 | HT7 | A23 | BD21 | HB10 | ET3 | 5 | 2.6 |

TABLE 9

| | | | EML | | | | E.Q.E | Percentage ratio of |
|---|---|---|---|---|---|---|---|---|
| | HTL | EBL | Host | Guest | HBL | ETL | [%] | luminance degradation |
| Example 22 | HT3 | HT7 | B2 | BD21 | HB10 | ET3 | 5 | 2.6 |
| Example 23 | HT3 | HT7 | B3 | BD21 | HB10 | ET3 | 5 | 2.6 |
| Example 24 | HT3 | HT7 | B14 | BD21 | HB10 | ET3 | 5 | 2.6 |
| Example 25 | HT3 | HT7 | B15 | BD21 | HB10 | ET3 | 5 | 2.6 |
| Example 26 | HT3 | HT7 | B26 | BD21 | HB10 | ET3 | 5 | 2.6 |
| Example 27 | HT3 | HT7 | B27 | BD21 | HB10 | ET3 | 5 | 2.6 |
| Example 28 | HT3 | HT7 | C2 | BD21 | HB10 | ET3 | 5 | 2.5 |
| Example 29 | HT3 | HT7 | C14 | BD21 | HB10 | ET3 | 5 | 2.5 |
| Example 30 | HT3 | HT7 | A2 | BD21 | A2 | ET3 | 5 | 2.7 |
| Example 31 | HT3 | HT7 | A15 | BD21 | A15 | ET3 | 5 | 2.7 |
| Comparative | HT3 | HT7 | Comparative | BD1 | — | ET1 | 4 | 1.0 |
| Example 1 | | | compound 1-a | | | | | |
| Comparative | HT3 | HT7 | Comparative | BD1 | HB11 | ET3 | 5 | 1.4 |
| Example 2 | | | compound 1-a | | | | | |
| Comparative | HT3 | HT7 | A2 | Comparative | HB11 | ET3 | 5 | 0.8 |
| Example 3 | | | | compound 1-b | | | | |
| Comparative | HT3 | HT7 | Comparative | BD1 | HB11 | ET3 | No light emission | |
| Example 4 | | | compound 2 | | | | | |

As described in Examples 1 to 31, the organic light-emitting devices of the present embodiment had excellent durability characteristics. In contrast, in comparative examples 1 to 4, the durability characteristics were not excellent.

In the case of Comparative Examples 1 and 2, since comparative compound 1-a serving as the host material of the light-emitting layer has multiple SP³ carbon atoms, it is considered that the driving durability of the device was adversely affected by bond cleavage and radical formation during the driving of the device and a decrease in compatibility with the guest material.

In the case of Comparative Example 1, since ETL, which is a layer adjacent to the light-emitting layer, is composed of compound ET1, which does not have a fused polycyclic hydrocarbon skeleton having three or more rings and five or less rings, it is considered that the compatibility was largely decreased, and the driving durability of the device was adversely affected by charge accumulation, quenching of excitons and charges, and so forth.

In the case of Comparative Example 3, since the guest material is comparative compound 1-b, which is an amine compound and has a carbon-nitrogen bond having low bond stability, it is considered that the ease of bond cleavage during the driving of the device adversely affected the driving durability of the device.

In the case of Comparative Example 4, since the host material in the light-emitting layer is comparative compound 2, which is represented by formula [1-7] and has high linearity and in which molecular aggregation easily occurs, it is considered that the deterioration of the film properties adversely affected the device characteristics.

For example, as in Examples 1 to 8, any guest material having a fluoranthene skeleton has excellent durability characteristics.

In Examples 9 to 11, comparisons were made with respect to combinations of the host material in which the number of fused rings in each of Ar₁ and Ar₂ is four and the material, in which the number of fused rings is three or more and five or less, of HBL serving as the first organic compound layer. The results indicated that the combination in which the number of fused rings in Ar₁ and Ar₂ of the host material and the number of fused rings in the HBL material were both four rings exhibited the best durability characteristics.

As in Examples 12 to 15, in the case of the combination in which the number of fused rings in each of Ar₁ and Ar₂ of the host material is three and the number of fused rings in the HBL material is five, the effect of improving the durability characteristics is of course provided. However, the effect is slightly inferior to the case of four rings only.

In Examples 16 to 31, comparisons were made with respect to the positions of Ar₁ and Ar₂ in the host material. In Examples 16 to 21, 30, and 31 in which a compound that is represented by general formula [1-3] and that has a small dihedral angle with the naphthalene plane is used as a host material, the effect of improving the durability characteristics is greater than in Examples 22 to 29.

### Example 32

An organic light-emitting device was produced in the same manner as in Example 1, except that the organic compound layers and the electrode layer given in Table 10 were continuously deposited over an ITO substrate. The characteristics of the resulting device were measured and evaluated as in Example 1.

TABLE 10

| | | | | Thickness |
|---|---|---|---|---|
| | Material | | | (nm) |
| Cathode | A1 | | | 100 |
| Electron injection layer (EIL) | LiF | | | 1 |
| Electron transport layer (ETL) | ET2 | | | 20 |
| Hole-blocking layer (HBL) | HB10 | | | 20 |
| Second light-emitting layer | Second host | A2 | Ratio by mass | 10 |
| | Second guest | BD6 | EM1:BD6 = | |
| | | | 98.5:1.5 | |
| First light-emitting layer | First host | A2 | Ratio by mass | 10 |
| | First guest | RD21 | EM2:RD21:GD5 = | |
| | Third guest | GD5 | 97.5:0.5:2.0 | |

| | | |
|---|---|---|
| Electron-blocking layer (EBL) | HT7 | 15 |
| Hole transport layer (HTL) | HT3 | 30 |
| Hole injection layer (HIL) | HT16 | 5 |

The emission color of the light-emitting device was white, and the maximum external quantum efficiency (E.Q.E.) was 7%. When the time when the percentage of luminance degradation of Comparative Example 1 reached 5% was defined as 1.0, the percentage ratio of luminance degradation in this example was 2.6.

### Examples 33 to 46 and Comparative Example 5

Organic light-emitting devices were produced in the same manner as in Example 32, except that the compounds were changed to compounds given in Table 11 as appropriate. The characteristics of the resulting devices were measured and evaluated as in Example 32. The measurement results are presented in Table 11.

TABLE 11

| | First EML | | | Second EML | | | | Percentage ratio |
|---|---|---|---|---|---|---|---|---|
| | First | First | Third | Second | Second | | E.Q.E | of luminance |
| | host | guest | guest | host | guest | HBL | [%] | degradation |
| Example 33 | A4 | RD1 | GD5 | A4 | BD6 | HB10 | 7 | 2.6 |
| Example 34 | A5 | RD21 | GD12 | A5 | BD6 | HB10 | 7 | 2.6 |
| Example 35 | A13 | RD16 | GD5 | A13 | BD13 | HB10 | 7 | 2.6 |
| Example 36 | A15 | RD12 | GD13 | A15 | BD17 | HB10 | 7 | 2.7 |
| Example 37 | A16 | RD24 | GD4 | A16 | BD17 | HB10 | 7 | 2.7 |
| Example 38 | A23 | RD24 | GD6 | A23 | BD21 | HB10 | 7 | 2.6 |
| Example 39 | B2 | RD12 | GD5 | B2 | BD13 | HB10 | 7 | 2.5 |
| Example 40 | B14 | RD12 | GD5 | B14 | BD13 | HB10 | 7 | 2.5 |
| Example 41 | B26 | RD2 | GD5 | B26 | BD6 | HB10 | 7 | 2.5 |
| Example 42 | C2 | RD21 | GD26 | C2 | BD6 | HB10 | 7 | 2.4 |
| Example 43 | C14 | RD21 | GD13 | C14 | BD30 | HB10 | 7 | 2.4 |
| Example 44 | A2 | RD10 | GD26 | A2 | BD16 | HB10 | 7 | 2.7 |
| Example 45 | A2 | RD10 | GD26 | A5 | BD16 | HB10 | 7 | 2.7 |
| Example 46 | A2 | RD10 | GD26 | A2 | BD16 | A2 | 7 | 2.7 |
| Comparative | Comparative | RD21 | GD5 | Comparative | BD6 | HB10 | 6 | 1.0 |
| Example 5 | compound 1-a | | | compound 1-a | | | | |

As described in Examples 32 to 46, it was confirmed that the white organic light-emitting device of the present embodiment had excellent durability characteristics. In contrast, in Comparative Example 5, the durability characteristics were not excellent. In the case of Comparative Example 5, since comparative compound 1-a serving as the host material of the light-emitting layer was a host having multiple SP³ carbon atoms, it is considered that the driving durability of the device was adversely affected by bond cleavage and radical formation during the driving of the device and a decrease in compatibility with the guest material.

### Example 47

In this Example, an organic light-emitting device having a top-emission structure was produced in which an anode, a hole injection layer, a hole transport layer, an electron-blocking layer, a first light-emitting layer, a second light-emitting layer, a hole-blocking layer (first organic compound layer), an electron transport layer, an electron injection layer, and a cathode were sequentially formed over a substrate.

A Ti film having a thickness of 40 nm was formed by a sputtering method on the substrate and patterned using known photolithography, thereby forming the anode. Here, the opposing electrode (metal electrode layer, cathode) had a pixel area of 3 mm². Subsequently, the cleaned substrate on which the electrode had been formed and materials were attached to a vacuum evaporation apparatus (available from ULVAC, Inc.). The apparatus was evacuated to 1.33×10⁻⁴ Pa (1×10⁻⁶ Torr), and then UV/ozone cleaning was performed. Thereafter, each layer was formed so as to achieve the layer configuration given in Table 12.

TABLE 12

| | | | | Thickness |
|---|---|---|---|---|
| | Material | | | (nm) |
| Electron transport layer (ETL) | ET3 | | | 20 |
| Hole-blocking layer (HBL) | HB10 | | | 20 |
| Second light-emitting layer | Second host | A2 | Ratio by mass | 10 |
| | Second guest | BD16 | EM1:BD23 = | |
| | | | 98.5:1.5 | |
| First light-emitting layer | First host | A2 | Ratio by mass | 13 |
| | First guest | RD1 | EM2:RD21:GD5 = | |
| | Third guest | GD5 | 97.5:0.5:2.0 | |

| | | |
|---|---|---|
| Electron-blocking layer (EBL) | HT7 | 15 |
| Hole transport layer (HTL) | HT3 | 30 |
| Hole injection layer (HIL) | HT16 | 5 |

After the formation of the electron transport layer, a lithium fluoride film having a thickness of 0.5 nm was formed as an electron injection layer. Thereafter, a MgAg alloy film having a thickness of 10 nm was formed as a cathode layer. The ratio of Mg to Ag was 1:1. Then a SiN film having a thickness of 1.5 μm was formed by a CVD method as a sealing layer.

The characteristics of the resulting organic EL device were measured and evaluated. At 1,000 cd/m², the efficiency was 7.2 cd/A, the voltage was 3.6 V, and the CIE chromaticity coordinates were (0.25, 0.31). That is, the resulting organic EL device was a good white organic light-emitting device having high efficiency and low device driving voltage. The device was subjected to a continuous operation test at a current density of 100 mA/cm². The time when the percentage of luminance degradation reached 5% was measured. When the time when the percentage of luminance degradation of Comparative Example 1 reached 5% was defined as 1.0, the percentage ratio of luminance degradation in this example was 2.7.

### Examples 48 to 55 and Comparative Example 6

White organic EL devices were produced in the same manner as in Example 47, except that the compounds of the first light-emitting layer and the second light-emitting layers were changed to the compounds given in Table 13 as appropriate. The characteristics of the resulting organic EL devices were measured and evaluated as in Example 47. The measurement results are presented in Table 13.

TABLE 13

| | | | | | | | Percentage |
|---|---|---|---|---|---|---|---|
| | First EML | | | Second EML | | | ratio of |
| | First | First | Third | Second | Second | Efficiency | luminance |
| | host | guest | guest | host | guest | [Cd/A] | degradation |
| Example 48 | A5 | RD16 | GD15 | A5 | BD6 | 7.0 | 2.7 |
| Example 49 | A15 | RD24 | GD15 | A15 | BD21 | 7.3 | 2.7 |
| Example 50 | A16 | RD21 | GD5 | A16 | BD21 | 7.2 | 2.7 |
| Example 51 | B2 | RD1 | GD5 | B2 | BD6 | 7.1 | 2.3 |
| Example 52 | B14 | RD1 | GD5 | B14 | BD6 | 7.1 | 2.3 |
| Example 53 | B26 | RD24 | GD15 | B26 | BD13 | 6.9 | 2.3 |
| Example 54 | C2 | RD16 | GD6 | C2 | BD17 | 6.8 | 2.1 |
| Example 55 | C14 | RD16 | GD6 | C14 | BD21 | 6.8 | 2.1 |
| Comparative | Comparative | RD16 | GD15 | Comparative | BD6 | 6.6 | 1.0 |
| Example 6 | compound 1-a | | | compound 1-a | | | |

As described in Examples 47 to 55, it was confirmed that the white organic light-emitting device of the present embodiment had excellent durability characteristics. In contrast, in Comparative Example 6, the durability characteristics were not excellent. In the case of Comparative Example 6, since comparative compound 1-a serving as the host material of the light-emitting layer was a host having multiple SP³ carbon atoms, it is considered that the driving durability of the device was adversely affected by bond cleavage and radical formation during the driving of the device and a decrease in compatibility with the guest material.

According to the present disclosure, it is possible to provide the organic light-emitting device having improved durability characteristics.

While the present disclosure has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

1. An organic light-emitting device, comprising, in sequence:
an anode;
a light-emitting layer;
a first organic compound layer in contact with the light-emitting layer; and
a cathode,
wherein the light-emitting layer contains a host material and a guest material,
wherein the host material is a hydrocarbon compound whose carbon atoms are SP² carbon atoms only, the hydrocarbon compound is represented by any of the following formulae [1-1] to [1-6]: 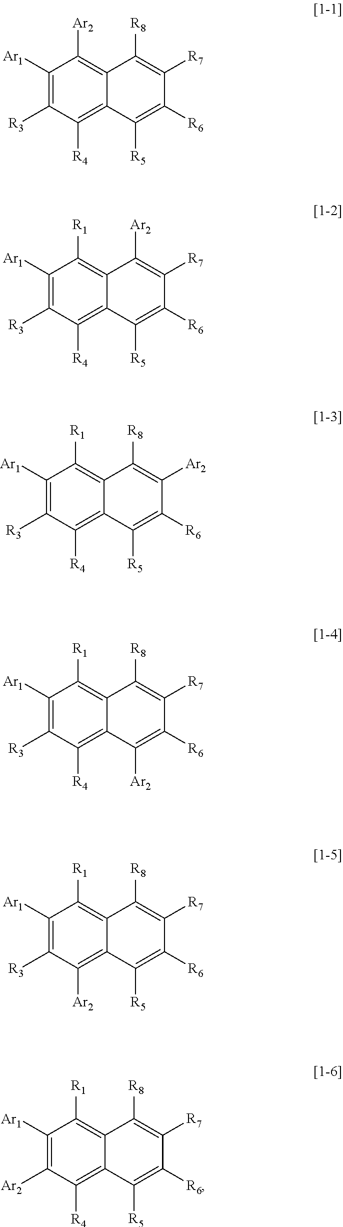
wherein in formulae [1-1] to [1-6], Ar₁ and Ar₂ are each independently selected from the group consisting of an anthracene residue, a phenanthrene residue, a pyrene residue, a fluoranthene residue, a chrysene residue, a triphenylene residue, a benzanthracene residue, a benzophenanthrene residue, a benzpyrene residue, a benzofluoranthene residue, a benzochrysene residue, and a picene residue, each of Ar₁ and Ar₂ optionally further contains a phenyl group, a biphenyl group, a terphenyl group, or a naphthyl group, and
R₁ to R₈ are each independently selected from the group consisting of a hydrogen atom and a substituted or unsubstituted aryl group,
wherein the guest material is a light-emitting material containing a fluoranthene skeleton, and
wherein the first organic compound layer contains a compound containing at least one fused polycyclic hydrocarbon skeleton having three or more rings and five or less rings.

2. The organic light-emitting device according to claim 1, wherein the host material is a hydrocarbon compound represented by formula [1-3].

3. The organic light-emitting device according to claim 1, wherein Ar₁ and Ar₂ are each independently selected from the group consisting of a pyrene residue, a fluoranthene residue, a chrysene residue, and a triphenylene residue.

4. The organic light-emitting device according to claim 3, wherein the first organic compound layer contains a compound having at least one fused polycyclic hydrocarbon skeleton having four rings.

5. The organic light-emitting device according to claim 1, wherein the guest material has a partial structure containing two or more fluoranthene skeletons.

6. The organic light-emitting device according to claim 1, wherein the light-emitting layer is a light-emitting layer that emits blue light.

7. The organic light-emitting device according to claim 1, further comprising another light-emitting layer disposed between the light-emitting layer and the anode, the another light-emitting layer containing a host material and a guest material.

8. The organic light-emitting device according to claim 7, wherein the host material contained in the another light-emitting layer has no SP³ carbon.

9. The organic light-emitting device according to claim 7, wherein the host material contained in the light-emitting layer is identical to the host material contained in the another light-emitting layer.

10. The organic light-emitting device according to claim 7, wherein the organic light-emitting device emits white light with the light-emitting layer and the another light-emitting layer.

11. The organic light-emitting device according to claim 1, further comprising a second organic compound layer disposed between the first organic compound layer and the cathode and in contact with the first organic compound layer,
wherein the second organic compound layer contains a compound containing at least one fused polycyclic hydrocarbon skeleton having three or more rings and five or less rings.

12. The organic light-emitting device according to claim 11, wherein a highest occupied molecular orbital (HOMO) level of the first organic compound layer is smaller than a HOMO level of the light-emitting layer.

13. A display apparatus, comprising multiple pixels, at least one of the multiple pixels including the organic light-emitting device according to claim 1 and a transistor coupled to the organic light-emitting device.

14. A photoelectric conversion apparatus, comprising:
an optical unit including multiple lenses;
an image pickup device configured to receive light passing through the optical unit; and
a display unit configured to display an image captured by the image pickup device,
wherein the display unit includes the organic light-emitting device according to claim 1.

15. An electronic apparatus, comprising:
a display unit including the organic light-emitting device according to claim 1;
a housing provided with the display unit; and
a communication unit disposed in the housing and configured to communicate with an outside.

16. A lighting apparatus, comprising:
a light source including the organic light-emitting device according to claim 1; and
a light diffusion unit or an optical filter configured to transmit light emitted from the light source.

17. A moving object, comprising:
a lighting unit including the organic light-emitting device according to claim 1; and
a body provided with the lighting unit.

18. An image-forming apparatus, comprising:
an exposure light source including the organic light-emitting device according to claim 1; and
a photoconductor configured to be exposed with the exposure light source.

19. An exposure light source, comprising a plurality of the organic light-emitting devices according to claim 1, wherein the organic light-emitting devices are arranged in a row.
